(19) United States
(12) Patent Application Publication
(10) Pub. No.: US 2023/0171984 A1
(43) Pub. Date: Jun. 1, 2023

(54) LIGHT-EMITTING DEVICE AND ELECTRONIC APPARATUS INCLUDING THE SAME

(71) Applicant: Samsung Display Co., Ltd., Yongin-si (KR)

(72) Inventors: Jinwoo PARK, Yongin-si (KR); Boobae KIM, Yongin-si (KR); Seokjae LEE, Yongin-si (KR); Jaejin LEE, Yongin-si (KR)

(73) Assignee: Samsung Display Co., Ltd., Yongin-si (KR)

(21) Appl. No.: 17/851,668

(22) Filed: Jun. 28, 2022

(30) Foreign Application Priority Data
Nov. 30, 2021 (KR) 10-2021-0169333

(51) Int. Cl. H01L 51/50; H01L 27/32; H01L 51/52

(52) U.S. Cl. CPC H01L 51/5056; H01L 51/5072; H01L 27/3218; H01L 51/5275; H01L 51/5092; H01L 27/3244

(57) ABSTRACT

A light-emitting device includes a first electrode; a second electrode facing the first electrode; m emitting parts located between the first electrode and the second electrode; and m−1 charge generation layers. A first hole transport region included in a first emitting part among the m emitting parts includes a first hole transport material, a second hole transport region included in a second emitting unit among the m emitting parts includes a second hole transport material, and a refractive index of the first hole transport material is greater than a refractive index of the second hole transport material.

### CROSS-REFERENCE TO RELATED APPLICATION(S)

This application is based on and claims priority to and benefits of Korean Patent Application No. 10-2021-0169333 under 35 U.S.C. § 119, filed on Nov. 30, 2021, in the Korean Intellectual Property Office (KIPO), the entire contents of which are incorporated herein by reference.

### BACKGROUND

### 1. Technical Field

One or more embodiments relate to a light-emitting device and an electronic apparatus including the same.

### 2. Description of Related Art

Organic light-emitting devices among light-emitting devices are self-emissive devices that have wide viewing angles, high contrast ratios, short response times, and excellent characteristics in terms of luminance, driving voltage, and response speed, compared to devices in the art.

Organic light-emitting devices may include a first electrode located on a substrate, and a hole transport region, an emission layer, an electron transport region, and a second electrode sequentially stacked on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. The excitons may transition from an excited state to a ground state, thus generating light.

### SUMMARY

One or more embodiments include a light-emitting device having improved efficiency and an electronic apparatus including the same.

Additional aspects will be set forth in part in the description which follows and, in part, will be apparent from the description, or may be learned by practice of the presented embodiments of the disclosure.

According to one or more embodiments, a light-emitting device includes a first electrode, a second electrode facing the first electrode, m emitting parts located between the first electrode and the second electrode, and m−1 charge generation layers each located between two neighboring ones among the m emitting parts, and each including an n-type charge generation layer and a p-type charge generation layer, wherein m is an integer of 2 or greater, the m emitting parts each include a hole transport region, an emission layer, and an electron transport region sequentially disposed in sequence, a first hole transport region included in a first emitting part among the m emitting parts includes a first hole transport material, a second hole transport region included in a second emitting part among the m emitting parts includes a second hole transport material, and a refractive index of the first hole transport material is greater than a refractive index of the second hole transport material.

A maximum emission wavelength of light emitted from at least one of the m emitting parts may be different from a maximum emission wavelength of light emitted from at least one of remaining emitting parts of the emitting parts.

A maximum emission wavelength of light emitted from each of the m light-emitting parts may be equal to each other.

A thickness of the first hole transport region and a thickness of the second hole transport region may be equal to each other.

The first hole transport region may directly contact the first electrode, the second hole transport region may directly contact the p-type charge generation layer of a first charge generation layer, the first charge generation layer being located between the first emitting part and the second emitting part, or the first hole transport region directly contacts the first electrode, and the second hole transport region may directly contact the p-type charge generation layer of a first charge generation layer, the first charge generation layer being located between the first emitting part and the second emitting part.

The first electrode may be an anode, the second electrode may be a cathode, the hole transport region may include at least one of a hole injection layer, a hole transport layer, an emission auxiliary layer, and an electron blocking layer, and the electron transport region may include at least one of a buffer layer, a hole blocking layer, an electron control layer, an electron transport layer, and an electron injection layer.

The first hole transport region may include a first hole transport layer including the first hole transport material, and the second hole transport region may include a second hole transport layer including the second hole transport material.

A thickness of the first hole transport layer and a thickness of the second hole transport layer may be equal to each other.

The first hole transport layer may directly contact the first electrode, the second hole transport layer may directly contact the p-type charge generation layer of a first charge generation layer of the m−1 charge generation layers, the first charge generation layer being located between the first emitting part and the second emitting part, or the first hole transport layer may directly contact the first electrode, and the second hole transport layer may directly contact the p-type charge generation layer of a first charge generation layer of the m−1 charge generation layers, and the first charge generation layer being located between the first emitting part and the second emitting part.

A refractive index of the first hole transport material may be about 1.8 or greater and about 2.8 or less, and a refractive index of the second hole transport material may be about 1.5 or greater and about 2.5 or less.

A difference between the refractive index of the first hole transport material and the refractive index of the second hole transport material may be 0.1 or greater and about 0.5 or less.

According to one or more embodiments, a light-emitting device includes first electrodes arranged according to a first subpixel, a second subpixel, respectively, and a third subpixel, a second electrode facing the first electrodes, m emitting parts located between the first electrodes and the second electrode, and m−1 charge generation layers each located between two neighboring ones among the m emitting parts, and each including an n-type charge generation layer and a p-type charge generation layer, wherein m is an integer of 2 or greater, the m emitting parts each include a hole transport region, an emission layer, and an electron transport region disposed in sequence, the emission layer includes a first emission layer located in the first subpixel and emitting first-color light, a second emission layer located in the second subpixel and emitting second-color light, and a third emission layer located in the third subpixel and emitting third-color light, a first hole transport region included in a first emitting part among the m emitting parts includes a first hole transport material, a second hole transport region included in a second emitting part among the m emitting parts includes a second hole transport material, and a refractive index of the first hole transport material is greater than a refractive index of the second hole transport material.

A difference between the refractive index of the first hole transport material and the refractive index of the second hole transport material may be about 0.1 or more and about 0.5 or less.

The first-color light may be red light, the second-color light may be green light, and the third-color light may be blue light.

According to one or more embodiments, a light-emitting device includes first electrodes arranged according to a first subpixel, a second subpixel, and a third subpixel, respectively, a second electrode facing the first electrodes, m emitting parts located between the first electrodes and the second electrode, and m−1 charge generation layers each located between two neighboring ones among the m emitting parts and each including an n-type charge generation layer and a p-type charge generation layer, wherein m is an integer of 2 or greater, m emitting parts each include a hole transport region, an auxiliary layer, an emission layer, and an electron transport layer sequentially disposed in sequence, the emission layer includes a first emission layer located in the first subpixel and emitting first-color light, a second emission layer located in the second subpixel and emitting second-color light, and a third emission layer located in the third subpixel and emitting third-color light, the auxiliary layer includes a first auxiliary layer located in the first subpixel and located between the hole transport region and the first emission layer, a second auxiliary layer located in the second subpixel and located between the hole transport region and the second emission layer, and a third auxiliary layer located in the third subpixel and located between the hole transport region and the third emission layer, the first auxiliary layer included in a first emitting part among the m emitting parts includes a first first auxiliary layer, a first second auxiliary layer, and a first third auxiliary layer, the second auxiliary layer included in a second emitting part among the m emitting parts includes a second first auxiliary layer, a second second auxiliary layer, and a second third auxiliary layer, the first first auxiliary layer, the first second auxiliary layer, and the first third auxiliary layer each independently include a first hole transport material, the second first auxiliary layer, the second second auxiliary layer, and the second third auxiliary layer each independently include a second hole transport material, a refractive index of the first hole transport material is greater than a refractive index of the second hole transport material.

A difference between the refractive index of the first hole transport material and the refractive index of the second hole transport material may be about 0.1 or greater and about 0.5 or less.

A thickness of the first first auxiliary layer and a thickness of the second first auxiliary layer may be equal to each other, a thickness of the first second auxiliary layer and a thickness of the second second auxiliary layer may be equal to each other, and a thickness of the first third auxiliary layer and a thickness of the second third auxiliary layer may be equal to each other.

An electronic apparatus may include the light-emitting device.

The electronic apparatus may further include a thin-film transistor, wherein the thin-film transistor may include a source electrode and a drain electrode, and the first electrode of the light-emitting device may be electrically connected to the source electrode or the drain electrode.

The electronic apparatus may further include at least one of a color filter, a color conversion layer, a touch screen layer, and a polarizing layer.

According to one or more embodiments, an electronic apparatus includes the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 3 each show a schematic cross-sectional view of a light-emitting device according to an embodiment;

FIGS. 4 and 5 each are a cross-sectional view of a light-emitting apparatus according to an embodiment;

FIG. 6 is a result of measuring refractive indices in each wavelength of Compounds A and B; and

FIGS. 7A to 7C are results of measuring the room-temperature lifespans of light-emitting devices of Example 1 and Comparative Example 1 in red light, green light, and blue light, respectively.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. The term “and/or” includes all combinations of one or more of which associated configurations may define. For example, “A and/or B” may be understood to mean “A, B, or A and B.” The phrase “at least one of” is intended to include the meaning of “at least one selected from the group of” for the purpose of its meaning and interpretation. For example, “at least one of A and B” may be understood to mean “A, B, or A and B” (i.e., A, B, or any combination thereof).

Because the disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

Hereinafter, embodiments of the disclosure will be described in detail with reference to the accompanying drawings. The same or corresponding components will be denoted by the same reference numerals, and thus redundant description thereof will be omitted.

It will be understood that although the terms “first,” “second,” and the like may be used herein to describe various components, these components should not be limited by these terms. These components are only used to distinguish one component from another.

An expression used in the singular encompasses the expression of the plural, unless it has a clearly different meaning in the context.

It will be further understood that the terms “comprises” and/or “comprising” used herein specify the presence of stated features or elements, but do not preclude the presence or addition of one or more other features or elements. It will be understood that the terms “contact,” “connected to,” and “coupled to” may include a physical and/or electrical contact, connection, or coupling.

In the following embodiments, when various components such as layers, films, regions, plates, etc. are said to be “on” another component, this may include not only a case in which other components are “immediately on” the layers, films, regions, or plates, but also a case in which other components may be placed therebetween. Sizes of elements in the drawings may be exaggerated for convenience of explanation. In other words, because sizes and thicknesses of components in the drawings are arbitrarily illustrated for convenience of explanation, the following embodiments are not limited thereto.

The term “interlayer” as used herein refers to a single layer and/or all layers between a first electrode and a second electrode of a light-emitting device.

In an embodiment, a light-emitting device may include a first electrode, a second electrode facing the first electrode, m emitting units (or parts) located between the first electrode and the second electrode, and m−1 charge generation layers each located between two neighboring emitting units among the m emitting units and each including an n-type charge generation layer and a p-type charge generation layer, wherein m may be an integer of 2 or more, the m emitting units may each include a hole transport region, an emission layer, an electron transport region sequentially disposed in the stated order, a first hole transport region included in a first emitting unit of the m emitting units may include a first hole transport material, a second hole transport region included in a second emitting unit of the m emitting units may include a second hole transport material, and a refractive index of the first hole transport material may be greater than a refractive index of the second hole transport material.

The number of the emitting units, m, may vary according to the purpose, and the upper limit of the number is not particularly limited. In an embodiment, the light-emitting device may include 2, 3, 4, 5, or 6 emitting units. An emitting unit herein is not particularly limited as long as the emitting unit has a function capable of emitting light. In an embodiment, the emitting unit may include one or more emission layers. When needed, the emitting unit may further include an organic layer other than the emission layer.

The emission layer included in the m emitting units may each independently emit red light, green light, blue light, and/or white light. For example, an emission layer included in a emitting units among m emitting units may emit blue light, an emission layer included in b emitting units may emit red light, an emission layer included in c emitting units may emit green light, and an emission layer included in d emitting units may emit white light. The sum of a, b, c, and d, each of which are an integer of 0 or more, is m. For example, each of the emission layers included in a emitting units among m emitting units may emit blue light, and the blue light may each independently have a maximum emission wavelength greater than or equal to about 400 nm and smaller than or equal to about 490 nm based on a front peak wavelength. For example, at least one of the emission layers included in a emitting units may emit blue light, and the maximum emission wavelength of the blue light may be greater than or equal to about 450 nm and smaller than or equal to about 490 nm.

In an embodiment, the maximum emission wavelength of light emitted from at least one of the m emitting units may be different from the maximum emission wavelength of light emitted from at least one emitting unit among the remaining emitting units. For example, in a light-emitting device in which the first emitting unit and the second emitting unit are stacked, the maximum emission wavelength of light emitted from the first emitting unit may be different from the maximum emission wavelength of light emitted from the second emitting unit. In this case, an emission layer of the first emitting unit and an emission layer of the second emitting unit may each independently have i) a single-layered structure consisting of a single layer consisting of a single material, ii) a single-layer structure consisting of a single layer consisting of different materials, or iii) a multi-layered structure having layers consisting of different materials. Accordingly, light emitted from the first emitting unit or the second emitting unit may be single-color light or mixed-color light. In an embodiment, in a light-emitting device in which a first emitting unit, a second emitting unit, and a third emitting unit are stacked, the maximum emission wavelength of light emitted from the first emitting unit may be the same as the maximum emission wavelength of light emitted from the second emitting unit but different from the maximum emission wavelength of light emitted from the third emitting unit. In an embodiment, the maximum emission wavelength of light emitted from the first emitting unit, the maximum emission wavelength of light emitted from the second emitting unit, and the maximum emission wavelength of light emitted from the third emitting unit may be different from one another.

In another embodiment, in case that m is 4, the light-emitting device may be a device in which a first emitting unit, a second emitting unit, a third emitting unit, and a fourth emitting unit are stacked, the first emitting unit to the third emitting unit may each emit blue fluorescence, and the fourth emitting unit may emit green phosphorescence. In an embodiment, at least one emitting unit among the m emitting units may include a first emission layer and a second emission layer.

In another embodiment, in case that m is 4, because the first emitting unit includes the emission layer having a multi-layer structure as described above, light emitted from the first emitting unit may be mixed color light, the second emitting unit and the third emitting unit may emit blue fluorescence, and the fourth emitting unit may emit green phosphorescence.

In another embodiment, the maximum emission wavelength of light emitted from the m emitting units may all be the same.

In an embodiment, the m emission layers included in the m emitting units may each independently include a phosphorescent dopant, a fluorescence dopant, a delayed fluorescence material, or any combination thereof.

For example, all the m emission layers may include a phosphorescent dopant, a fluorescence dopant, or a delayed fluorescence material.

In one or more embodiments, at least one of them emission layers may include a phosphorescent dopant and the remaining emission layers may include a fluorescence dopant. In one or more embodiments, at least one of the m emission layers may include a phosphorescent dopant and the remaining emission layers may include a delayed fluorescence material. In one or more embodiments, at least one of the m emission layers may include a fluorescence dopant and the remaining emission layers may include a delayed fluorescence material.

In one or more embodiments, at least one of them emission layers may include a phosphorescent dopant, at least one of the remaining emission layers may include a fluorescence dopant, and the remaining emission layers may include a delayed fluorescence material.

In one or more embodiments, at least one of the m−1 emission layers may include a phosphorescent dopant, at least one of the remaining emission layers may include a fluorescence dopant, and the remaining emission layers may include a delayed fluorescence material.

For example, all dopants included in the m−1 emission layers may be identical to or different from each other.

The charge generation layer is included between two neighboring emitting units among m emitting units. Herein, the term “neighboring” refers to a location relationship of emitting units located closest to each other among neighboring emitting units. In an embodiment, the “two neighboring emitting units” refers to the location relationship of two emitting units located closest to each other among emitting units. The “neighboring” may refer to a case where two layers physically contact each other, and a case where another layer, not mentioned, may be located between the two layers. For example, the “emitting unit neighboring to a second electrode” refers to an emitting unit located closest to the second electrode. Also, the second electrode and the emitting unit may physically contact each other. In an embodiment, however, layers other than the emitting unit may be located between the second electrode and the emitting unit. In an embodiment, an electron transport layer may be located between the second electrode and the emitting unit. However, a charge generation layer may be located between two neighboring emitting units.

The “charge generation layer” may generate electrons with respect to an emitting unit of two neighboring emitting units and thus acts as a cathode, and may generate holes with respect to the other emitting unit and thus acts as an anode. The charge generation layer is not directly connected to an electrode, and may separate neighboring emitting units. A light-emitting device including m emitting units may contain m−1 charge generation layers.

Each of the m−1 charge generation layers may include an n-type charge generation layer and a p-type charge generation layer. Here, the n-type charge generation layer and the p-type charge generation layer may directly contact each other to form an NP junction. By the NP junction, electrons and holes may be simultaneously generated between the n-type charge generation layer and the p-type charge generation layer. The generated electrons may be transferred to one of the two neighboring emitting units through the n-type charge generation layer. The generated holes may be transferred to the other one of the two neighboring emitting units through the p-type charge generation layer. In addition, because each of the charge generation layers include an n-type charge generation layer and a p-type charge generation layer, the light-emitting device including m−1 charge generation layers may each include m−1 n-type charge generation layers and m−1 p-type charge generation layers.

The n-type refers to n-type semiconductor characteristics, that is, the characteristics of injecting or transporting electrons. The p-type refers to p-type semiconductor characteristics, that is, the characteristics of injecting or transporting holes.

The m emitting units each include a hole transport region, an emission layer, and an electron transport region sequentially disposed in the stated order. A first hole transport region included in the first emitting unit among the m emitting units may include a first hole transport material, a second hole transport region included in the second emitting unit among the m emitting units may include a second hole transport material, and the refractive index of the first hole transport material is greater than the refractive index of the second hole transport material.

In an embodiment, in case that m is 2, a first emitting unit may be located between the first electrode and a first charge generation layer, and a second emitting unit may be located between the first charge generation layer and the second electrode. The first hole transport region included in the first emitting unit may include the first hole transport material, and the second hole transport region included in the second emitting unit may include the second hole transport material.

In one or more embodiments, in case that m is 3, a first emitting unit may be located between the first electrode and a first charge generation layer, a second emitting unit may be located between the first charge generation layer and a second charge generation layer, and a third emitting unit may be located between the second charge generation layer and the second electrode. The first hole transport region included in the first emitting unit may include the first hole transport material, the second hole transport region included in the second emitting unit may include the second hole transport material, and the third hole transport region included in the third emitting unit may include the third hole transport material. The refractive index of the first hole transport material may be greater than the refractive index of the second hole transport material, and the refractive index of the second hole transport material may be greater than the refractive index of the third hole transport material.

In an embodiment, a thickness of the first hole transport region and a thickness of the second hole transport region may be identical to each other.

In an embodiment, the first hole transport region may directly contact the first electrode, the second hole transport region may directly contact the p-type charge generation layer of the first charge generation layer located between the first emitting unit and the second emitting unit, or a combination thereof may be possible.

In one or more embodiments, the first hole transport region may directly contact the first emission layer included in the first emitting unit, the second hole transport region may directly contact the second emission layer included in the second emitting unit, or a combination thereof may be possible.

In one or more embodiments, the first hole transport region may directly contact the first electrode and the first emission layer included in the first emitting unit, the second hole transport region may directly contact the first charge generation layer located between the first emitting unit and the second emitting unit, and the second emission layer included in the second emitting unit, or a combination thereof may be possible.

In an embodiment, the first electrode may be an anode, the second electrode may be a cathode, the hole transport region may include a hole injection layer, a hole transport layer, an emission auxiliary layer, an electron blocking layer, or any combination thereof, and the electron transport region may include a buffer layer, a hole blocking layer, an electron control layer, an electron transport layer, an electron injection layer, or any combination thereof.

In an embodiment, the first hole transport region may include a first hole transport layer including the first hole transport material, and the second hole transport region may include a second hole transport layer including the second hole transport material.

In an embodiment, a thickness of the first hole transport layer and a thickness of the second hole transport layer may be identical to each other. In an embodiment, the thickness of the first hole transport layer and the thickness of the second hole transport layer may each independently be from about 10 Å to about 800 Å. In an embodiment, the thickness of the first hole transport layer and the thickness of the second hole transport layer may each independently be from about 10 Å to about 700 Å, about 10 Å to about 600 Å, about 10 Å to about 500 Å, about 10 Å to about 400 Å, about 10 Å to about 300 Å, about 10 Å to about 200 Å, about 10 Å to about 100 Å, about 10 Å to about 50 Å, about 100 Å to about 800 Å, about 200 Å to about 800 Å, or about 300 Å to about 800 Å.

In an embodiment, the first hole transport layer may directly contact the first electrode, the second hole transport layer may directly contact the p-type charge generation layer of the first charge generation layer located between the first emitting unit and the second emitting unit, or a combination thereof may be possible.

In one or more embodiments, the first hole transport layer may directly contact the first emission layer included in the first emitting unit, the second hole transport layer may directly contact the second emission layer included in the first emitting unit, or a combination thereof may be possible.

In one or more embodiments, the first hole transport layer may directly contact the first electrode and the first emission layer included in the first emitting unit, the second hole transport layer may directly contact the first charge generation layer located between the first emitting unit and the second emitting unit, and the second emission layer included in the second emitting unit, or a combination thereof may be possible.

In an embodiment, the refractive index of the first hole transport material may be about 1.8 or more and about 2.8 or less, and the refractive index of the second hole transport material may be about 1.5 or more and about 2.5 or less. For example, the refractive index may be in a wavelength from about 380 nm to about 480 nm. In an embodiment, the refractive index of the first hole transport material may be about 1.8 or more and about 2.6 or less, and the refractive index of the second hole transport material may be about 1.6 or more and about 2.3 or less. In an embodiment, the refractive index of the first hole transport material may be about 1.8 or more and about 2.0 or less, and the refractive index of the second hole transport material may be about 1.6 or more and about 1.8 or less.

In an embodiment, the difference between the refractive index of the first hole transport material and the refractive index of the second hole transport material may be about 0.1 or more and about 0.5 or less. In an embodiment, the difference between the refractive index of the first hole transport material and the refractive index of the second hole transport material may be about 0.1 or more and 0.4 or less. In an embodiment, the difference between the refractive index of the first hole transport material and the refractive index of the second hole transport material may be in a range of about 0.1 or more and about 0.3 or less.

Types of the first hole transport material and the second hole transport material are not limited as long as the types of the material satisfy the conditions of the refractive indices above.

For example, the first hole transport layer and the second hole transport layer may each independently include a compound represented by Formula 201, a compound represented by Formula 202, or any combination thereof:

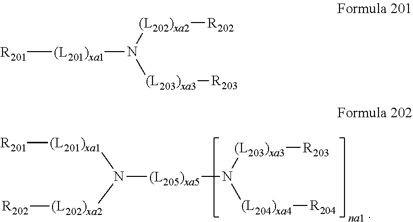

Formulae 201 and 202 are each the same as described in the specification.

In an embodiment, the first hole transport material may be a fluorene group-containing compound, a carbazole group-containing compound, an aryl amine group-containing compound, a diaryl amine group-containing compound, a triaryl amine group-containing compound, a dibenzofuran group-containing compound, a dibenzothiophene group-containing compound, a dibenzosilole group-containing compound, or any combination thereof, and the second hole transport material may be a benzene group-containing compound, a naphthalene group-containing compound, an aryl amine group-containing compound substituted with at least one C₃-C₃₀ carbocyclic group, or any combination thereof, but embodiments are not limited thereto. For example, the C₃-C₃₀ carbocyclic group may be a cyclohexane group, a norbornane group, an adamantane group, or any combination thereof.

Because the refractive index of the first hole transport material in the light-emitting device is greater than the refractive index of the second hole transport material, an internal reflection interface is formed to increase constructive interference, and thus, resonance is increased, thereby improving out-coupling efficiency. In addition, in case that the difference between the refractive index of the first hole transport material and the refractive index of the second hole transport material is about 0.1 or more and about 0.5 or less, as can be seen from the Fresnel equation, out-coupling efficiency may be further improved. Particularly, because the out-coupling efficiency of the hole transport material is improved according to the difference in refractive index regardless of other characteristics (for example, hole mobility), the luminescence efficiency and lifespan characteristics may be improved. Thus, the light-emitting device, for example, an organic light-emitting device, may have high luminescence efficiency and a long lifespan.

$$Refractive Index ( {R}_{0} ) = {\vert \frac{n 1 - n 2}{n 1 + n 2} \vert}^{2} \qquad < Fresnel equation >$$

In the Fresnel equation, n1 is the refractive index of the first material, and n2 is the refractive index of the second material.

The electron transport region may further include a buffer layer, a hole blocking layer, an electron control layer, or any combination thereof. For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, the constituting layers of each structure being sequentially stacked from an emission layer. The electron transport region is the same as described in the specification.

According to one or more embodiments, a light-emitting device may include first electrodes arranged according to each of a first subpixel, a second subpixel, and a third subpixel, a second electrode facing the first electrodes, m emitting units located between the first electrodes and the second electrode, and m−1 charge generation layers each located between two neighboring emitting units among the m emitting units and each including an n-type charge generation layer and a p-type charge generation layer, wherein m may be an integer of 2 or more, the m emitting units may each include a hole transport region, an emission layer, and an electron transport region sequentially disposed in the stated order, the emission layer may include a first emission layer located in the first subpixel and emitting first-color light, a second emission layer located in the second subpixel and emitting second-color light, a third emission layer located in the third subpixel and emitting third-color light, the first-color light, the second-color light, and the third-color light may be identical to or different from each other, a first hole transport region included in a first emitting unit among the m emitting units may include a first hole transport material, a second hole transport region included in a second emitting unit among the m emitting units may include a second hole transport material, and a refractive index of the first hole transport material may be greater than a refractive index of the second hole transport material. The first hole transport material and the second hole transport material may each be the same as described in the specification

In an embodiment, the first-color light may be red light, the second-color light may be green light, and the third-color light may be blue light.

In one or more embodiments, a light-emitting device may include first electrodes arranged according to a first subpixel, a second subpixel, and a third subpixel, a second electrode facing the first electrodes, m emitting units located between the first electrodes and the second electrode, and m−1 charge generation layers each located between two neighboring emitting units among the m emitting units and each including an n-type charge generation layer and a p-type charge generation layer, wherein m is an integer of 2 or more, m emitting units may each include a hole transport region, an auxiliary layer, an emission layer, and an electron transport layer sequentially disposed in the stated order, the emission layer may include a first emission layer located in the first subpixel and emitting first-color light, a second emission layer located in the second subpixel and emitting second-color light, and a third emission layer located in the third subpixel and emitting third-color light, wherein the first-color light, the second-color light, and the third-color light are identical to or different from each other, the auxiliary layer may include a first auxiliary layer located in the first subpixel and located between the hole transport region and the first emission layer, a second auxiliary layer located in the second subpixel and located between the hole transport region and the second emission layer, and a third auxiliary layer located in the third subpixel and located between the hole transport region and the third emission layer, the first auxiliary layer included in a first emitting unit among the m emitting units may include a first first auxiliary layer, a first second auxiliary layer, and a first third auxiliary layer, the second auxiliary layer included in a second emitting unit among the m emitting units may include a second first auxiliary layer, a second second auxiliary layer, and a second third auxiliary layer, the first first auxiliary layer, the first second auxiliary layer, and the first third auxiliary layer may each independently include a first hole transport material, the second first auxiliary layer, the second second auxiliary layer, and the second third auxiliary layer may each independently include a second hole transport material, and a refractive index of the first hole transport material may be greater than a refractive index of the second hole transport material. The first hole transport material and the second hole transport material are each the same as described in the specification

In an embodiment, a thickness of the first first auxiliary layer and a thickness of the second first auxiliary layer may be the same, a thickness of the first second auxiliary layer and a thickness of the second second auxiliary layer may be the same, and a thickness of the first third auxiliary layer and a thickness of the second third auxiliary layer may be the same.

In an embodiment, the first hole transport material included in the first first auxiliary layer, the first second auxiliary layer, and the first third auxiliary layer may be the same, and the second hole transport material included in the second first auxiliary layer, the second second auxiliary layer, and the second third auxiliary layer may be the same.

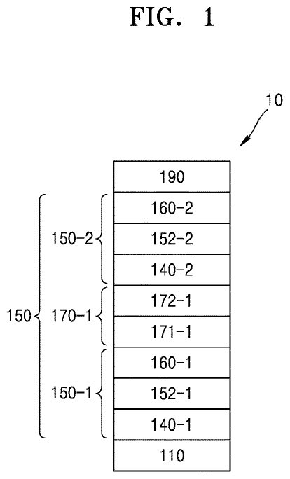

In one or more embodiments, an electronic apparatus may include the light-emitting device. The electronic apparatus may further include a thin-film transistor. For example, the electronic apparatus may further include a thin-film transistor including a source electrode and a drain electrode, wherein the first electrode of the light-emitting device may be electrically connected to the source electrode or the drain electrode. In an embodiment, the electronic apparatus may further include a color filter, a color conversion layer, a touch screen layer, a polarizing layer, or any combination thereof. For more details on the electronic apparatus, related descriptions provided herein may be referred to.

[Description of FIG. 1]

FIG. 1 is a schematic cross-sectional view of a light-emitting device 10 according to an embodiment. The light-emitting device 10 is a drawing exemplifying a light-emitting device in case that m is 2, but embodiments are not limited thereto.

As illustrated in FIG. 1, the light-emitting device 10 may include a first electrode 110, a second electrode 190 facing the first electrode, and an interlayer 150. The interlayer 150 may include two emitting units 150-1 and 150-2 (hereinafter also referred to as a first emitting unit 150-1 and a second emitting unit 150-2) stacked between the first electrode 110 and the second electrode 190, and a charge generation layer 170-1 (hereinafter also referred to as a first charge generation layer 170-1).

The light-emitting device 10 may include a first emitting unit 150-1 closest to the first electrode 110 and a second emitting unit 150-2 closest to the second electrode 190.

The light-emitting device 10 may include the first charge generation layer 170-1 located between the first emitting unit 150-1 and the second emitting unit 150-2.

The first emitting unit 150-1 may include a first hole transport region 140-1, a first emission layer 152-1, and a first electron transport region 160-1 sequentially disposed in the stated order.

The second emitting unit 150-2 may include a second hole transport region 140-2, a second emission layer 152-2, and a second electron transport region 160-2 sequentially disposed in the stated order.

The first and second hole transport regions 140-1 and 140-2 may each independently include a hole injection layer, a hole transport layer, an emission auxiliary layer, an electron blocking layer, or any combination thereof.

The first hole transport region 140-1 may include the first hole transport material, and the second hole transport region 140-2 may include the second hole transport material. The first hole transport material and the second hole transport material are each the same as described in the specification

For example, the first hole transport region 140-1 may include the first hole transport layer (not shown), and the first hole transport layer may include the first hole transport material.

For example, the second hole transport region 140-2 may include the second hole transport layer (not shown), and the second hole transport layer may include the second hole transport material.

The first charge generation layer 170-1 may include a first n-type charge generation layer 171-1 and a first p-type charge generation layer 172-1. The first n-type charge generation layer 171-1 may directly contact the first p-type charge generation layer 172-1.

Hereinafter, the structure of the light-emitting device 10 according to an embodiment and a method of manufacturing the light-emitting device 10 will be described with reference to FIG. 1.

[First Electrode 110]

In FIG. 1, a substrate may be additionally located under the first electrode 110 or above the second electrode 190. As the substrate, a glass substrate or a plastic substrate may be used. In one or more embodiments, the substrate may be a flexible substrate, and may include plastics with excellent heat resistance and durability, such as polyimide, polyethylene terephthalate (PET), polycarbonate, polyethylene napthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In case that the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, in case that the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure consisting of a single layer or a multi-layered structure including layers. For example, the first electrode 110 may have a three-layered structure of ITO/Ag/ITO.

[Interlayer 150]

The interlayer 150 is located on the first electrode 110. The interlayer 150 may include emission layers 152-1 and 152-2.

The interlayer 150 may include i) two or more emitting units 150-1 and 150-2 sequentially stacked between the first electrode 110 and the second electrode 190, and ii) the charge generation layer 170-1 located between the two or more emitting units. In case that the interlayer 150 includes the emitting units 150-1 and 150-2 and the charge generation layer 170-1, the light-emitting device 10 may be a tandem light-emitting device.

The two or more light-emitting units 150-1 and 150-2 may each include the hole transport regions 140-1 and 140-2, the emission layers 152-1 and 152-2, and the electron transport regions 160-1 and 160-2 sequentially disposed in the stated order.

The interlayer 150 may further include metal-containing compounds such as organometallic compounds, inorganic materials such as quantum dots, and the like, in addition to various organic materials.

[Hole Transport Regions 140-1 and 140-2 in Interlayer 150]

The hole transport regions 140-1 and 140-2 may have i) a single-layer structure consisting of a single layer consisting of a single material, ii) a single-layer structure consisting of a single layer consisting of different materials, or iii) a multi-layered structure including layers including different materials.

The hole transport regions 140-1 and 140-2 may include a hole injection layer, a hole transport layer, an emission auxiliary layer, an electron blocking layer, or any combination thereof.

For example, the hole transport regions 140-1 and 140-2 may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein, in each structure, the layers are sequentially stacked in the stated order from the first electrode 110.

The hole transport regions 140-1 and 140-2 may include a compound represented by Formula 201, a compound represented by Formula 202, or any combination thereof:

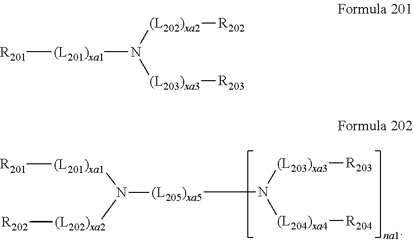

In Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S-′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group or the like) unsubstituted or substituted with at least one R₁₀ₐ (for example, Compound HT16),

R₂₀₃ and 8204 may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer from 1 to 4.

For example, each of Formulae 201 and 202 may include at least one of groups represented by Formulae CY201 to CY217:

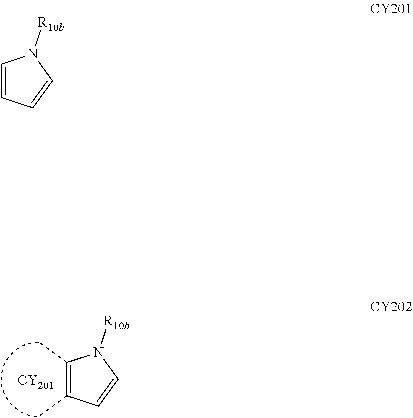

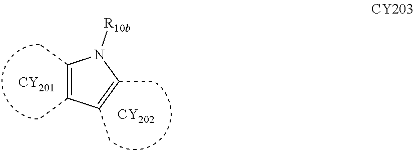

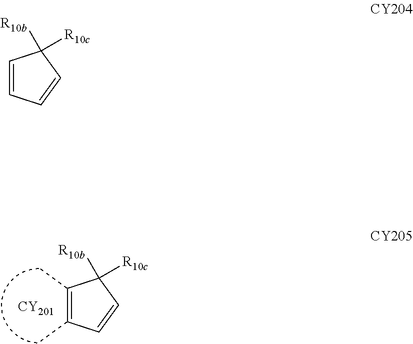

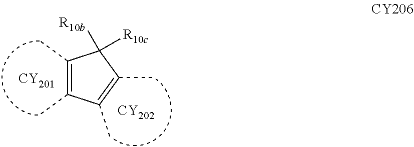

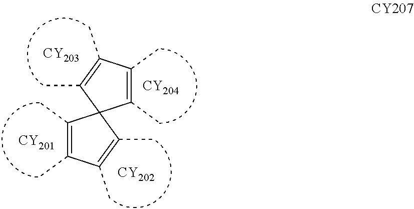

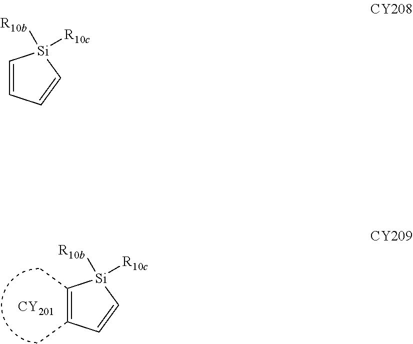

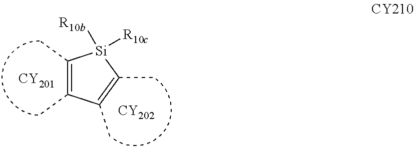

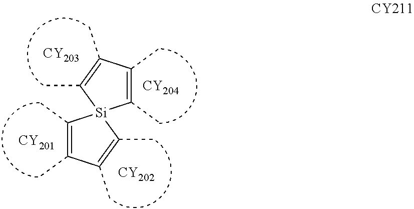

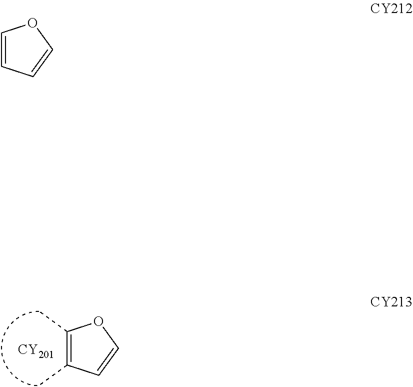

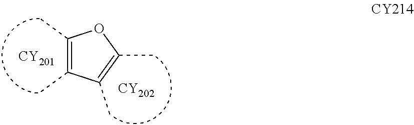

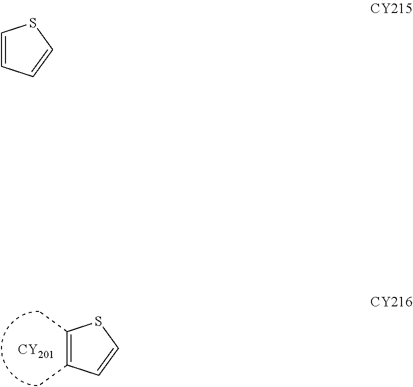

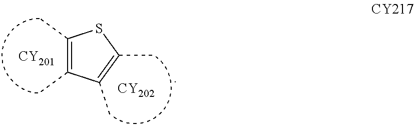

In Formulae CY201 to CY217, R_{10b} and R_{10c} may each be the same as in the description of R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In an embodiment, ring CY₂₀₁ to ring CY₂₀₄ in Formulae CY201 to CY217 may each independently be a benzene group, a naphthalene group, a phenanthrene group, or an anthracene group.

In one or more embodiments, each of Formulae 201 and 202 may include at least one of groups represented by Formulae CY201 to CY203.

In one or more embodiments, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include a group represented by one of Formulae CY201 to CY203.

In one or more embodiments, each of Formulae 201 and 202 may not include a group represented by one of Formulae CY201 to CY203, and may include at least one of the groups represented by Formulae CY204 to CY217.

In one or more embodiments, each of Formulae 201 and 202 may not include a group represented by one of Formulae CY201 to CY217.

In an embodiment, the hole transport regions 140-1 and 140-2 may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

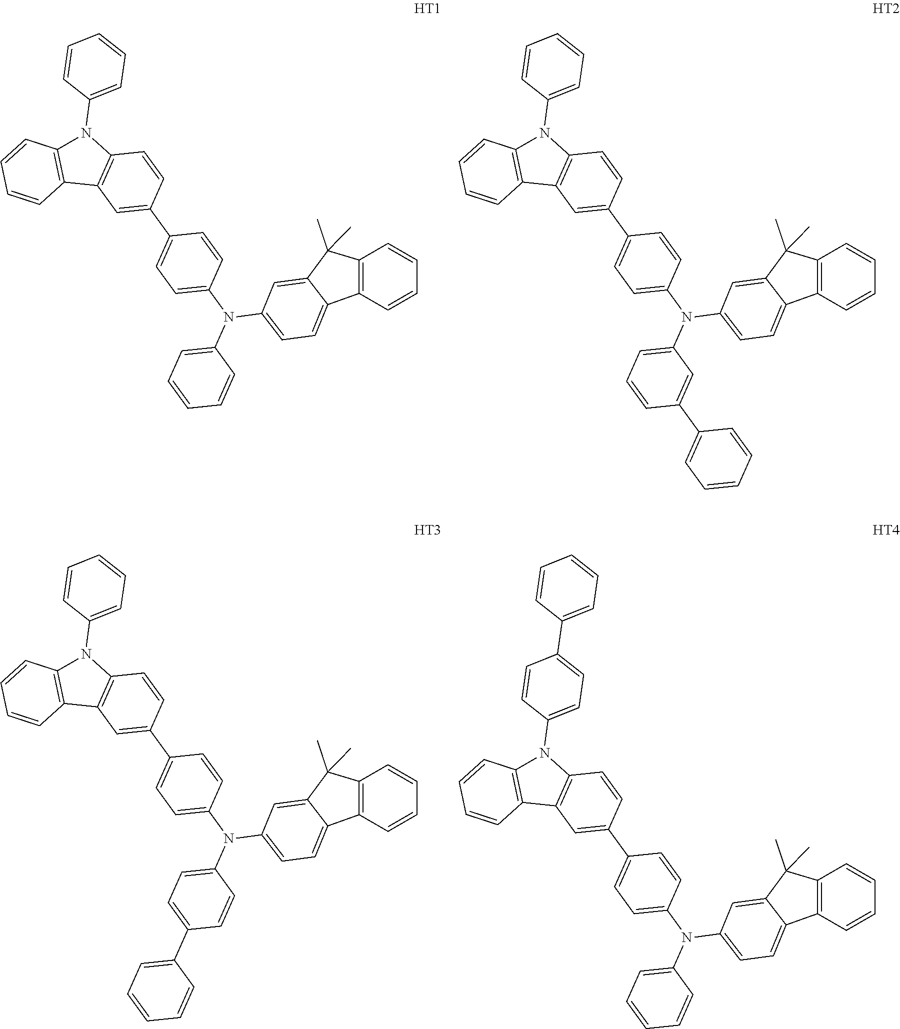

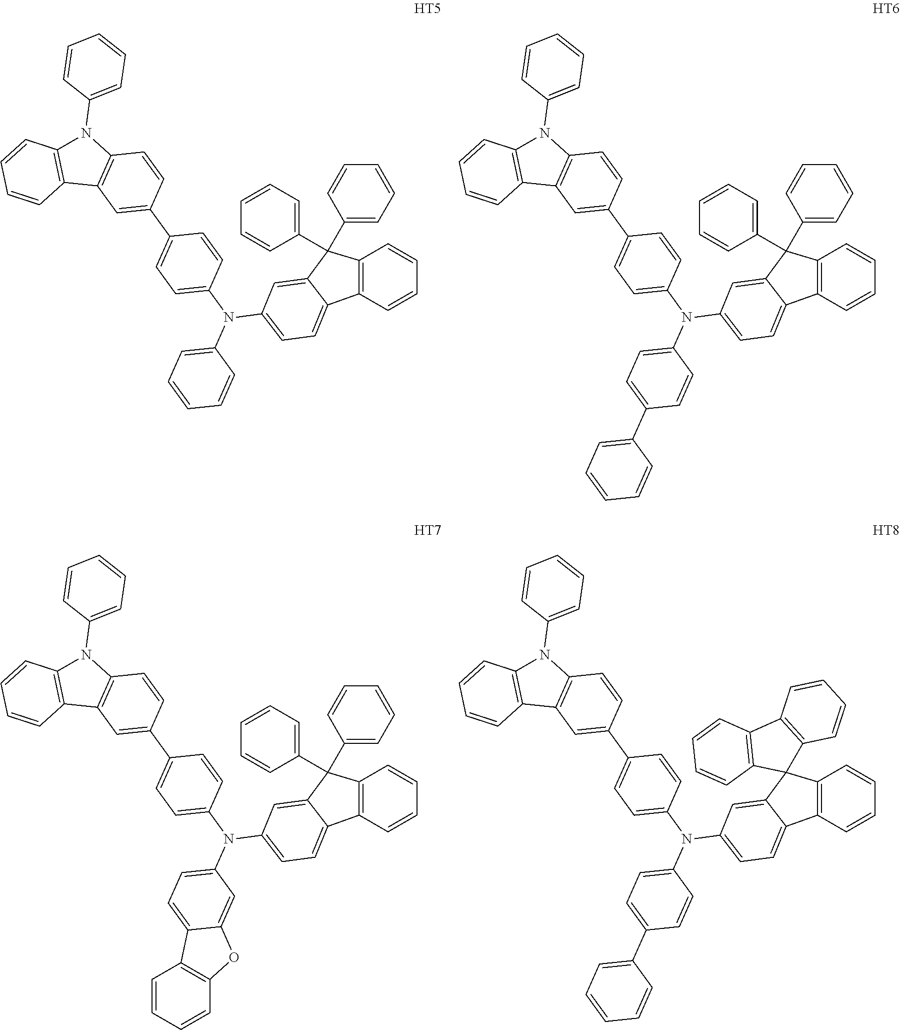 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

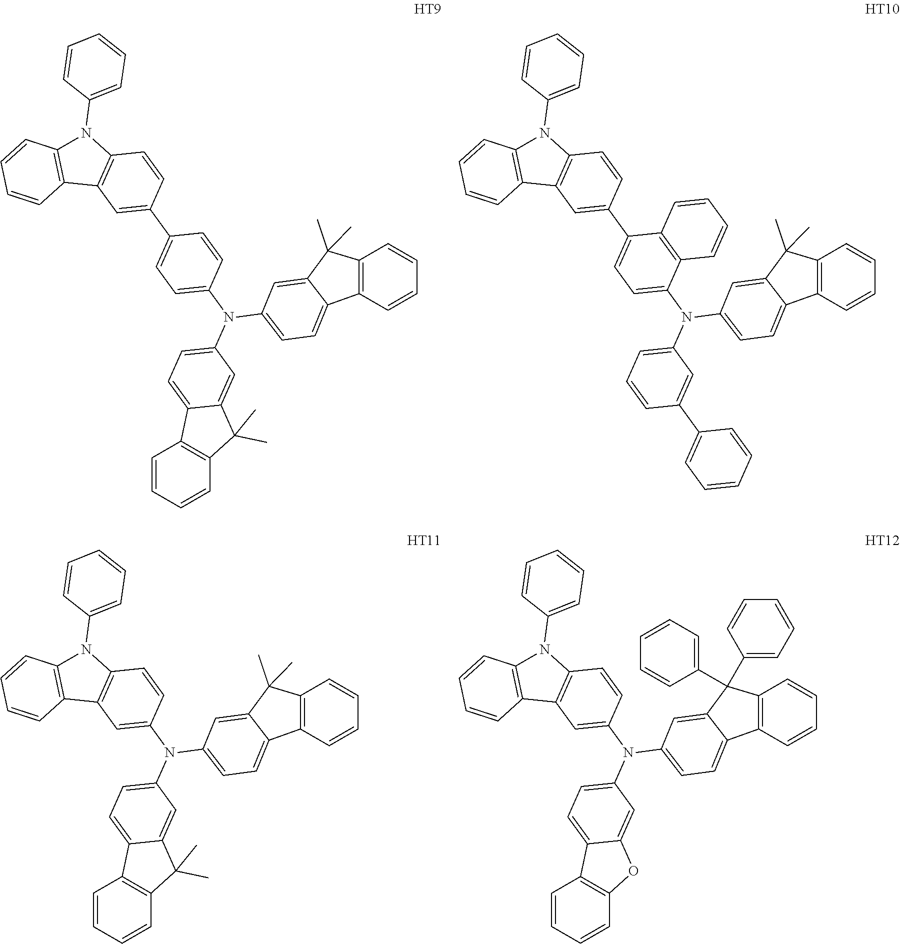 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

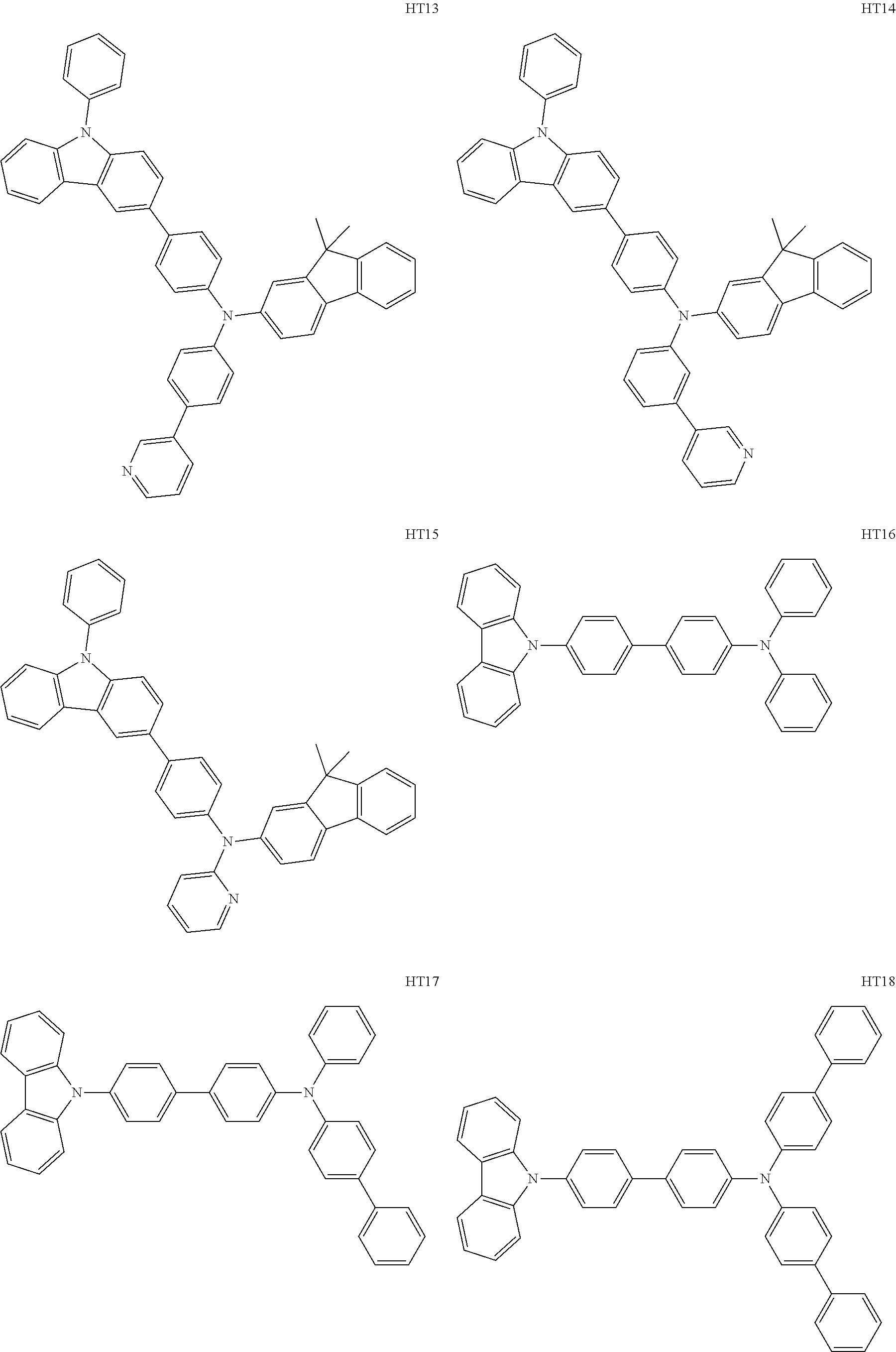

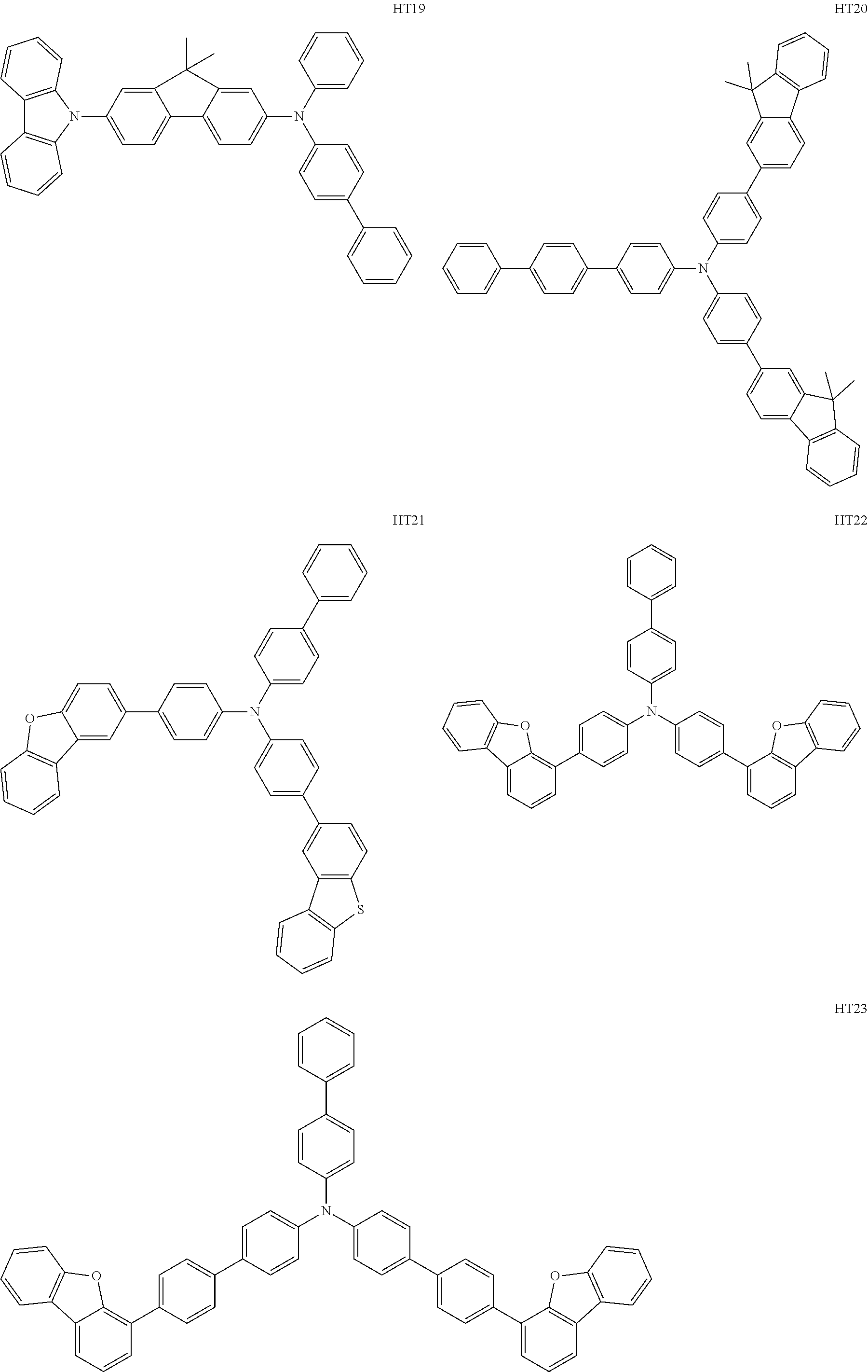

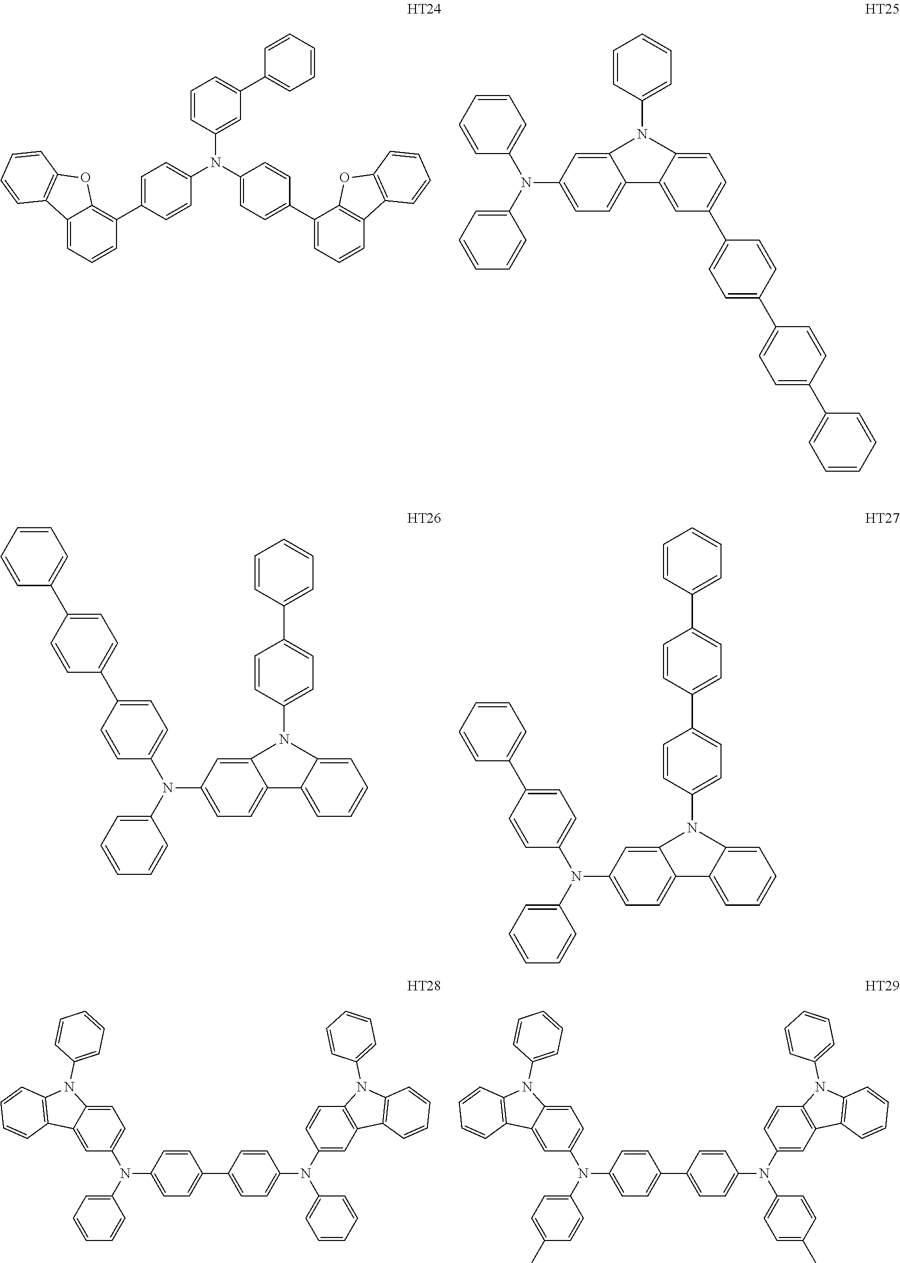

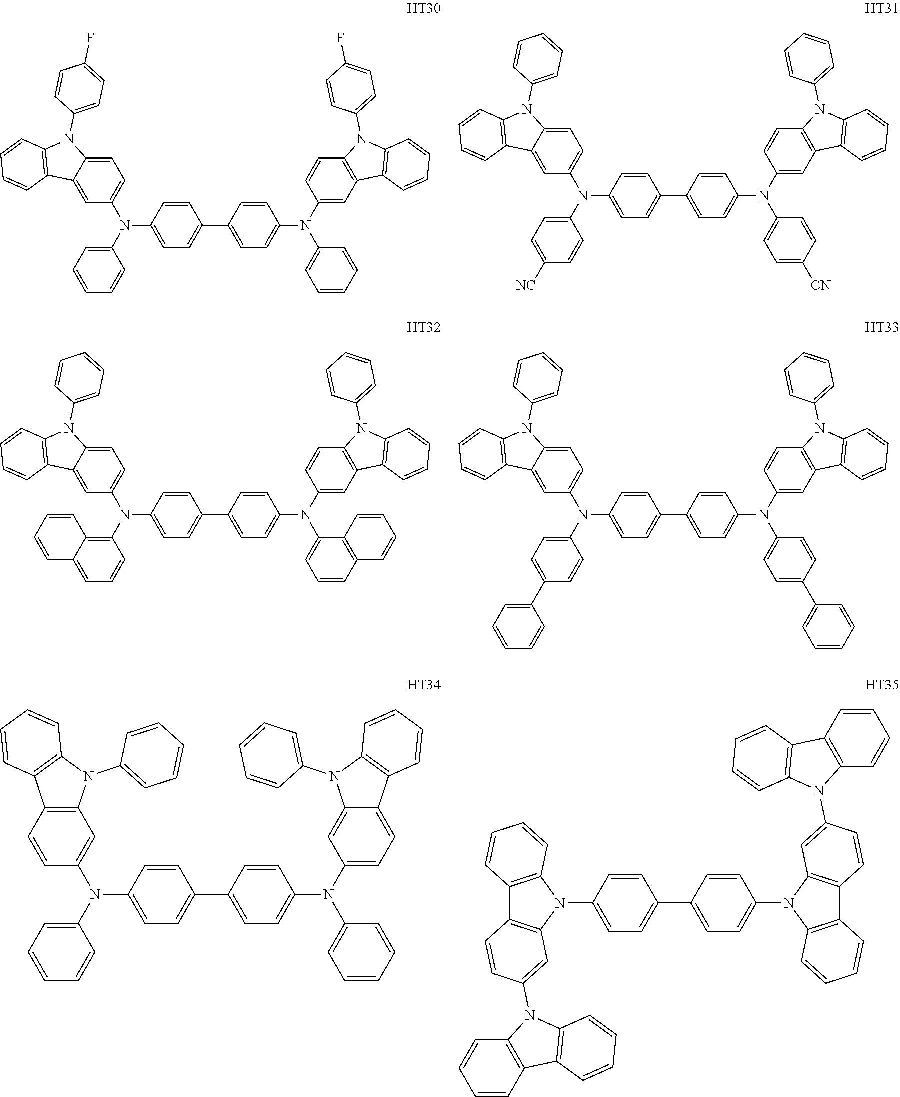

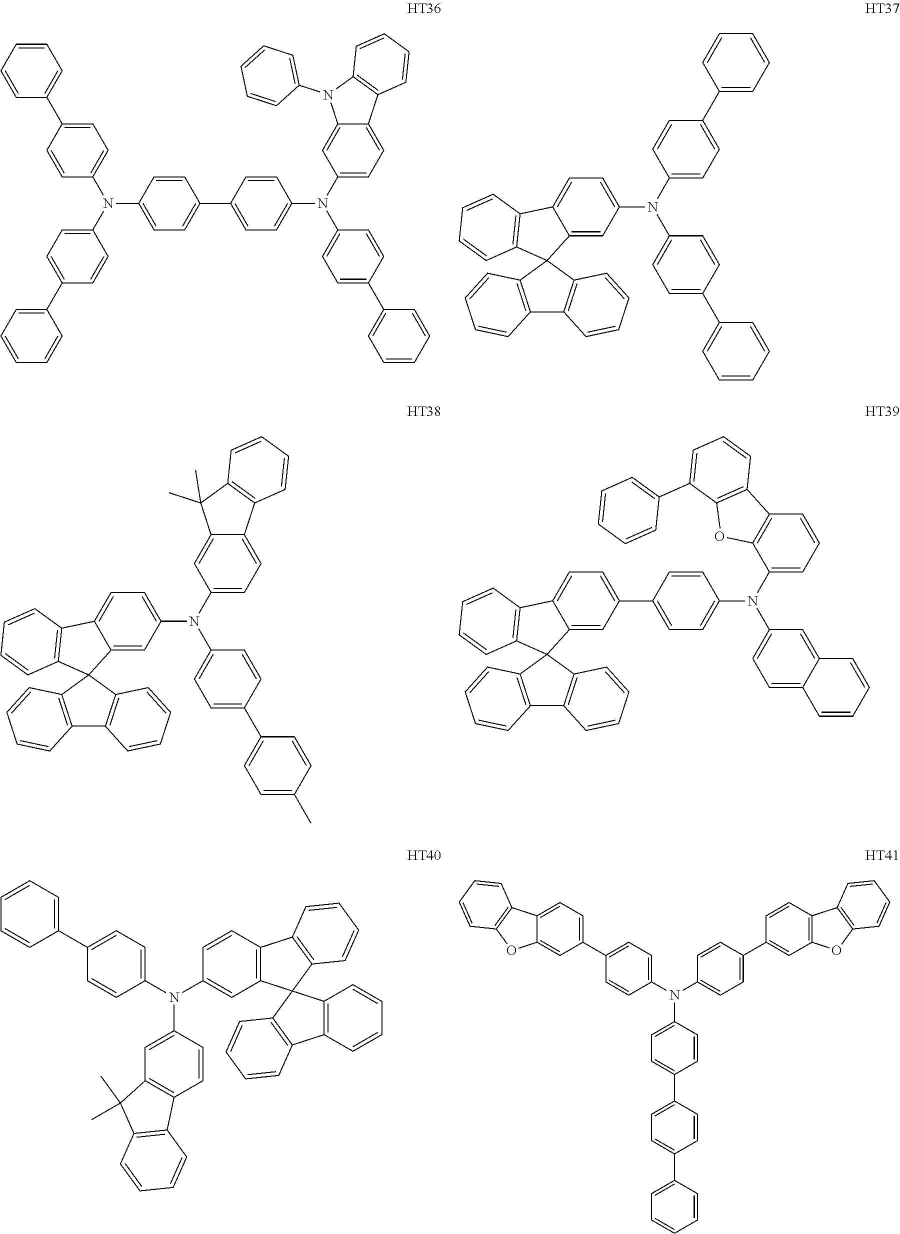

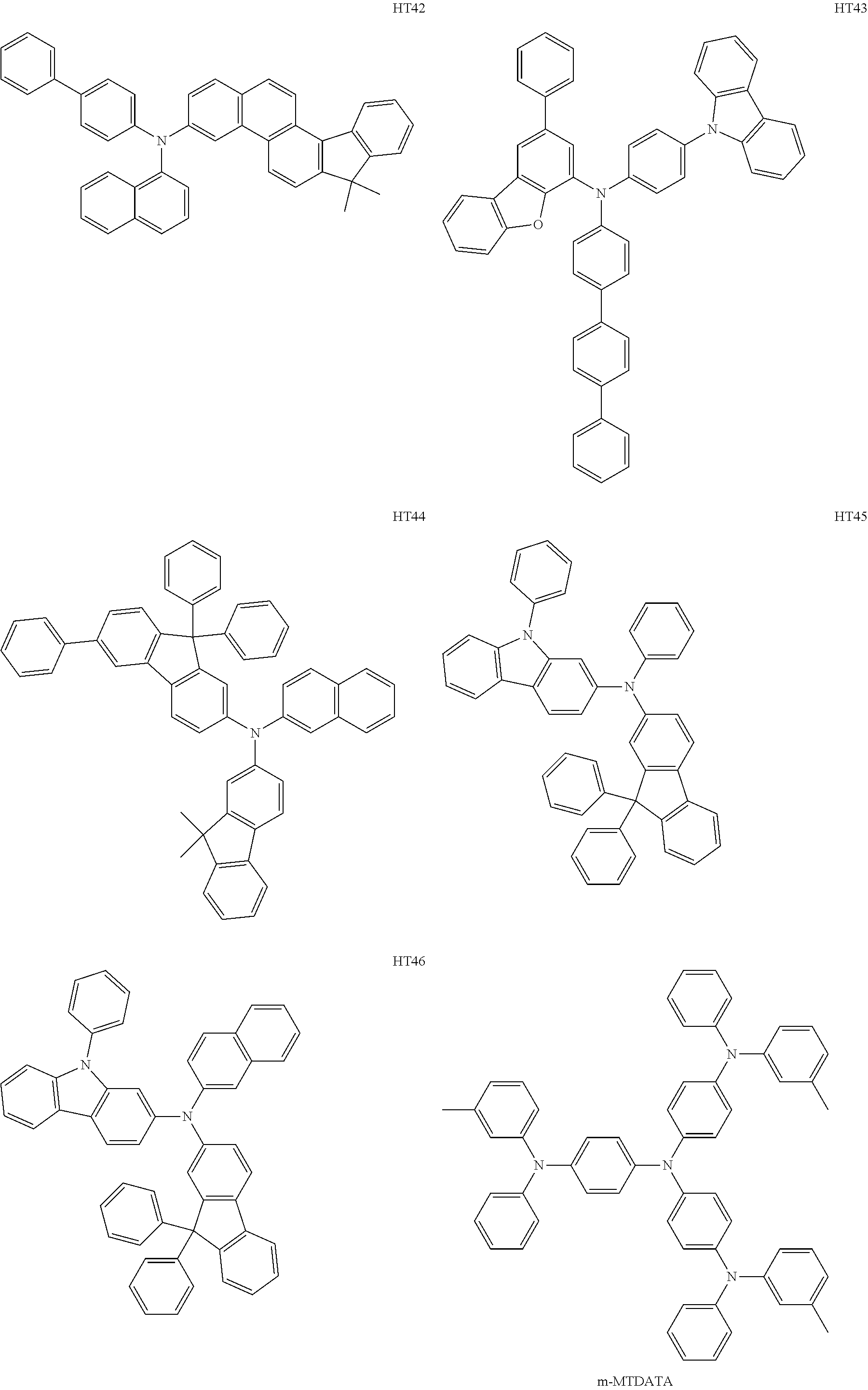

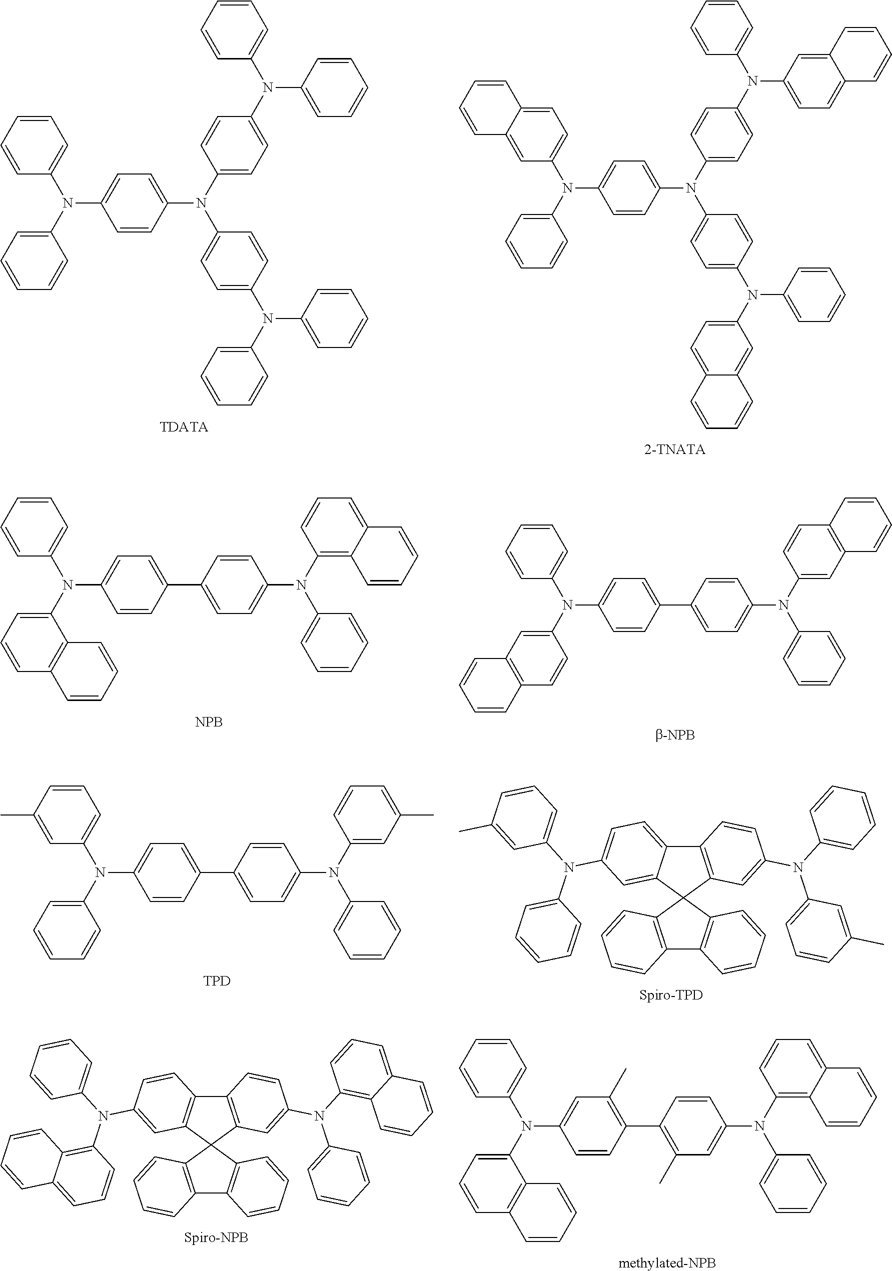

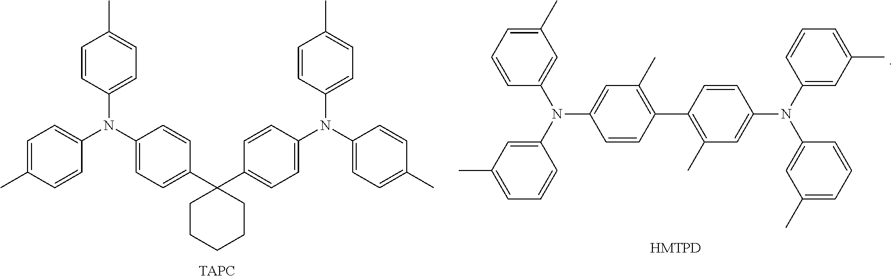

A thickness of the hole transport regions 140-1 and 140-2 may be in a range of about 50 Å to about 10,000 Å, for example, about 100 Å to about 4,000 Å. In case that the hole transport regions 140-1 and 140-2 include a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. In case that the thicknesses of the hole transport regions 140-1 and 140-2, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to the wavelength of light emitted by an emission layer, and the electron blocking layer may block the leakage of electrons from an emission layer to a hole transport region. Materials that may be included in the hole transport regions 140-1 and 140-2 may be included in the emission auxiliary layer and the electron blocking layer.

[p-Dopant]

The hole transport regions 140-1 and 140-2 may further include, in addition to the materials as described above, a charge-generation material for the improvement of conductive characteristics. The charge-generation material may be uniformly or non-uniformly dispersed in the hole transport region (for example, in the form of a single layer consisting of a charge-generation material).

The charge-generation material may be, for example, a p-dopant.

For example, the lowest unoccupied molecular orbital (LUMO) energy level of the p-dopant may be about −3.5 eV or less.

In one or more embodiments, the p-dopant may include a quinone derivative, a cyano group-containing compound, a compound including element EL1 and element EL2, or any combination thereof.

Examples of the quinone derivative are TCNQ, F4-TCNQ, etc.

Examples of the cyano group-containing compound are HAT-CN, and a compound represented by Formula 221:

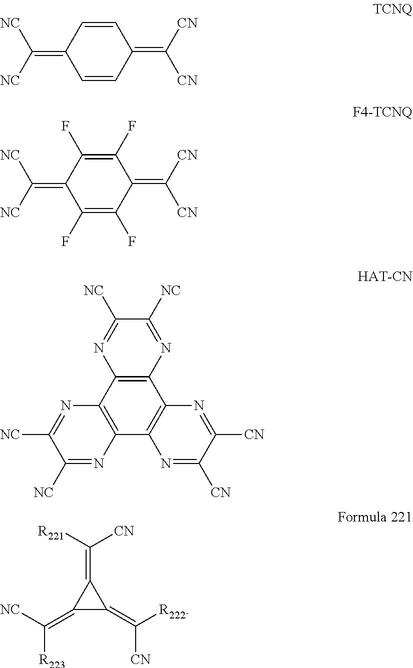

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and

at least one of R₂₂₁ to R₂₂₃ may each independently be a C₃-C₆₀ carbocyclic group or a C₁-C₆₀ heterocyclic group, each substituted with a cyano group, —F, —Cl, —Br, —I, a C₁-C₂₀ alkyl group substituted with a cyano group, —F, —Cl, —Br, —I, or any combination thereof, or any combination thereof.

In the compound including element EL1 and element EL2, element EL1 may be metal, metalloid, or any combination thereof, and element EL2 may be non-metal, metalloid, or any combination thereof.

Examples of the metal are an alkali metal (for example, lithium (Li), sodium (Na), potassium (K), rubidium (Rb), cesium (Cs), etc.). alkaline earth metal (for example, beryllium (Be), magnesium (Mg), calcium (Ca), strontium (Sr), barium (Ba), etc.), transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc., post-transition metal (for example, zinc (Zn), indium (In), tin (Sn), etc.), and lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid are silicon (Si), antimony (Sb), and tellurium (Te).

Examples of the non-metal are oxygen (O) and halogen (for example, F, Cl, Br, I, etc.).

Examples of the compound including element EL1 and element EL2 are metal oxide, metal halide (for example, metal fluoride, metal chloride, metal bromide, or metal iodide), metalloid halide (for example, metalloid fluoride, metalloid chloride, metalloid bromide, or metalloid iodide), metal telluride, or any combination thereof.

Examples of the metal oxide are tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), and rhenium oxide (for example, ReO₃, etc.).

Examples of the metal halide are alkali metal halide, alkaline earth metal halide, transition metal halide, post-transition metal halide, and lanthanide metal halide.

Examples of the alkali metal halide are LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of the alkaline earth metal halide are BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and BaI₂.

Examples of the transition metal halide are titanium halide (for example, TiF₄, TiCl₄, TiBr₄, TiI₄, etc.), zirconium halide (for example, ZrF₄, ZrCl₄, ZrBr₄, ZrI₄, etc.), hafnium halide (for example, HfF₄, HfCl₄, HfBr₄, HfI₄, etc.), vanadium halide (for example, VF₃, VC₁₃, VBr₃, VI₃, etc.), niobium halide (for example, NbF₃, NbCl₃, NbBr₃, NbI₃, etc.), tantalum halide (for example, TaF₃, TaCl₃, TaBr₃, TaI₃, etc.), chromium halide (for example, CrF₃, CrCl₃, CrBr₃, CrI₃, etc.), molybdenum halide (for example, MoF₃, MoCl₃, MoBr₃, MoI₃, etc.), tungsten halide (for example, WF₃, WC₁₃, WBr₃, WI₃, etc.), manganese halide (for example, MnF₂, MnCl₂, MnBr₂, MnI₂, etc.), technetium halide (for example, TcF₂, TcCl₂, TcBr₂, TcI₂, etc.), rhenium halide (for example, ReF₂, ReCl₂, ReBr₂, ReI₂, etc.), iron halide (for example, FeF₂, FeCl₂, FeBr₂, FeI₂, etc.), ruthenium halide (for example, RuF₂, RuCl₂, RuBr₂, RuI₂, etc.), osmium halide (for example, OsF₂, OsCl₂, OsBr₂, OsI₂, etc.), cobalt halide (for example, CoF₂, CoCl₂, CoBr₂, CoI₂, etc.), rhodium halide (for example, RhF₂, RhCl₂, RhBr₂, RhI₂, etc.), iridium halide (for example, IrF₂, IrCl₂, IrBr₂, IrI₂, etc.), nickel halide (for example, NiF₂, NiCl₂, NiBr₂, NiI₂, etc.), palladium halide (for example, PdF₂, PdCl₂, PdBr₂, PdI₂, etc.), platinum halide (for example, PtF₂, PtCl₂, PtBr₂, PtI₂, etc.), copper halide (for example, CuF, CuCl, CuBr, CuI, etc.), silver halide (for example, AgF, AgCl, AgBr, AgI, etc.), and gold halide (for example, AuF, AuCl, AuBr, AuI, etc.).

Examples of the post-transition metal halide are zinc halide (for example, ZnF₂, ZnCl₂, ZnBr₂, ZnI₂, etc.), indium halide (for example, InI₃, etc.), and tin halide (for example, SnI₂, etc.).

Examples of the lanthanide metal halide are YbF, YbF₂, YbF₃, Sm F₃, YbCl, YbCl₂, YbCl₃ SmCl₃, YbBr, YbBr₂, YbBr₃ SmBr₃, YbI, YbI₂, YbI₃, and SmI₃

An example of the metalloid halide is antimony halide (for example, SbCl₅, etc.).

Examples of the metal telluride are alkali metal telluride (for example, Li₂Te, a na₂Te, K₂Te, Rb₂Te, Cs₂Te, etc.), alkaline earth metal telluride (for example, BeTe, MgTe, CaTe, SrTe, BaTe, etc.), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (for example, ZnTe, etc.), and lanthanide metal telluride (for example, LaTe, CeTe, PrTe, NdTe, PmTe, EuTe, GdTe, TbTe, DyTe, HoTe, ErTe, TmTe, YbTe, LuTe, etc.).

[Emission Layers 152-1 and 152-2 in Interlayer 150]

In case that the light-emitting device 10 is a full-color light-emitting device, the emission layers 152-1 and 152-2 may be patterned into a red emission layer, a green emission layer, and/or a blue emission layer, for each subpixel. In one or more embodiments, the emission layer may have a stacked structure of two or more layers of a red emission layer, a green emission layer, and a blue emission layer, in which the two or more layers contact each other or are separated from each other to emit white light. In one or more embodiments, the emission layer may include two or more materials of a red light-emitting material, a green light-emitting material, and a blue light-emitting material, in which the two or more materials are mixed with each other in a single layer to emit white light.

The emission layers 152-1 and 152-2 may include a host and a dopant. The dopant may include a phosphorescent dopant, a fluorescence dopant, or any combination thereof.

The amount of the dopant in the emission layers 152-1 and 152-2 may be from about 0.01 parts by weight to about 15 parts by weight based on 100 parts by weight of the host.

In one or more embodiments, the emission layers 152-1 and 152-2 may include quantum dots.

In one or more embodiments, the emission layers 152-1 and 152-2 may include a delayed fluorescence material. The delayed fluorescence material may act as a host or a dopant in the emission layers 152-1 and 152-2.

A thickness of the emission layers 152-1 and 152-2 may be in a range of about 100 Å to about 1,000 Å, for example, about 200 Å to about 600 Å. In case that the thickness of the emission layers 152-1 and 152-2 is within these ranges, excellent luminescence characteristics may be obtained without a substantial increase in driving voltage.

[Host]

In one or more embodiments, the host may include a compound represented by Formula 301 below:

[Ar₃₀₁]_{xb11}-[(L₃₀₁)_{xb1}-R₃₀₁]_{xb21}. Formula 301

In Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb11 may be 1, 2, or 3,

xb1 may be an integer from 0 to 5,

R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ,—Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer from 1 to 5, and

Q₃₀₁ to Q₃₀₃ are each the same as described herein with respect to Q₁.

For example, in case that xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination thereof:

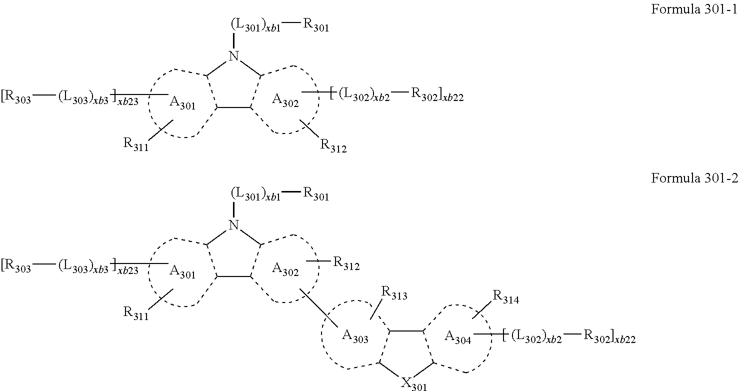

In Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N-[(L₃₀₄)_{xb4}-R₃₀₄], C(R₃₀₄)(R₃₀₅), or Si(R₃₀₄)(R₃₀₅),

xb22 and xb23 may each independently be 0, 1, or 2,

L₃₀₁, xb1, and R₃₀₁ may each be the same as described herein,

L₃₀₂ to L₃₀₄ may each independently be the same as described herein with respect to with L₃₀₁,

xb2 to xb4 may each independently be the same as described herein with respect to xb1, and

R₃₀₂ to R₃₀₅ and R₃₁₁ to R₃₁₄ may each be the same as described herein with respect to R₃₀₁.

In one or more embodiments, the host may include an alkali earth metal complex, a post-transition metal complex, or any combination thereof. For example, the host may include a Be complex (for example, Compound H55), an Mg complex, a Zn complex, or any combination thereof.

In an embodiment, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

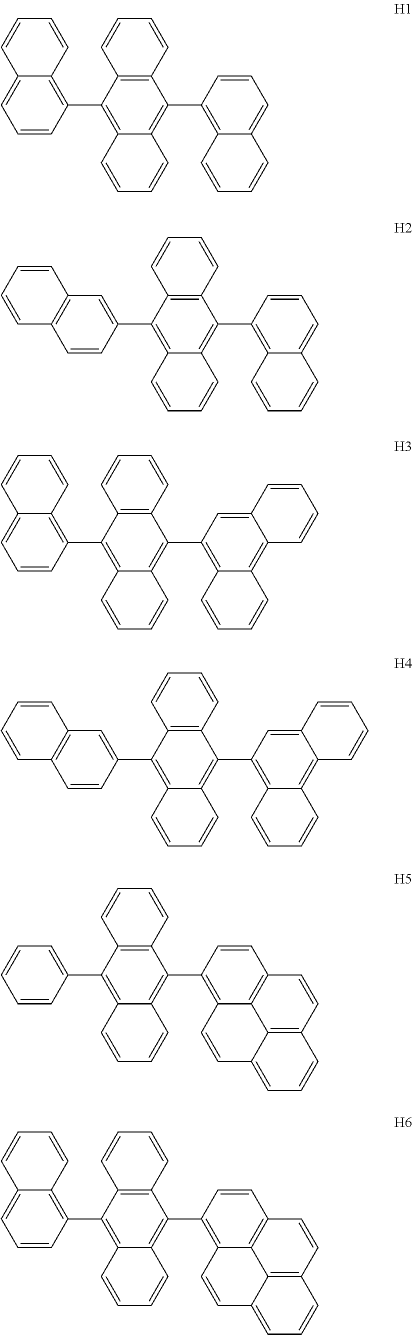

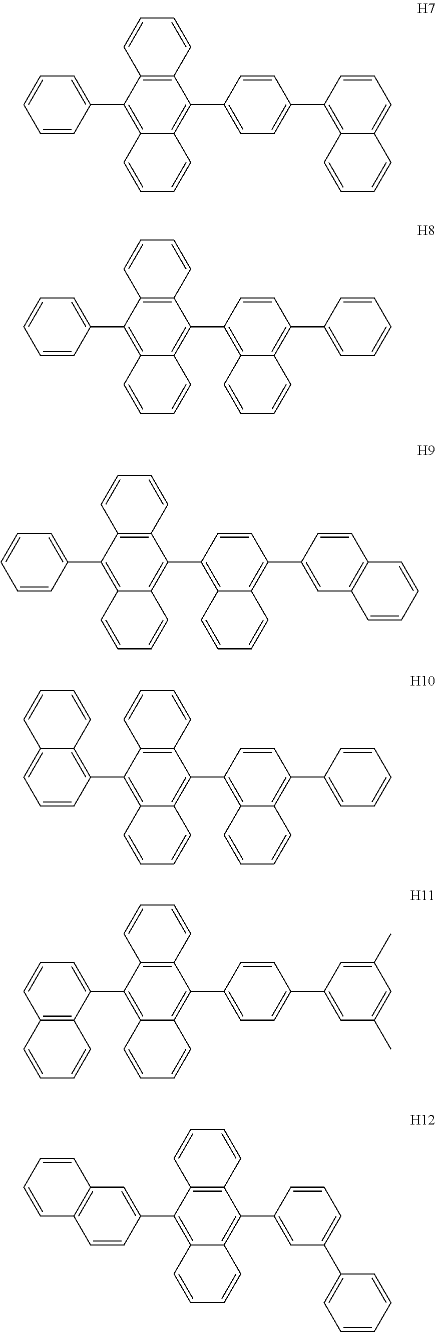

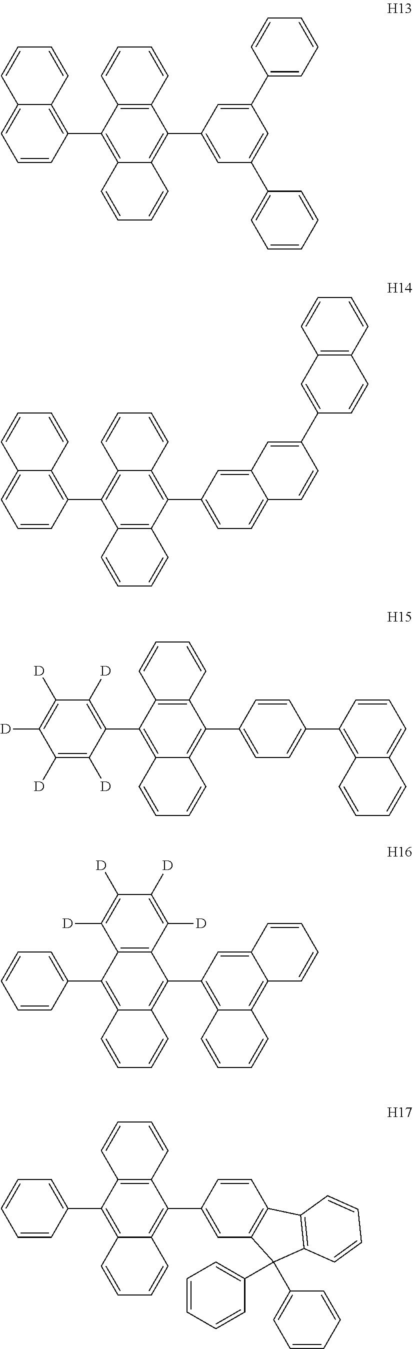

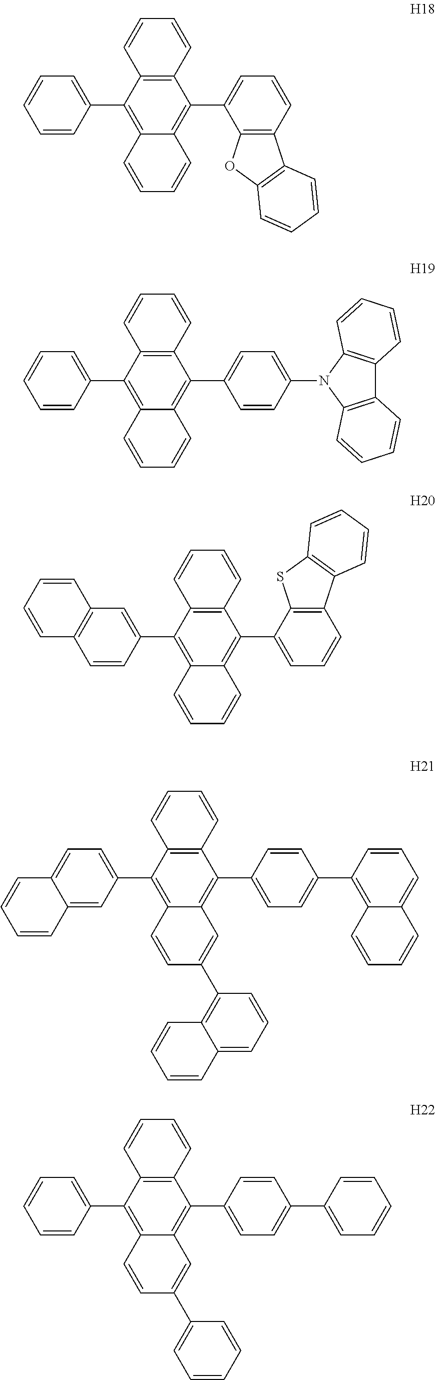

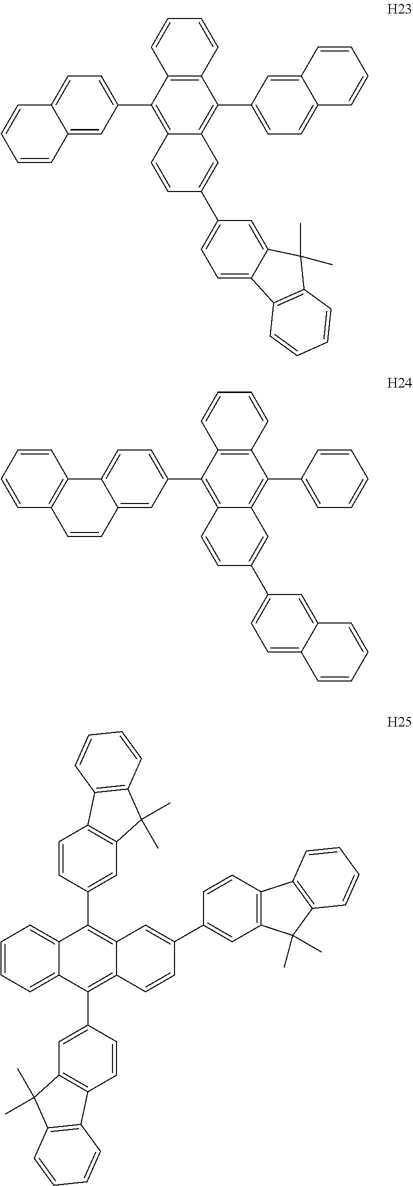

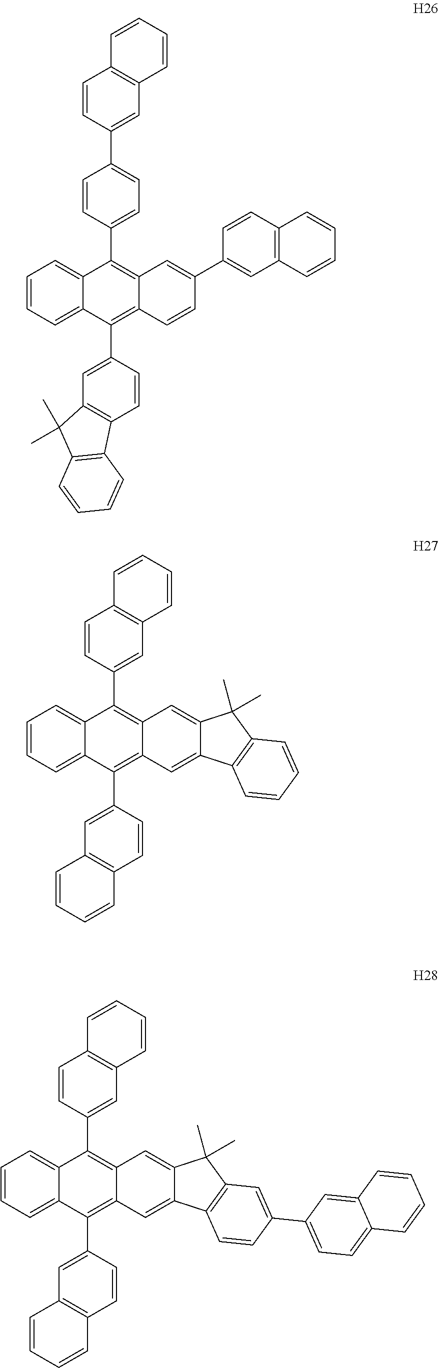

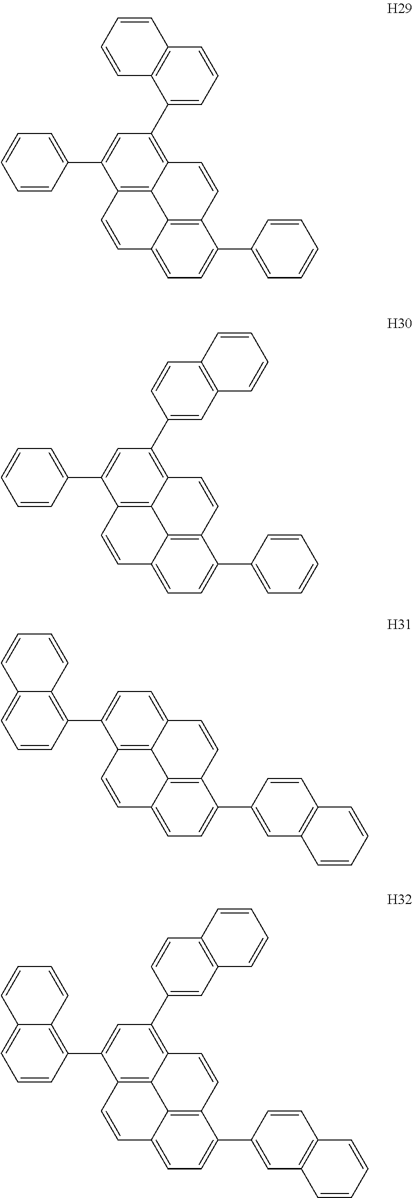

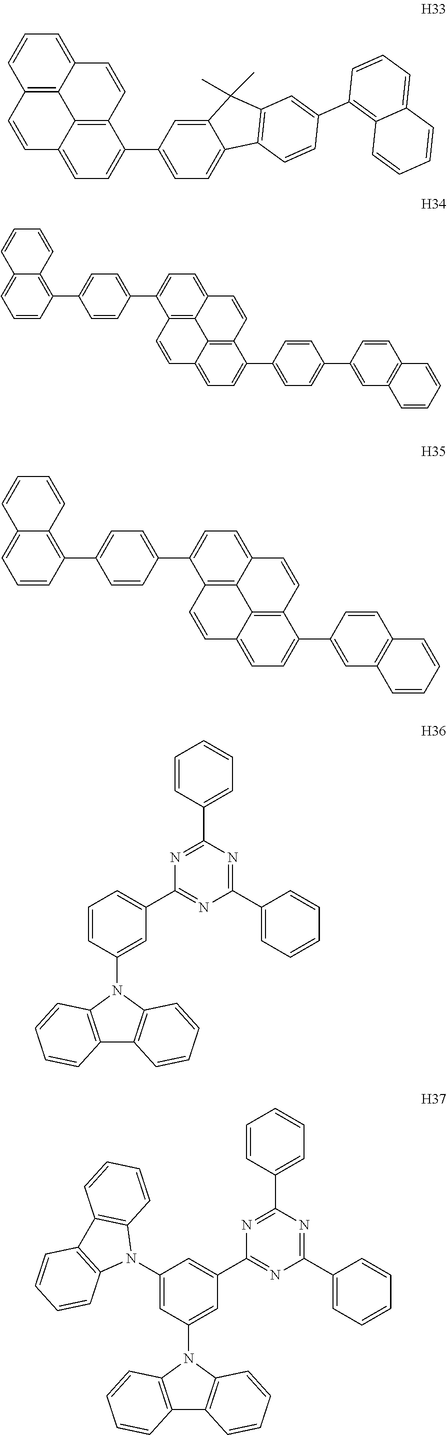

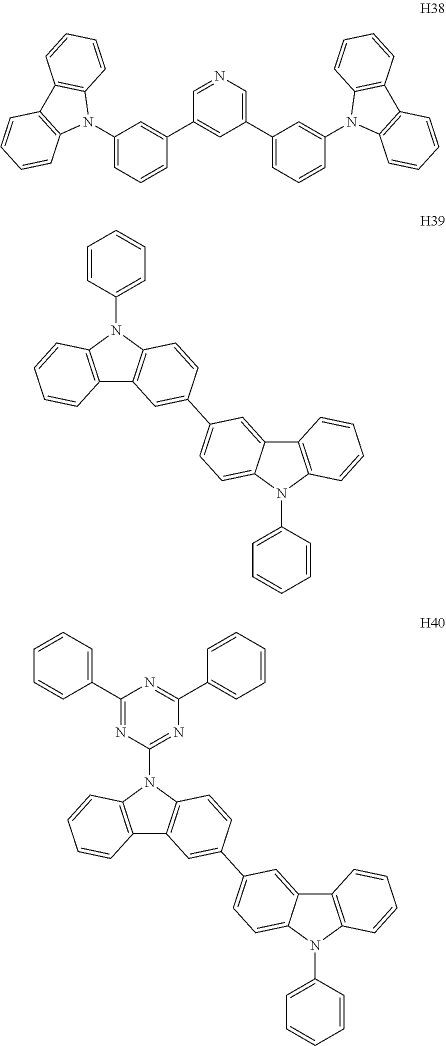 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

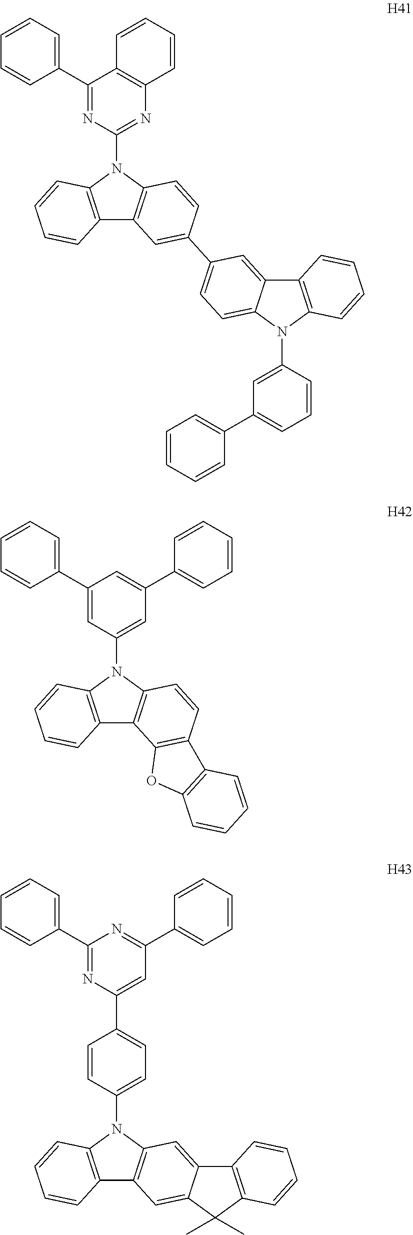

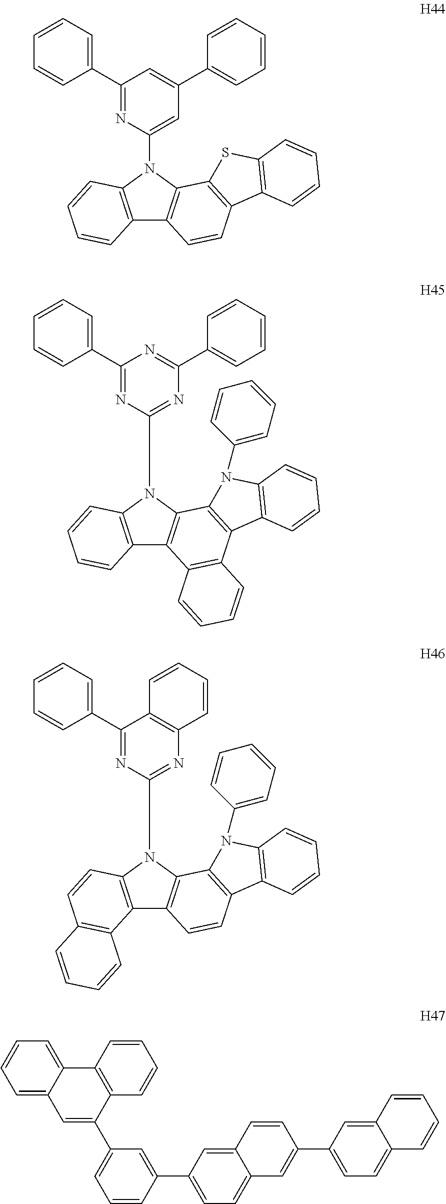

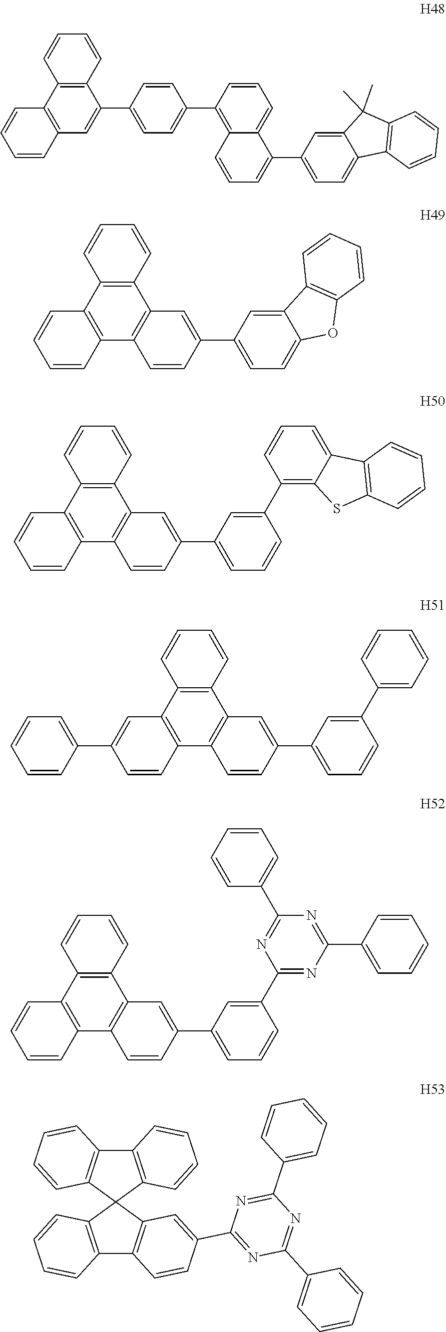

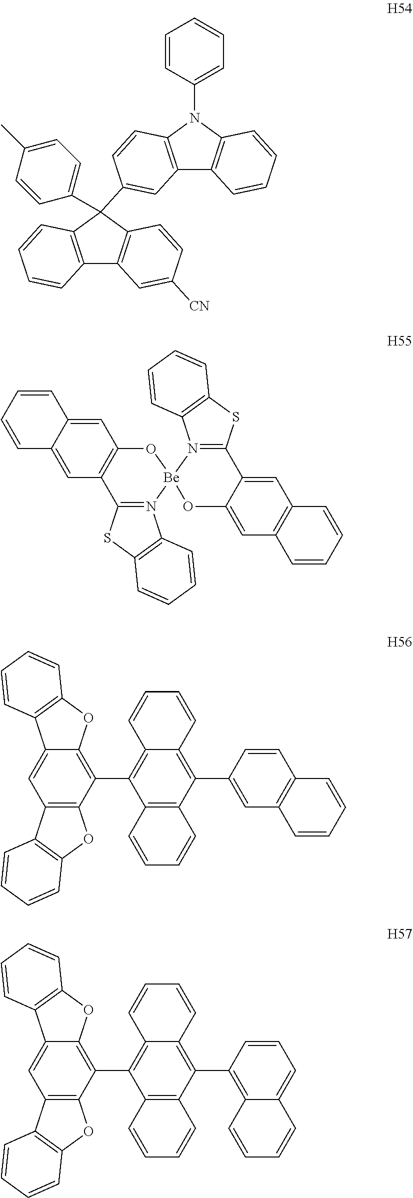

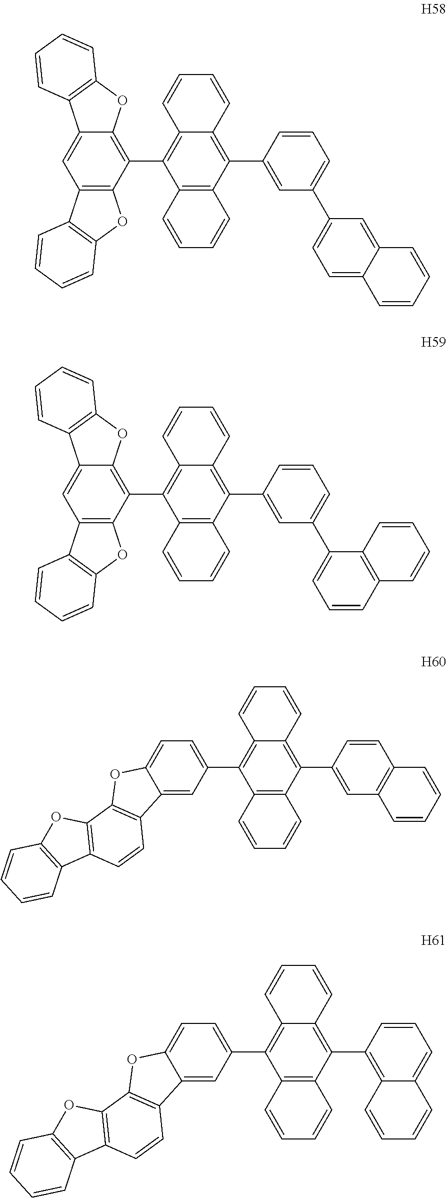 [SMILES: c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

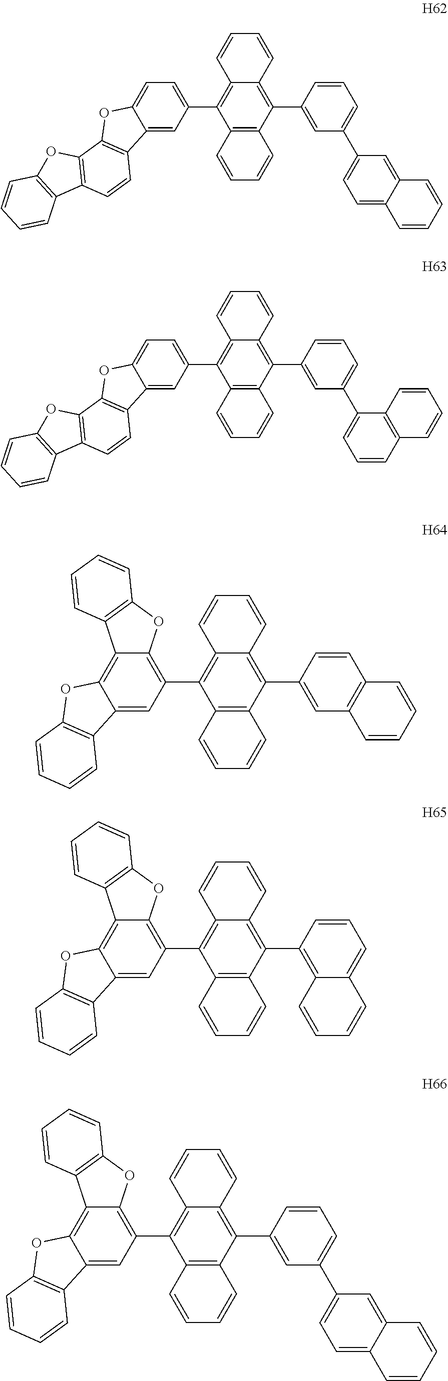

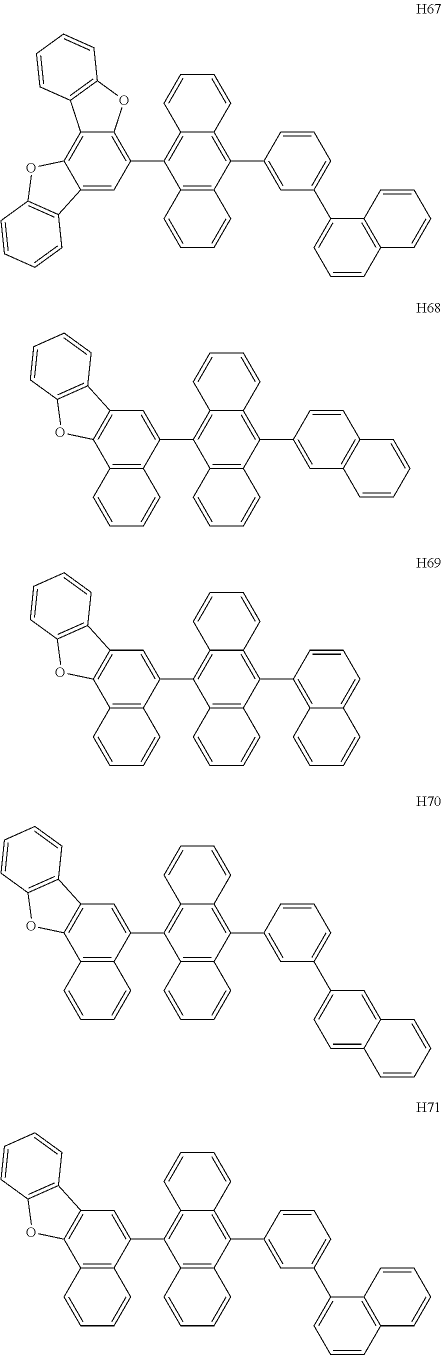 [SMILES: c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1]

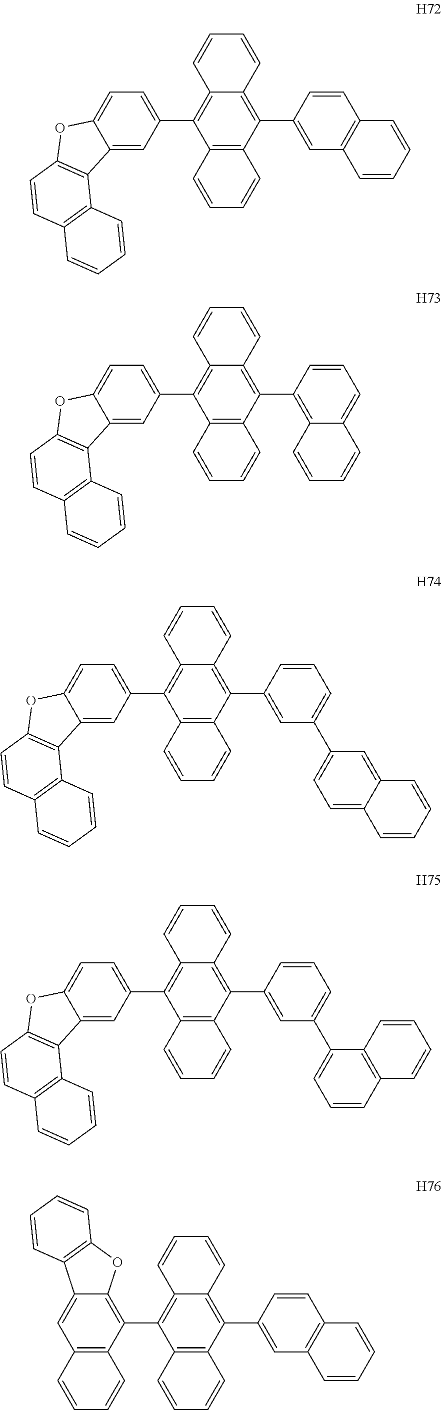 [SMILES: c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1]

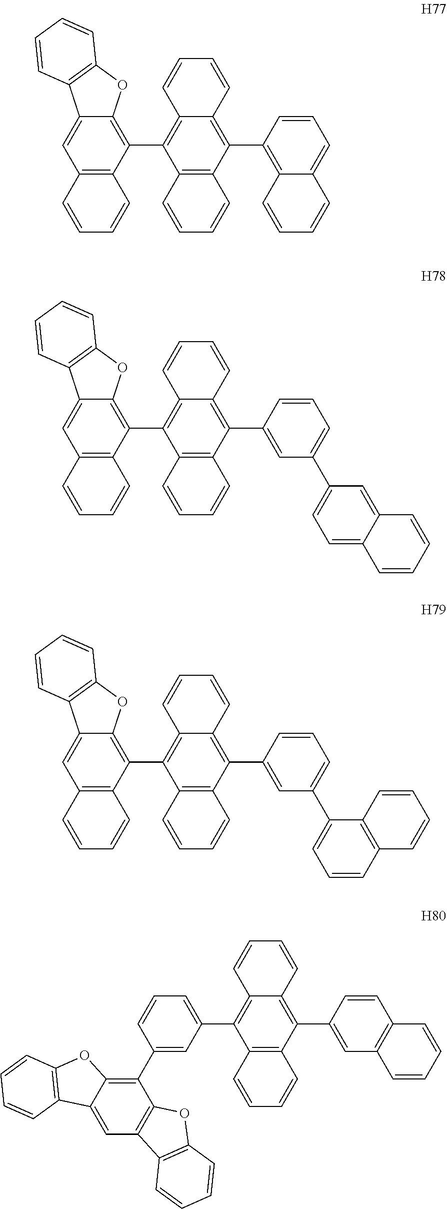 [SMILES: c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1]

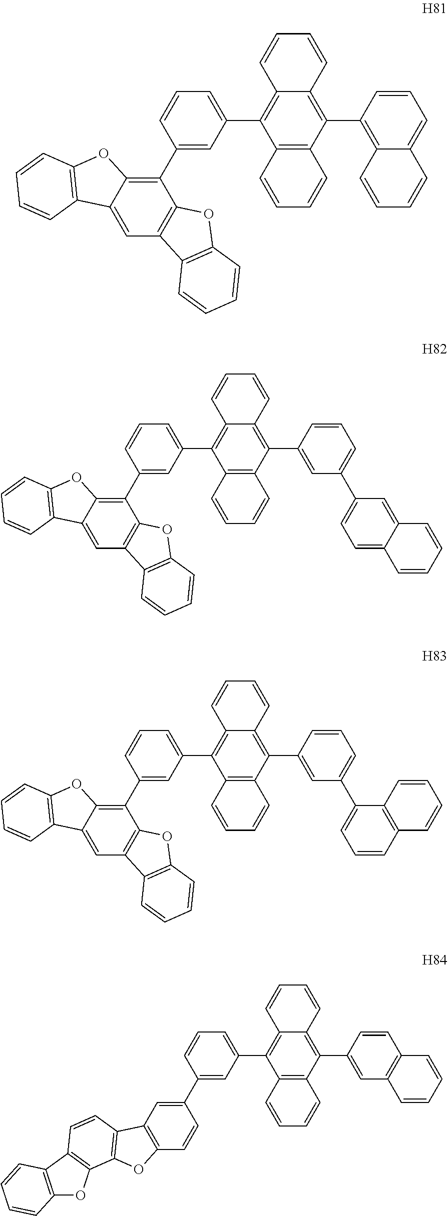 [SMILES: c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1]

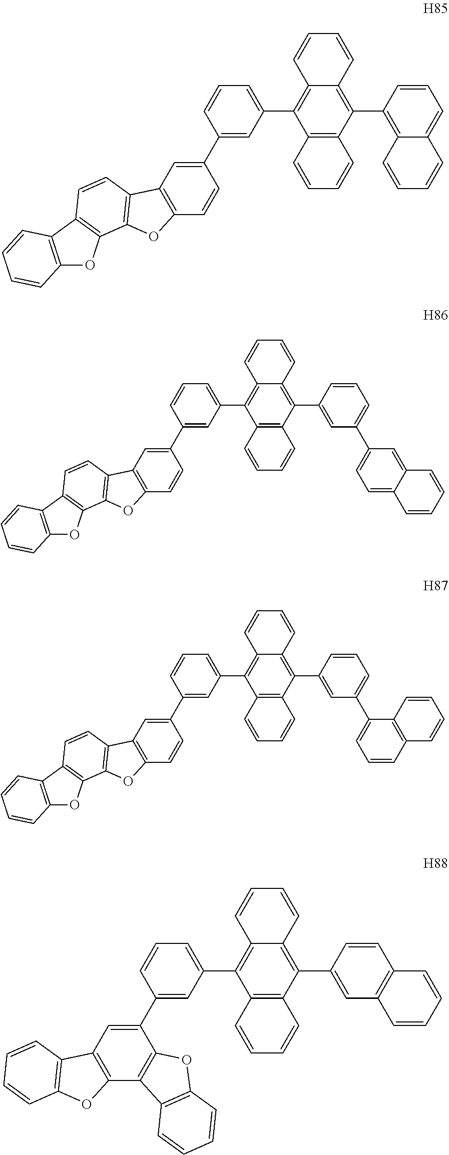 [SMILES: c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1]

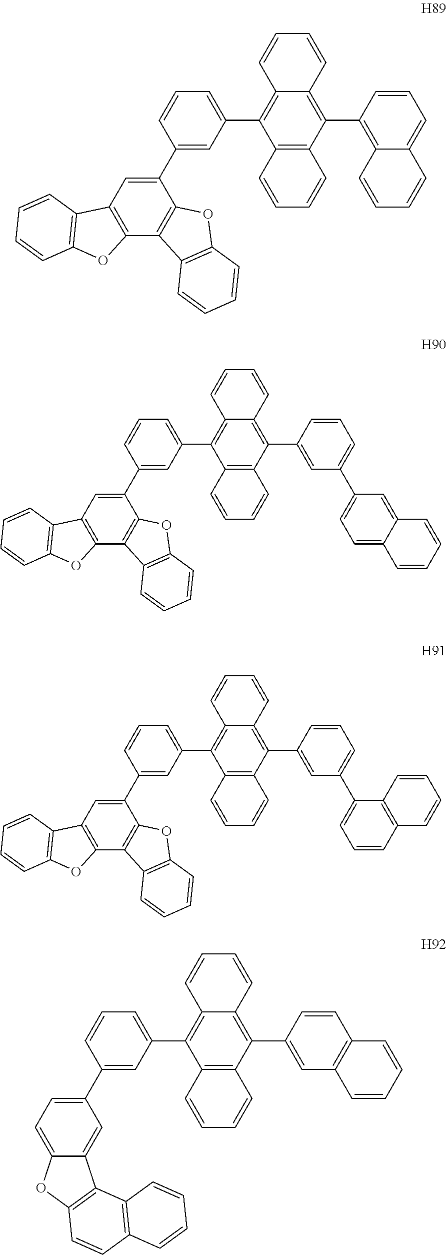 [SMILES: c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1]

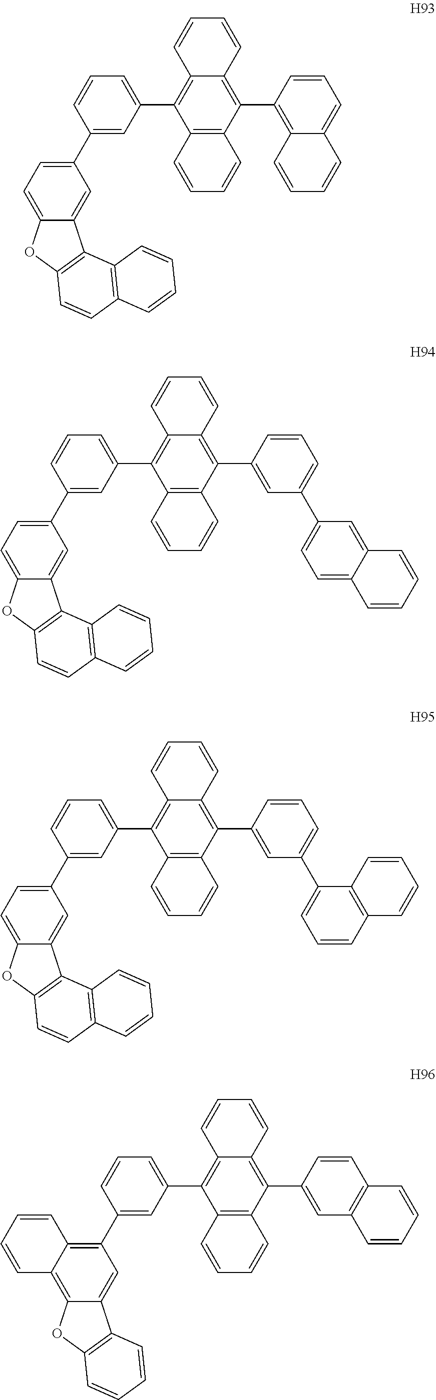 [SMILES: c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1]

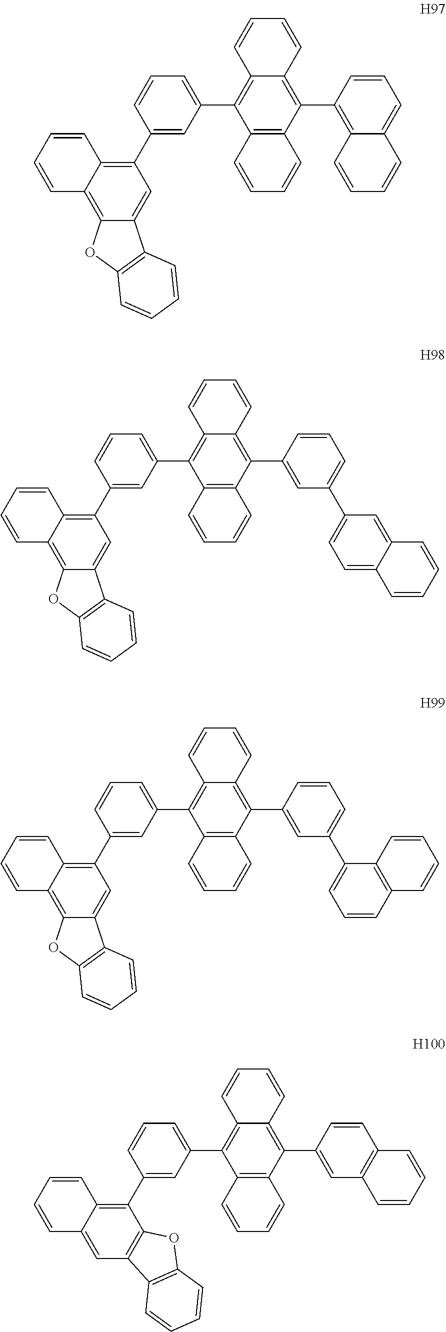 [SMILES: c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1]

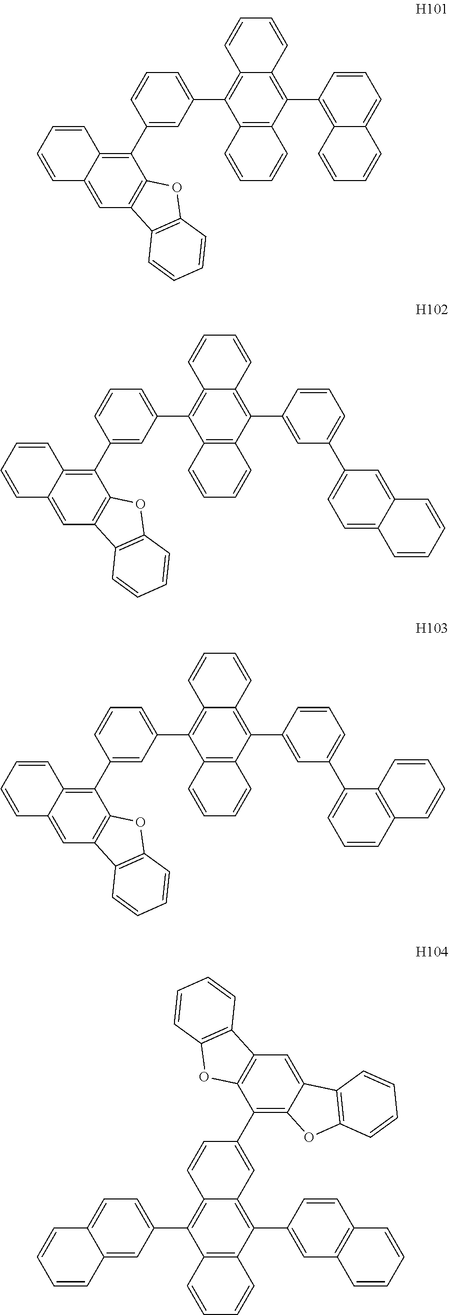 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

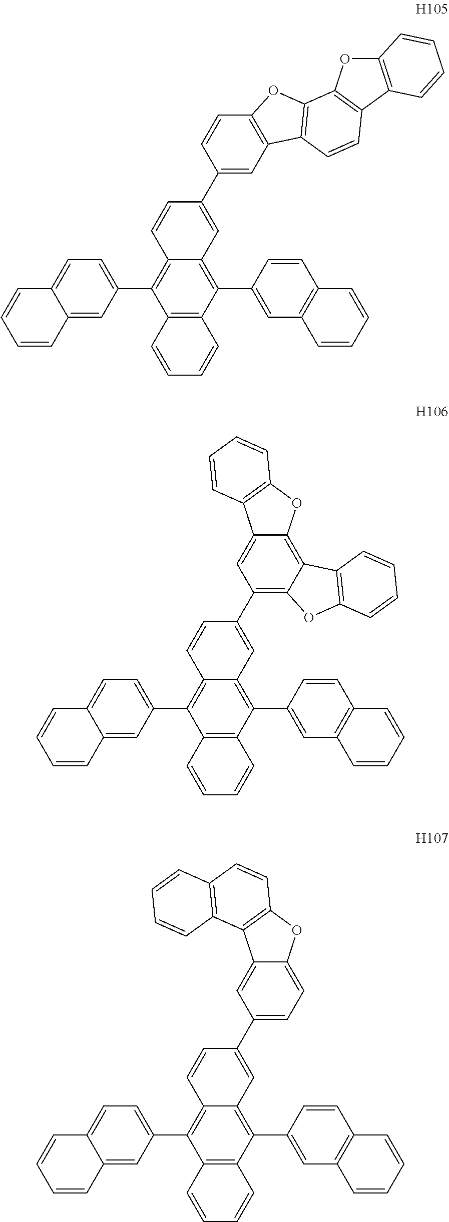 [SMILES: c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1]

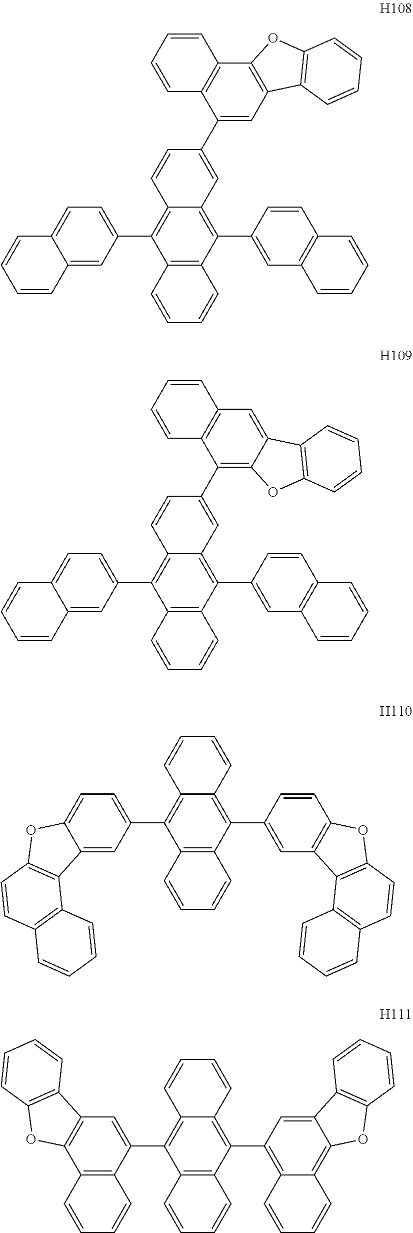 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

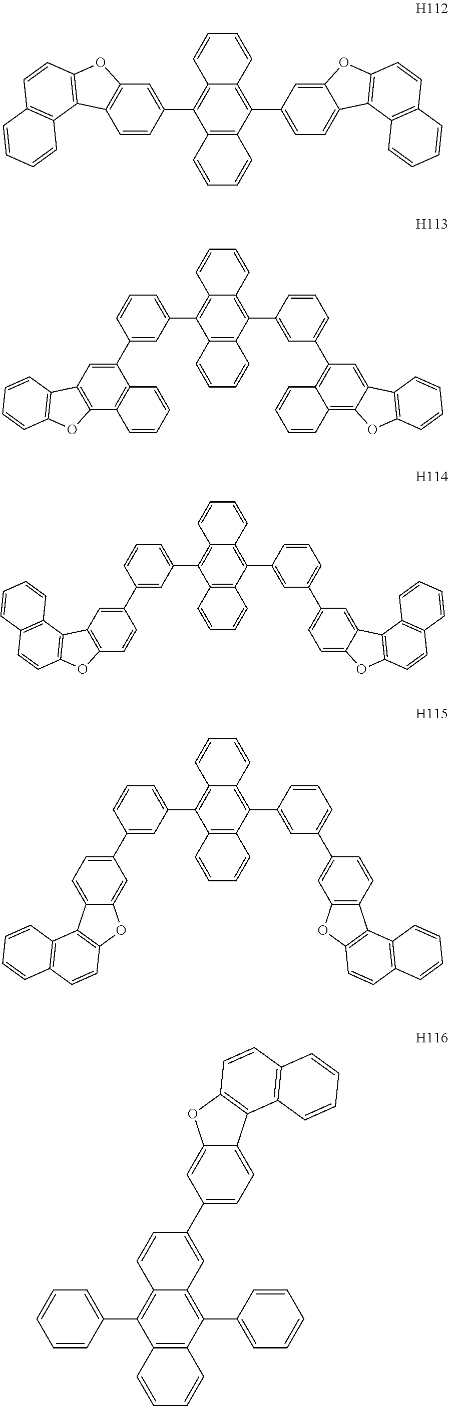 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

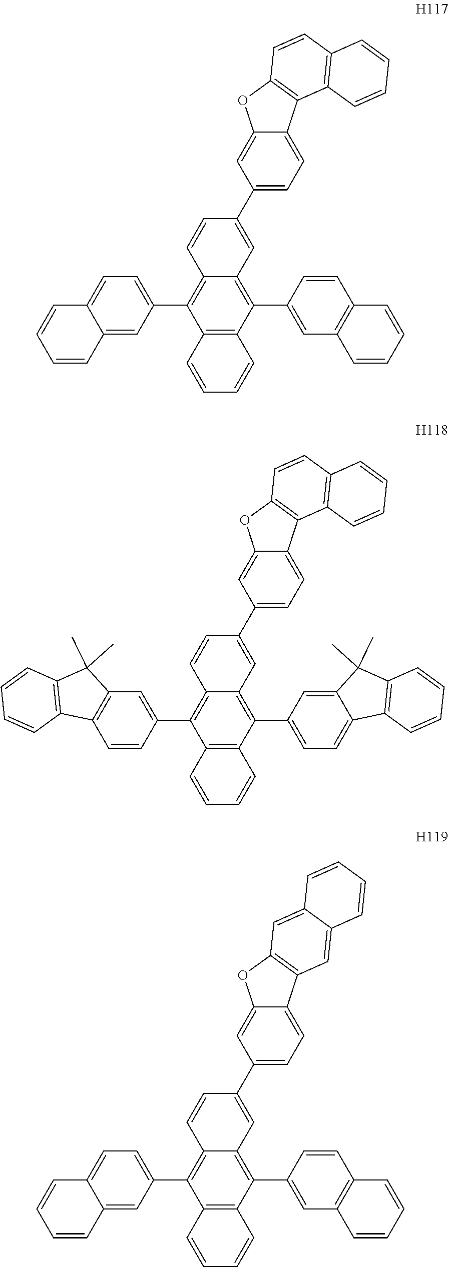 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1]

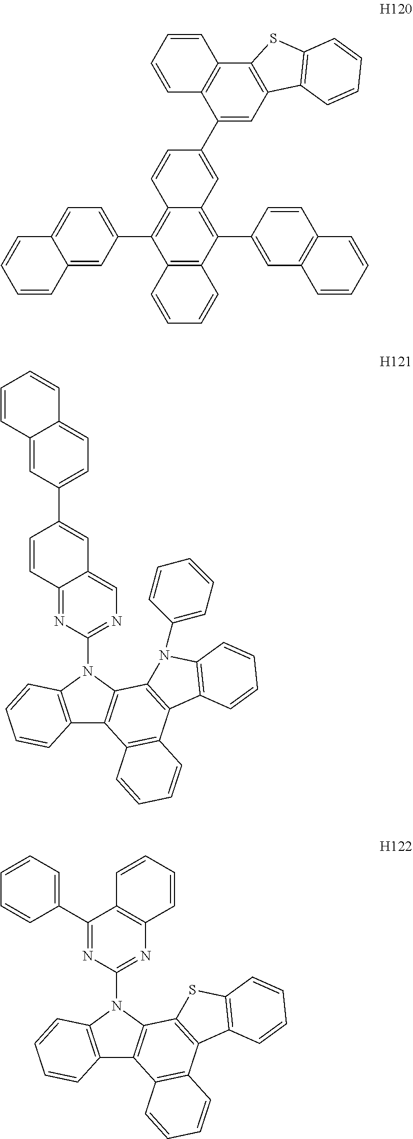 [SMILES: c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1]

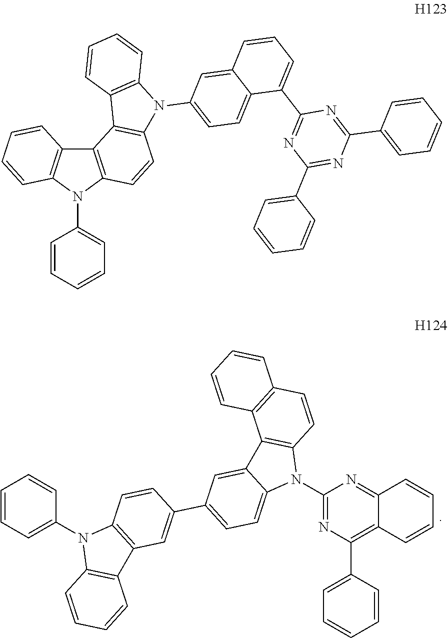 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

[Phosphorescent Dopant]

In one or more embodiments, the phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

For example, the phosphorescent dopant may include an organometallic compound represented by Formula 401:

M(L₄₀₁)_{xc1}(L₄₀₂)_{xc2} Formula 401

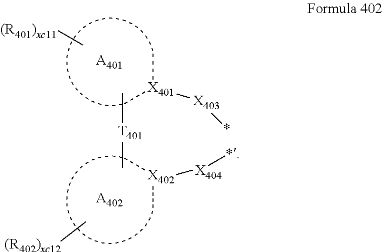

In Formulae 401 and 402,

M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),

L₄₀₁ may be a ligand represented by Formula 402, and xc1 may be 1, 2, or 3, and in case that xc1 is two or more, two or more of L₄₀₁(s) may be identical to or different from each other,

L₄₀₂ may be an organic ligand, and xc2 may be 0, 1, 2, 3, or 4, and in case that xc2 is 2 or more, two or more of L₄₀₂(s) may be identical to or different from each other,

X₄₀₁ and X₄₀₂ may each independently be nitrogen or carbon,

ring A₄₀₁ and ring A₄₀₂ may each independently be a C₃-C₆₀ carbocyclic group or a C₁-C₆₀ heterocyclic group,

T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C(Q₄₁₁)=*′,

X₄₀₃ and X₄₀₄ may each independently be a chemical bond (for example, a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),

Q₄₁₁ to Q₄₁₄ may each be the same as described herein with respect to Q₁,

R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

Q₄₀₁ to Q₄₀₃ may each be the same as described herein with respect to Q₁,

xc11 and xc12 may each independently be an integer from 0 to 10, and

* and *¹ in Formula 402 each indicate a binding site to M in Formula 401.

For example, in Formula 402, i) X₄₀₁ may be nitrogen, and X₄₀₂ may be carbon, or ii) X₄₀₁ and X₄₀₂ may each be nitrogen.

In one or more embodiments, in case that xc1 in Formula 402 is 2 or more, two ring A₄₀₁(s) in two or more of L₄₀₁(s) may be optionally linked to each other via T₄₀₂, which is a linking group, and two ring A₄₀₂(s) may be optionally linked to each other via T₄₀₃, which is a linking group (see Compounds PD1 to PD4 and PD7). T₄₀₂ and T₄₀₃ may each be the same as described herein with respect to T₄₀₁.

L₄₀₂ in Formula 401 may be an organic ligand. For example, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, etc.), or any combination thereof.

The phosphorescent dopant may include, for example, one of compounds PD1 to PD39, or any combination thereof:

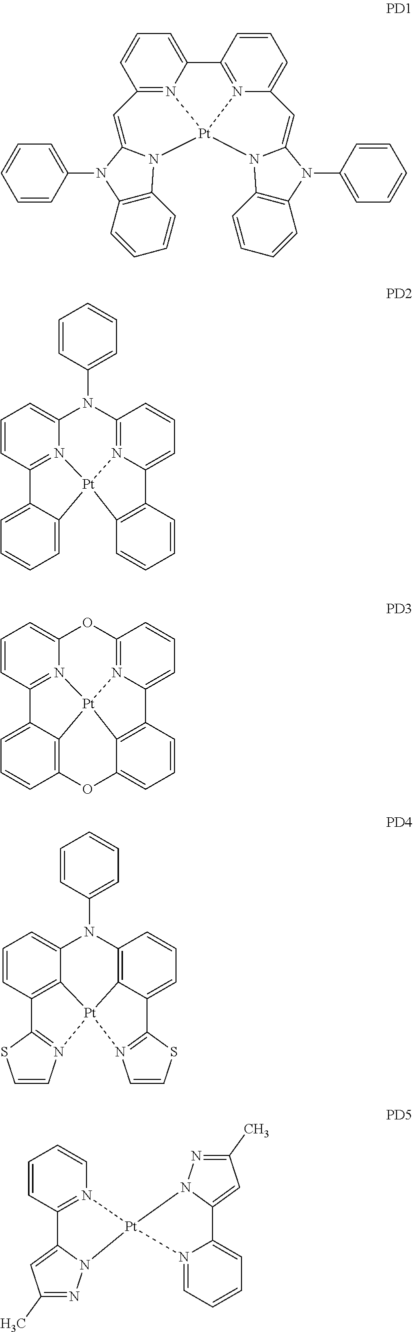

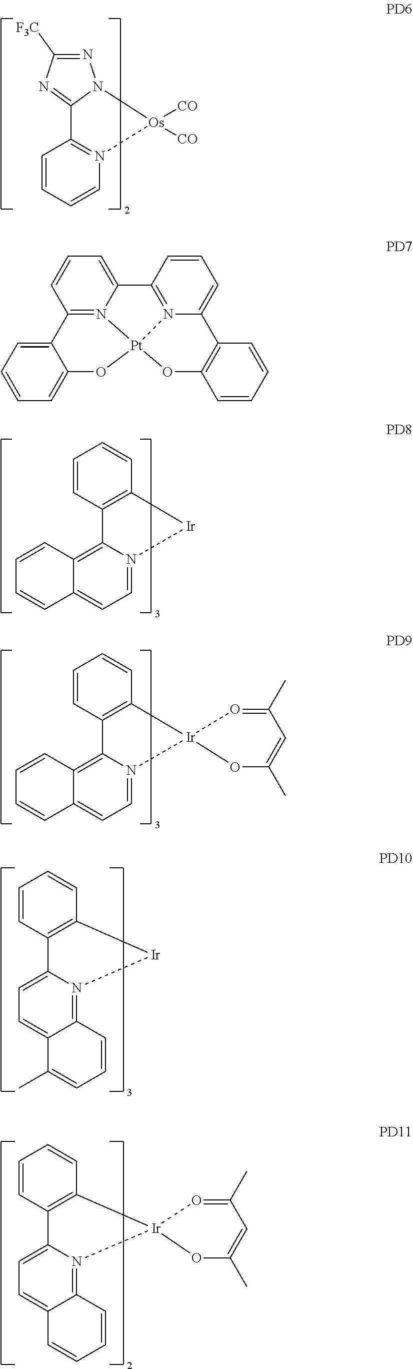

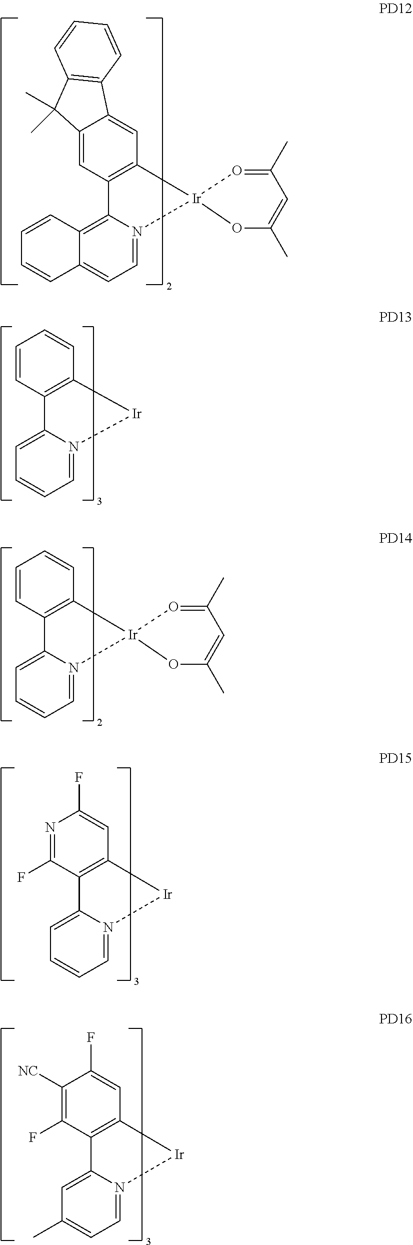

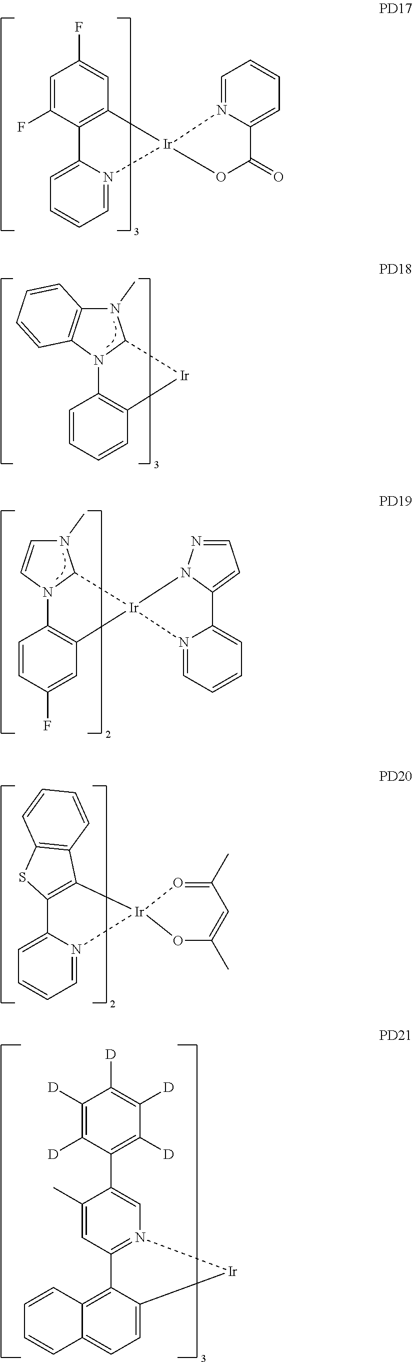

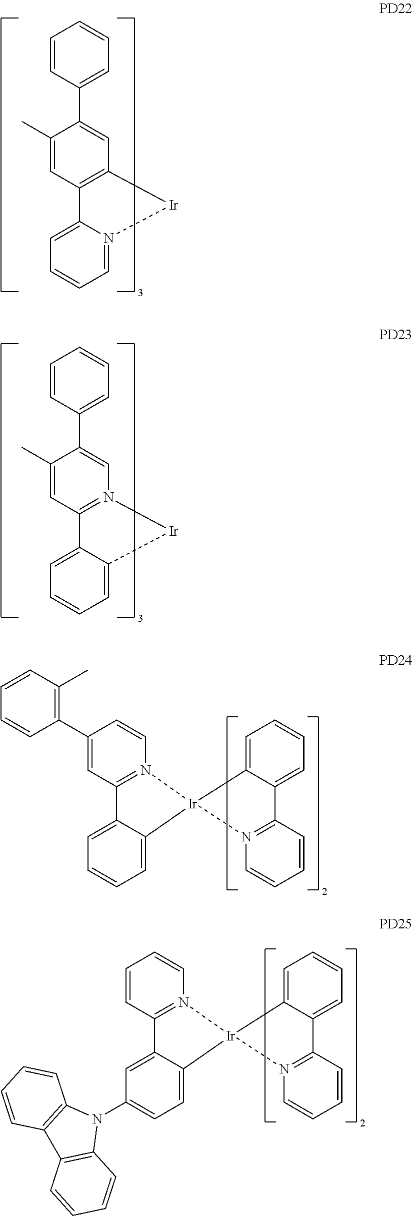

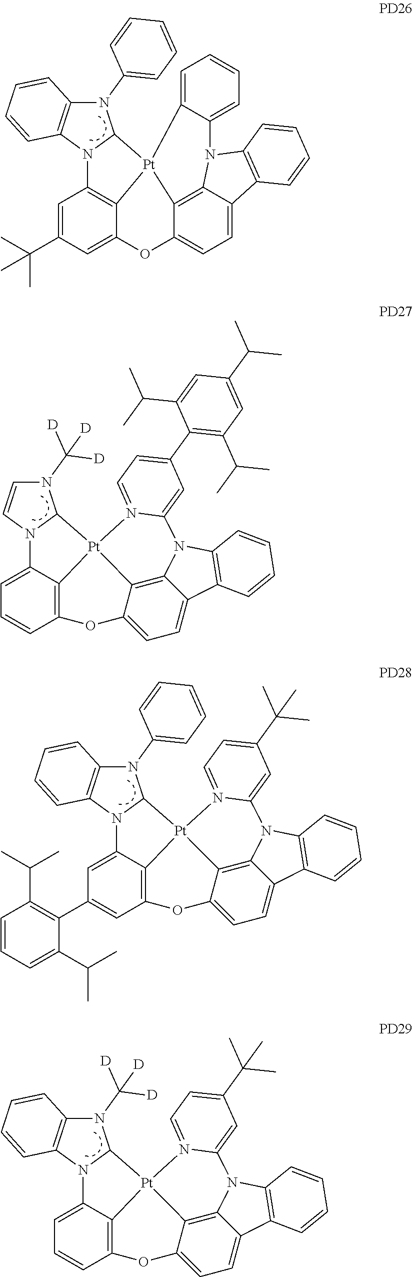

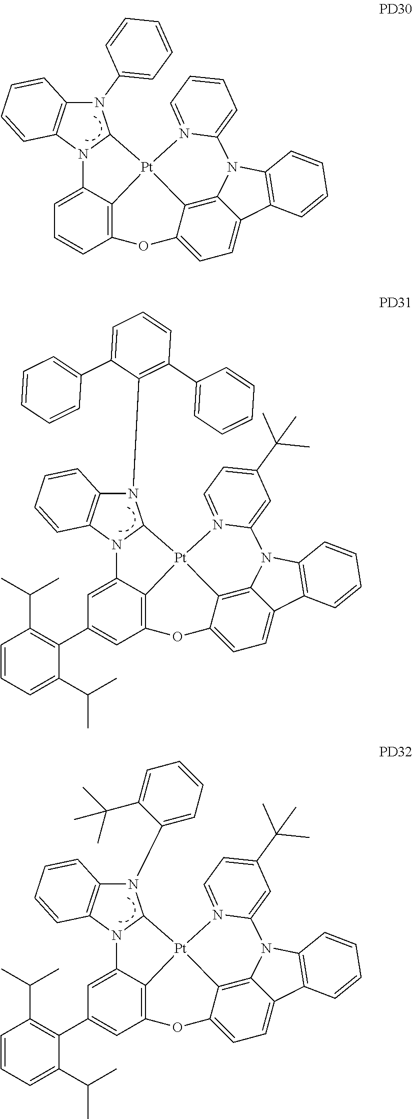

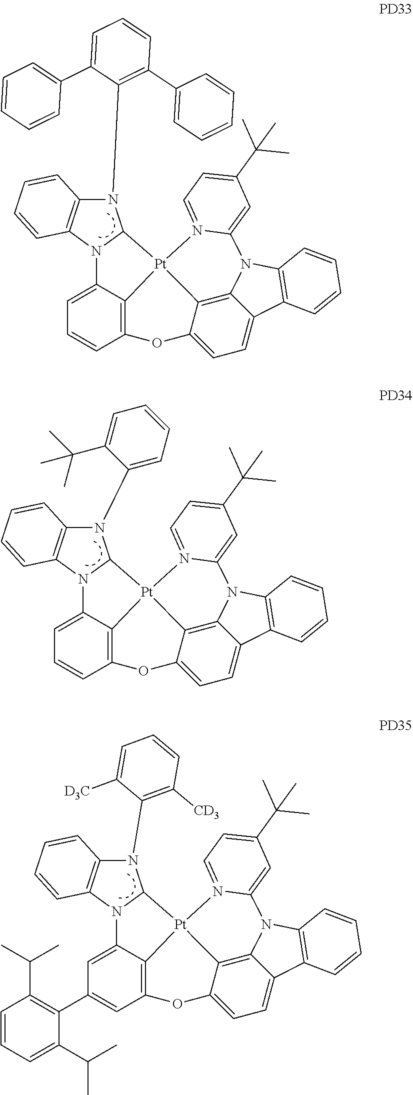

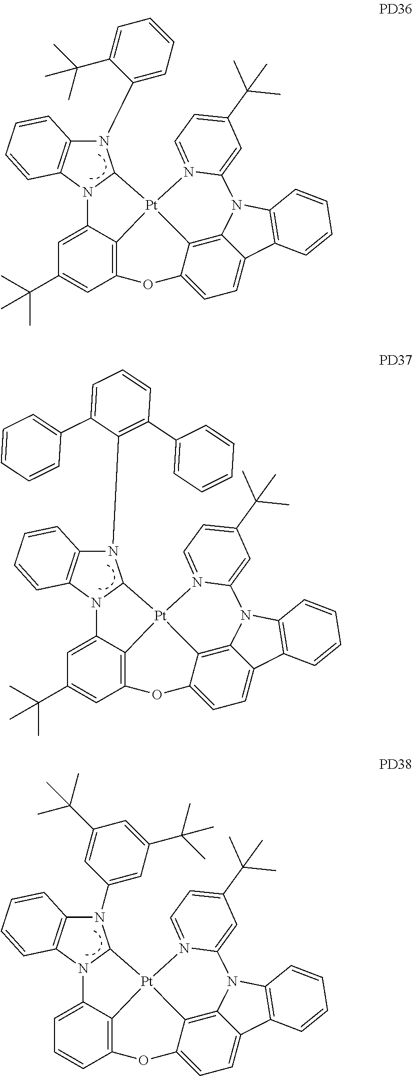

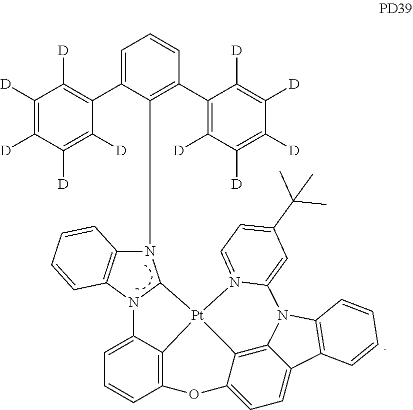

[Fluorescence Dopant]

The fluorescence dopant may include an amine group-containing compound, a styryl group-containing compound, or any combination thereof.

For example, the fluorescence dopant may include a compound represented by Formula 501:

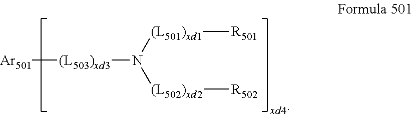

In Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

For example, Ar₅₀₁ in Formula 501 may be a condensed cyclic group (for example, an anthracene group, a chrysene group, or a pyrene group) in which three or more monocyclic groups are condensed together.

In one or more embodiments, xd4 in Formula 501 may be 2.

For example, the fluorescence dopant may include one of Compounds FD1 to FD36, DPVBi, DPAVBi, or any combination thereof:

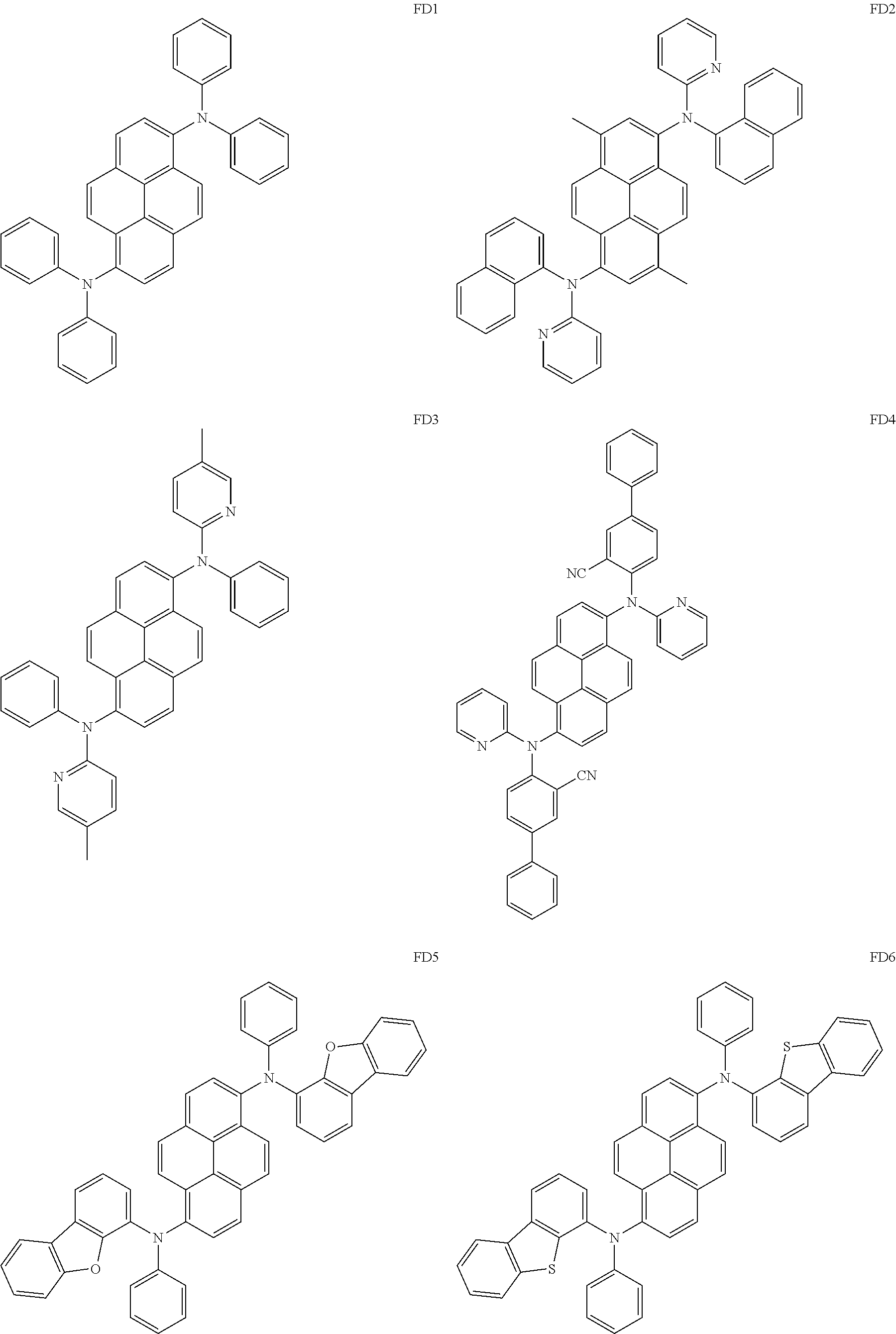

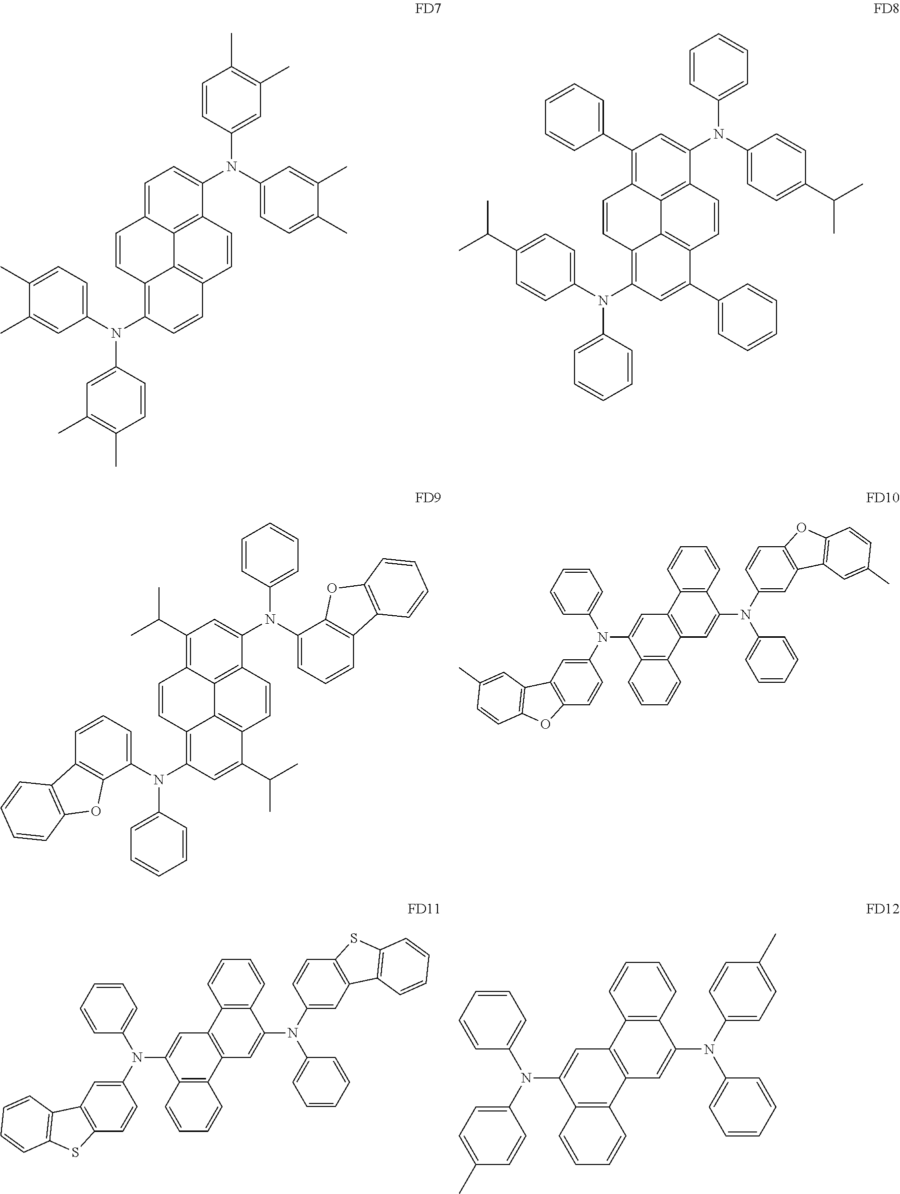

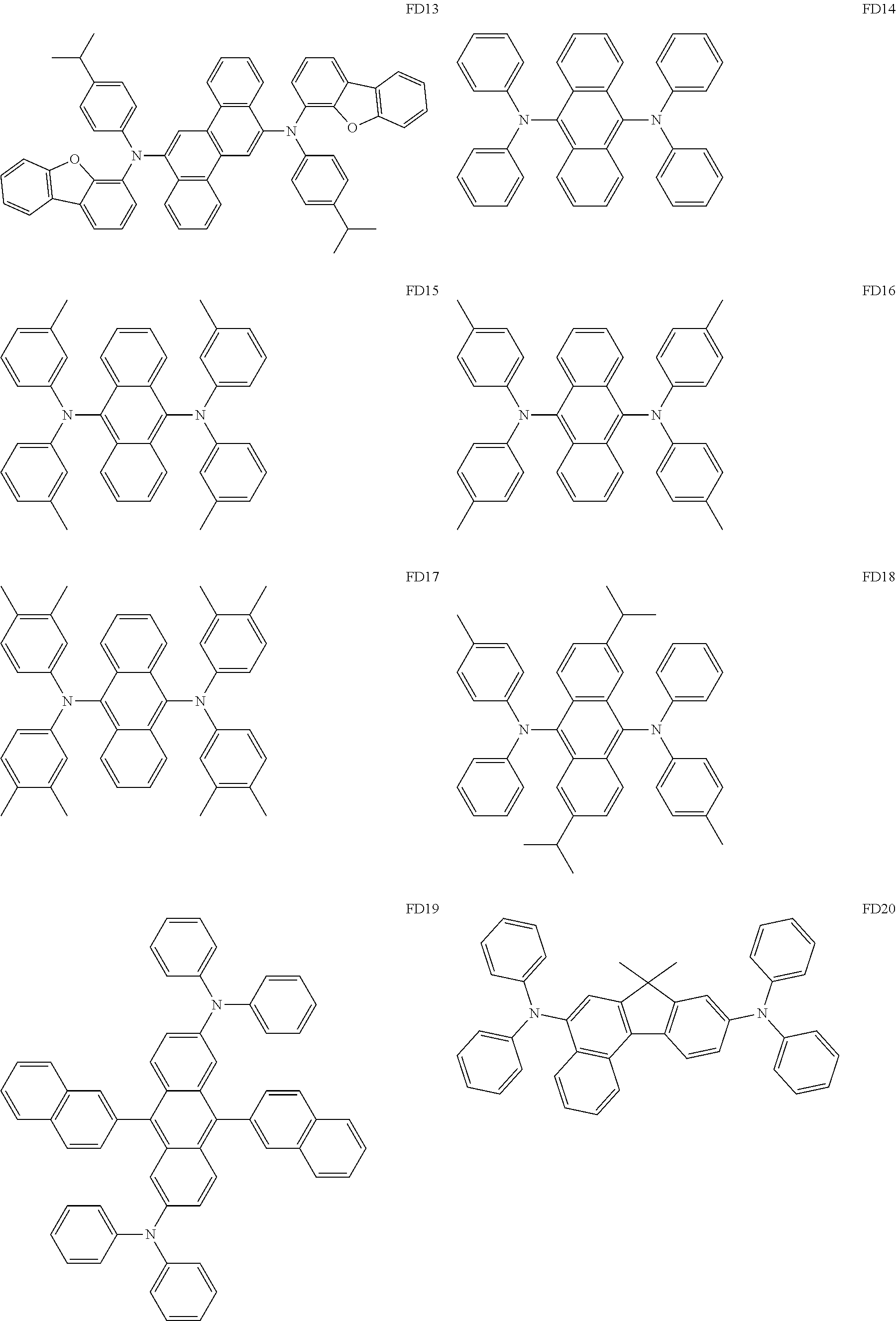

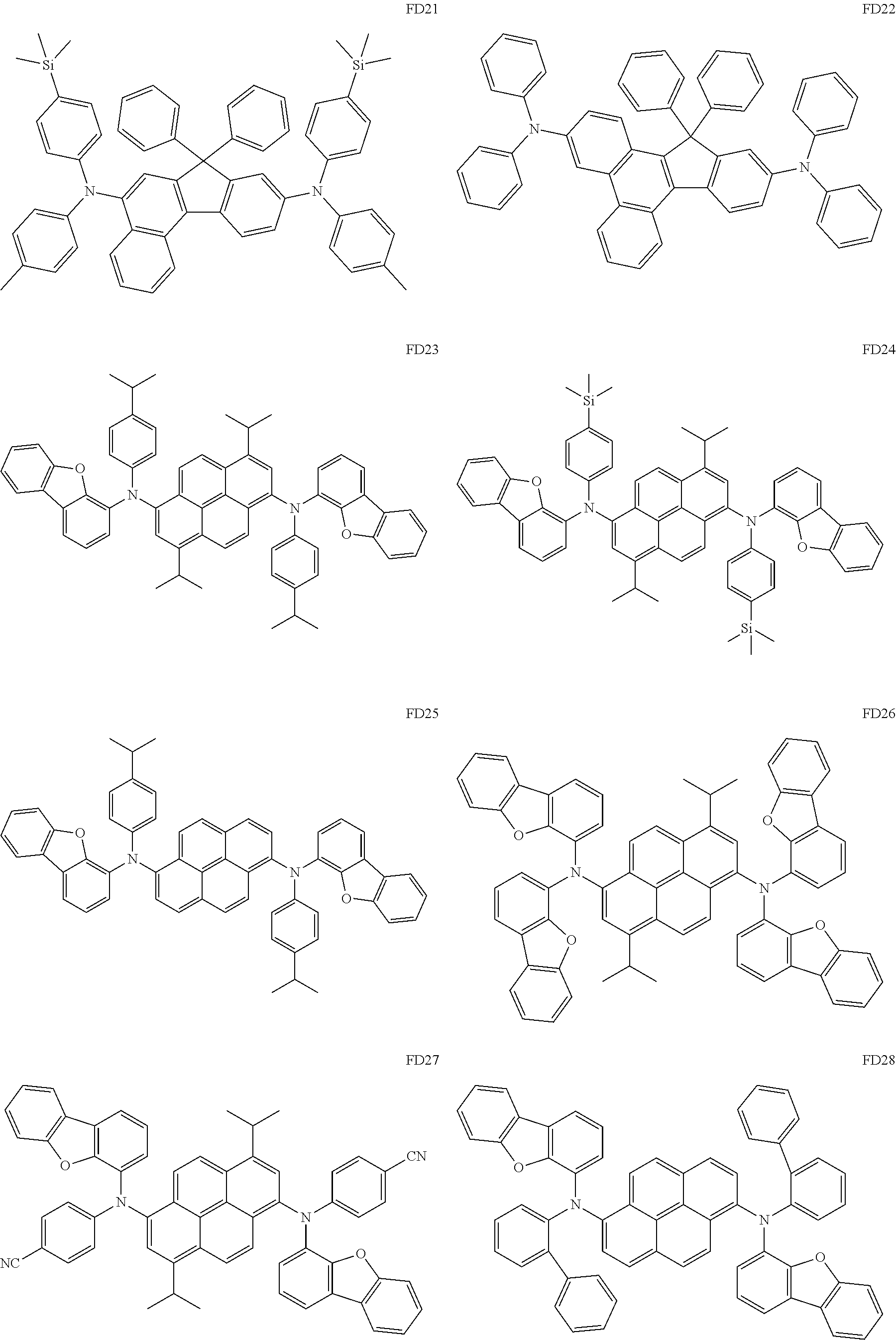

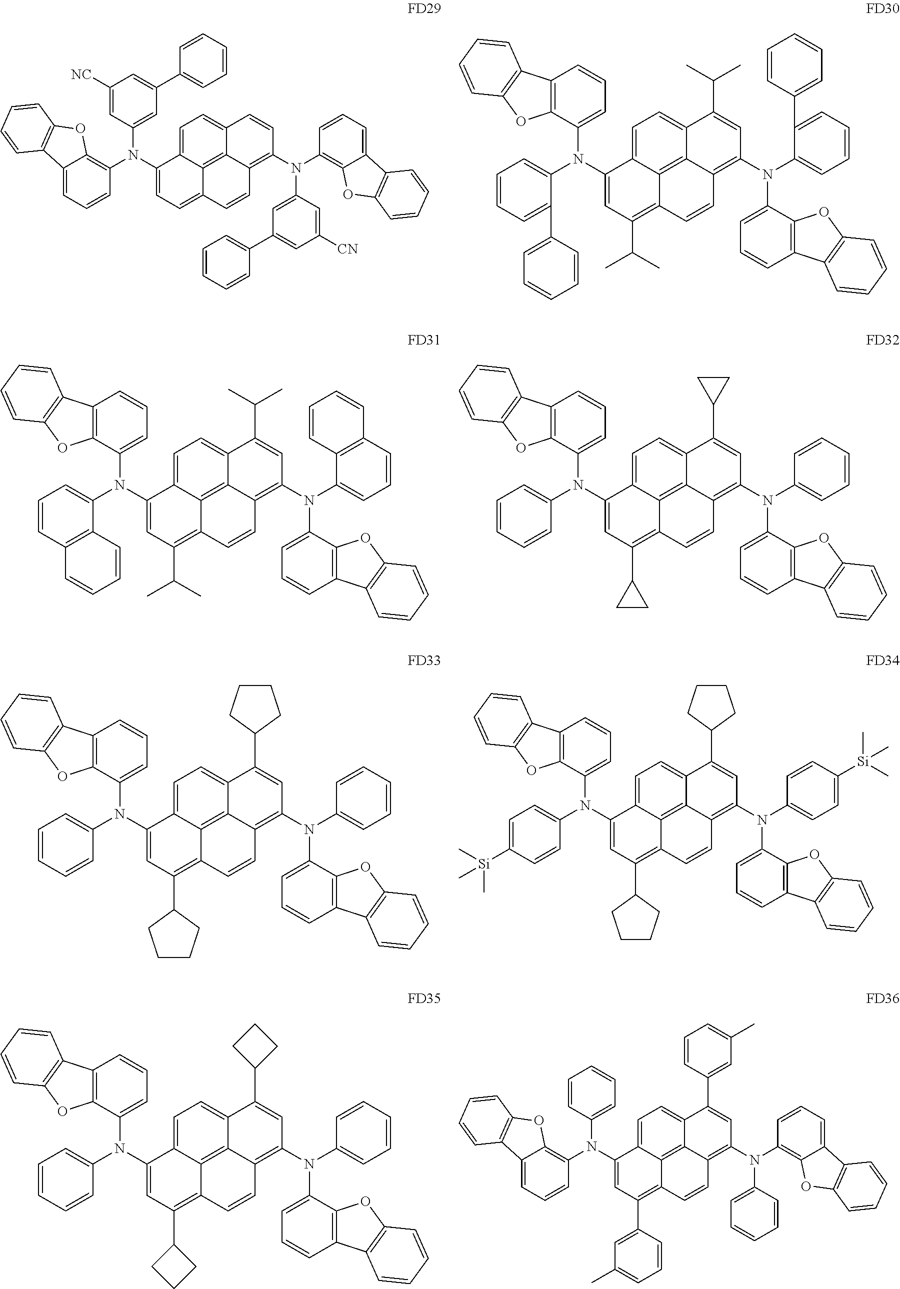

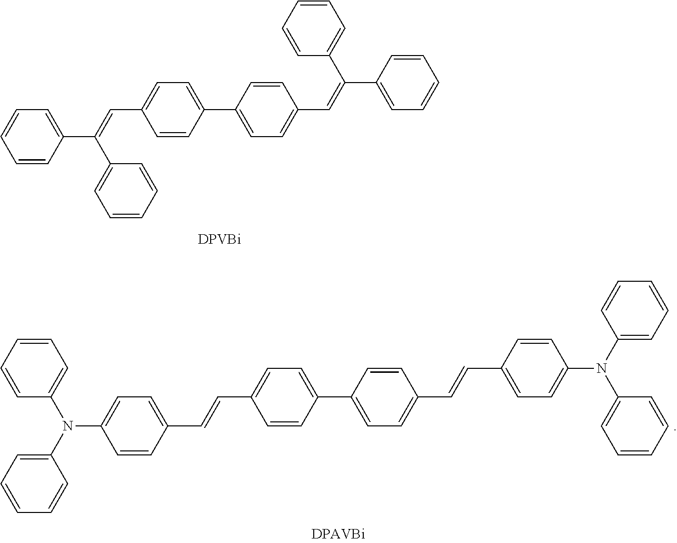

[Delayed Fluorescence Material]

In one or more embodiments, the emission layers 152-1 and 152-2 may include a delayed fluorescence material.

In the specification, the delayed fluorescence material may be selected from compounds capable of emitting delayed fluorescence light based on a delayed fluorescence emission mechanism.

The delayed fluorescence material included in the emission layers 152-1 and 152-2 may act as a host or a dopant, depending on the type of other materials included in the emission layers.

In one or more embodiments, the difference between the triplet energy level (eV) of the delayed fluorescence material and the singlet energy level (eV) of the delayed fluorescence material may be greater than or equal to about 0 eV and less than or equal to about 0.5 eV. In case that the difference between the triplet energy level (eV) of the delayed fluorescence material and the singlet energy level (eV) of the delayed fluorescence material satisfies the above-described range, up-conversion from the triplet state to the singlet state of the delayed fluorescence materials may effectively occur, and thus, the luminescence efficiency of the light-emitting device 10 may be improved.

For example, the delayed fluorescence material may include i) a material including at least one electron donor (for example, a π electron-rich C₃-C₆₀ cyclic group, such as a carbazole group) and at least one electron acceptor (for example, a sulfoxide group, a cyano group, or a π electron-deficient nitrogen-containing C₁-C₆₀ cyclic group), and ii) a material including a C₈-C₆₀ polycyclic group in which two or more cyclic groups are condensed while sharing boron (B).

Examples of the delayed fluorescence material may include at least one of the following compounds DF1 to DF9:

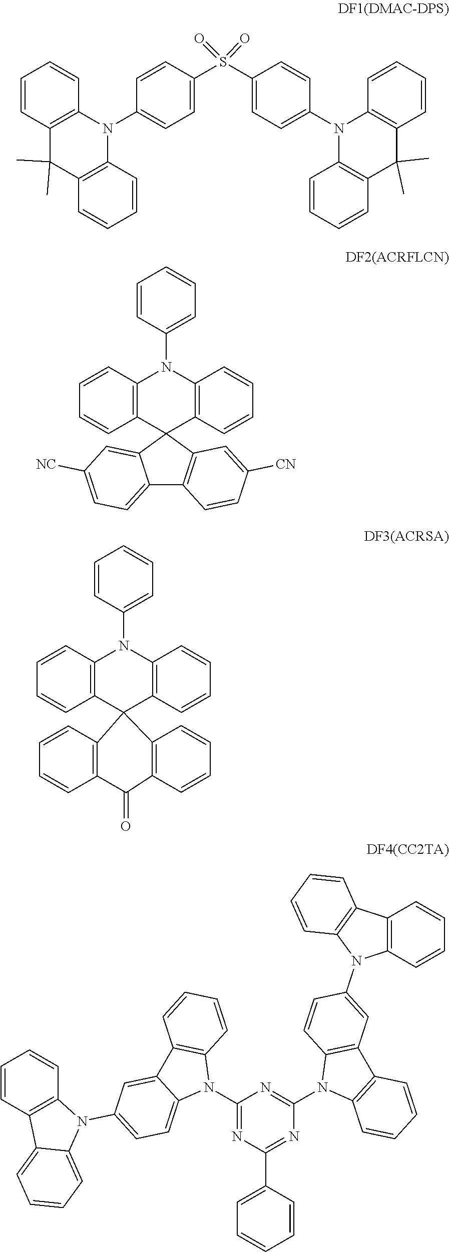

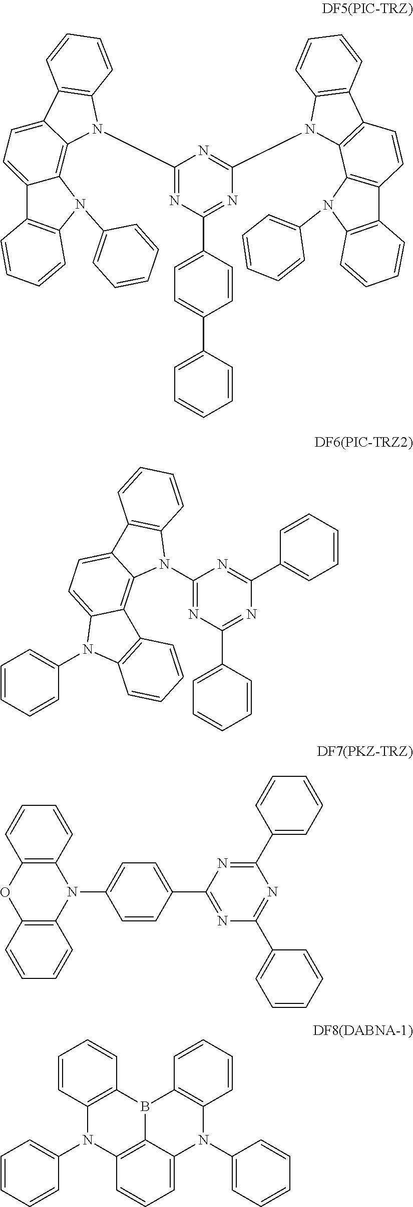 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1 ; c1ccc(N2c3ccccc3B3c4ccccc4N(c4ccccc4)c4cccc2c43)cc1]

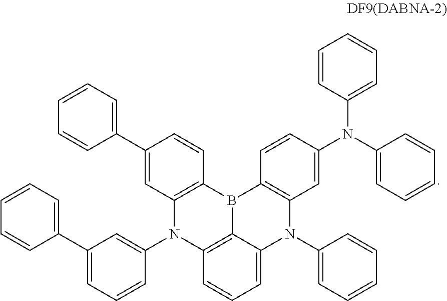 [SMILES: c1ccc(-c2cccc(N3c4cc(-c5ccccc5)ccc4B4c5ccc(N(c6ccccc6)c6ccccc6)cc5N(c5ccccc5)c5cccc3c54)c2)cc1]

[Quantum Dot]

In one or more embodiments, the emission layers 152-1 and 152-2 may include quantum dots.

The term “quantum dot” as used herein refers to a crystal of a semiconductor compound, and may include any material capable of emitting light of various emission wavelengths according to the size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method including mixing a precursor material with an organic solvent and growing a quantum dot particle crystal. In case that the crystal grows, the organic solvent naturally acts as a dispersant coordinated on the surface of the quantum dot crystal and controls the growth of the crystal so that the growth of quantum dot particles can be controlled through a process which costs lower and is easier than vapor deposition methods, such as metal organic chemical vapor deposition (MOCVD) or molecular beam epitaxy (MBE).

The quantum dot may include a Group II-VI semiconductor compound, a Group III-V semiconductor compound, a Group III-VI semiconductor compound, a Group semiconductor compound, a Group IV-VI semiconductor compound, a Group IV element or compound, or any combination thereof.

Examples of the Group II-VI semiconductor compound may include a binary compound, such as CdSe, CdTe, ZnS, ZnSe, ZnTe, ZnO, HgS, HgSe, HgTe, MgSe, or MgS, a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a quaternary compound, such as CdZnSeS, CdZnSeTe, CdZnSTe, CdHgSeS, CdHgSeTe, CdHgSTe, HgZnSeS, HgZnSeTe, or HgZnSTe, or any combination thereof.

Examples of the Group III-V semiconductor compound may include a binary compound, such as GaN, GaP, GaAs, GaSb, AlN, AlP, AlAs, AlSb, InN, InP, InAs, or InSb, a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb, a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, or any combination thereof. The Group III-V semiconductor compound may further include a Group II element. Examples of the Group III-V semiconductor compound further including a Group II element are InZnP, InGaZnP, InAlZnP, etc.

Examples of the Group III-VI semiconductor compound may include a binary compound, such as GaS, GaSe, Ga₂Se₃, GaTe, InS, InSe, In₂S₃, In₂Se₃, or InTe, a ternary compound, such as InGaS₃, or InGaSe₃, and any combination thereof.

Examples of the Group I-III-VI semiconductor compound may include a ternary compound, such as AgInS, AgInS₂, CuInS, CuInS₂, CuGaO₂, AgGaO₂, or AgAlO₂, or any combination thereof.

Examples of the Group IV-VI semiconductor compound may include a binary compound, such as SnS, SnSe, SnTe, PbS, PbSe, or PbTe, a ternary compound, such as SnSeS, SnSeTe, SnSTe, PbSeS, PbSeTe, PbSTe, SnPbS, SnPbSe, or SnPbTe, a quaternary compound, such as SnPbSSe, SnPbSeTe, or SnPbSTe, or any combination thereof.

The Group IV element or compound may include a single element compound, such as Si or Ge, a binary compound, such as SiC or SiGe, or any combination thereof.

Each element included in a multi-element compound such as the binary compound, the ternary compound, and the quaternary compound may be present at a uniform concentration or non-uniform concentration in a particle.

The quantum dot may have a single structure in which the concentration of each element in the quantum dot is uniform, or a dual structure of a core and a shell. For example, the material included in the core and the material included in the shell may be different from each other.

The shell of the quantum dot may act as a protective layer that prevents chemical degeneration of the core to maintain semiconductor characteristics, and/or as a charging layer that imparts electrophoretic characteristics to the quantum dot. The shell may be single layered or multi-layered. The interface between the core and the shell may have a concentration gradient in which the concentration of an element existing in the shell decreases toward the center of the core.

Examples of the shell of the quantum dot may be an oxide of metal, metalloid, or non-metal, a semiconductor compound, and any combination thereof. Examples of the oxide of metal, metalloid, or non-metal may include a binary compound, such as SiO₂, Al₂O₃, TiO₂, ZnO, MnO, Mn₂O₃, Mn₃O₄, CuO, FeO, Fe₂O₃, Fe₃O₄, COO, Co₃O₄, or NiO, a ternary compound, such as MgAl₂O₄, CoFe₂O₄, NiFe₂O₄, or CoMn₂O₄, and any combination thereof. Examples of the semiconductor compound may include, as described herein, Group II-VI semiconductor compounds, Group III-V semiconductor compounds, Group III-VI semiconductor compounds, Group semiconductor compounds, Group IV-VI semiconductor compounds, and any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of the emission wavelength spectrum of the quantum dot may be about 45 nm or less, for example, about 40 nm or less, for example, about 30 nm or less, and within these ranges, color purity or color reproducibility may be increased. In addition, since the light emitted through the quantum dot is emitted in all directions, the wide viewing angle may be improved.

In addition, the quantum dot may be in the form of a spherical particle, a pyramidal particle, a multi-arm particle, a cubic nanoparticle, a nanotube particle, a nanowire particle, a nanofiber particle, or a nanoplate particle.

Since the energy band gap may be adjusted by controlling the size of the quantum dot, light having various wavelength bands may be obtained from the quantum dot emission layer. Accordingly, by using quantum dots of different sizes, a light-emitting device that emits light of various wavelengths may be implemented. In one or more embodiments, the size of the quantum dot may be selected to emit red, green, and/or blue light. In addition, the size of the quantum dot may be configured to emit white light by combination of light of various colors.

[Electron Transport Regions 160-1 and 160-2 in Interlayer 150]

The electron transport regions 160-1 and 160-2 may have i) a single-layer structure consisting of a single layer consisting of a single material, ii) a single-layer structure consisting of a single layer consisting of different materials, or iii) a multi-layered structure including layers including different materials.

The electron transport regions 160-1 and 160-2 may include a buffer layer, a hole blocking layer, an electron control layer, an electron transport layer, an electron injection layer, or any combination thereof.

For example, the electron transport regions 160-1 and 160-2 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the constituent layers of each structure are sequentially stacked from the emission layer.

In an embodiment, the electron transport regions 160-1 and 160-2 (for example, the buffer layer, the hole blocking layer, the electron control layer, or the electron transport layer in the electron transport region) may include a metal-free compound including at least one π electron-deficient nitrogen-containing C₁-C₆₀ cyclic group.

In an embodiment, the electron transport regions 160-1 and 160-2 may include a compound represented by Formula 601:

[Ar₆₀₁]ₓₑ₁₁-[(L₆₀₁)ₓₑ₁-R₆₀₁]ₓₑ₂₁. Formula 601

In Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each be the same as described herein with respect to Q₁,

xe21 may be 1, 2, 3, 4, or 5, and

at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

For example, in case that xe11 in Formula 601 is 2 or more, two or more of Ar₆₀₁ (s) may be linked to each other via a single bond.

In other embodiments, Ar₆₀₁ in Formula 601 may be a substituted or unsubstituted anthracene group.

In one or more embodiments, the electron transport regions 160-1 and 160-2 may include a compound represented by Formula 601-1:

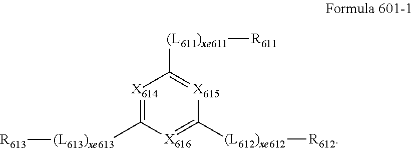

In Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may each be the same as described herein with respect to L₆₀₁,

xe611 to xe613 may each be the same as described herein with respect to xe1₇

R₆₁₁ to R₆₁₃ may each be the same as described herein with respect to R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport regions 160-1 and 160-2 may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

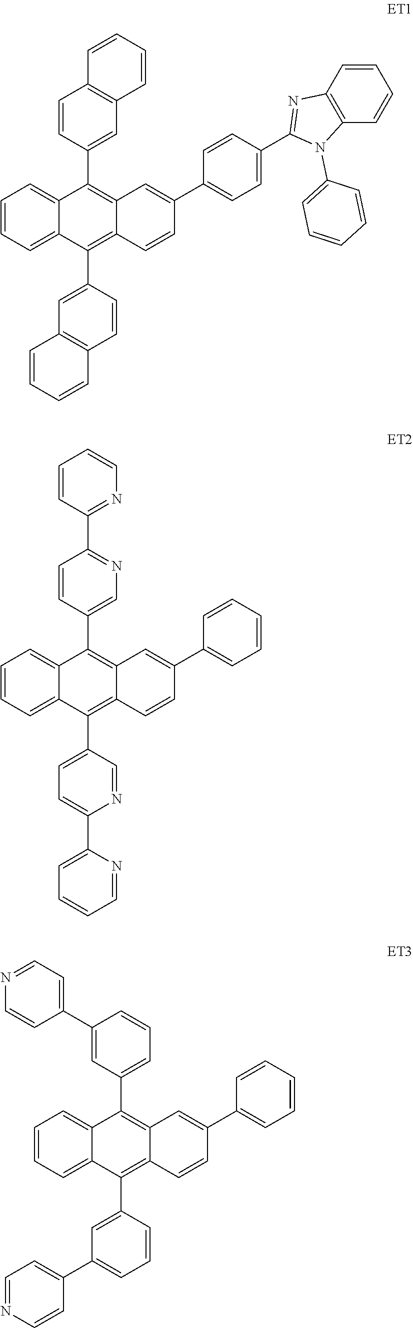 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

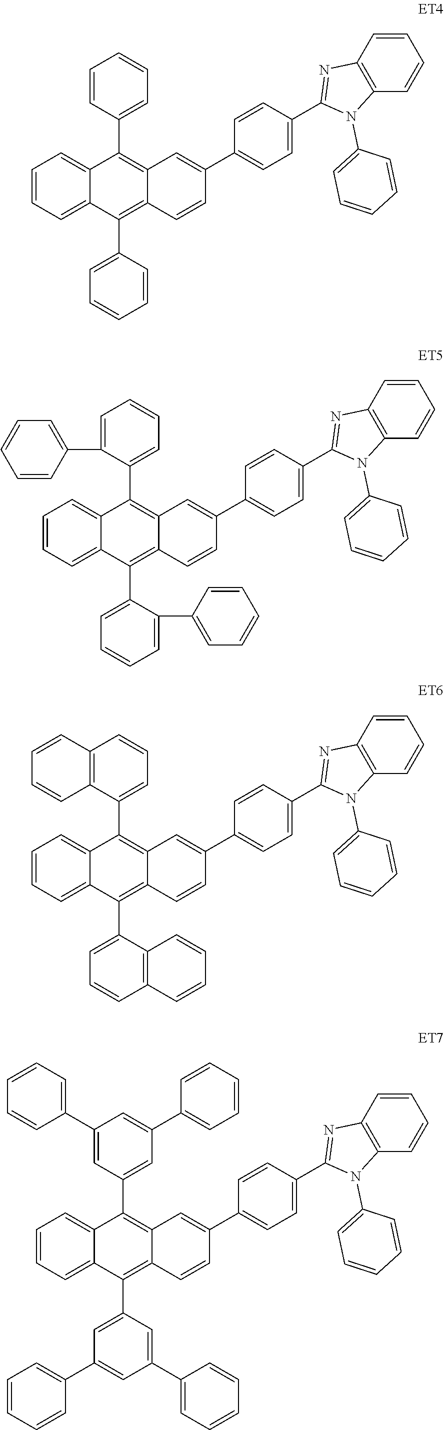 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

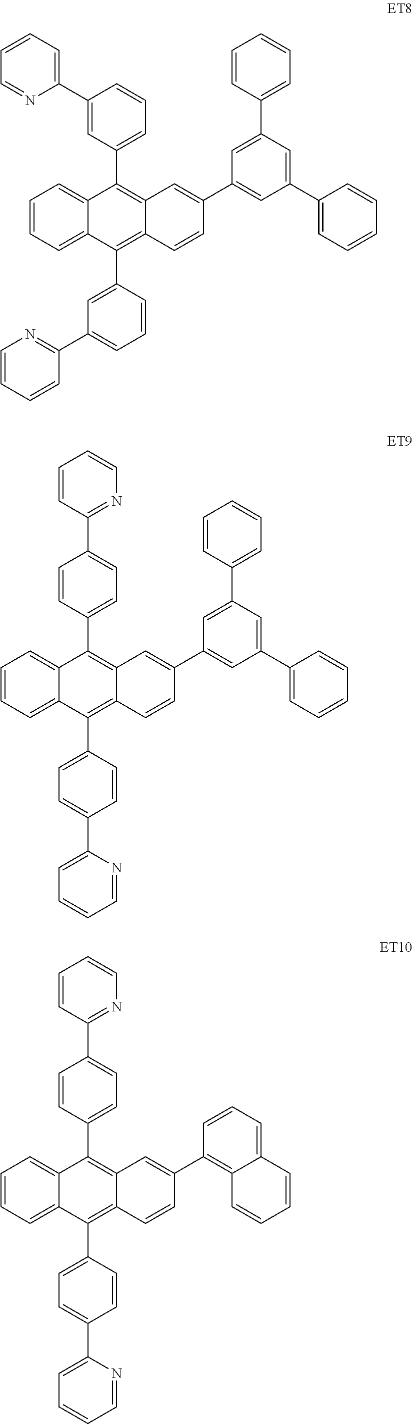

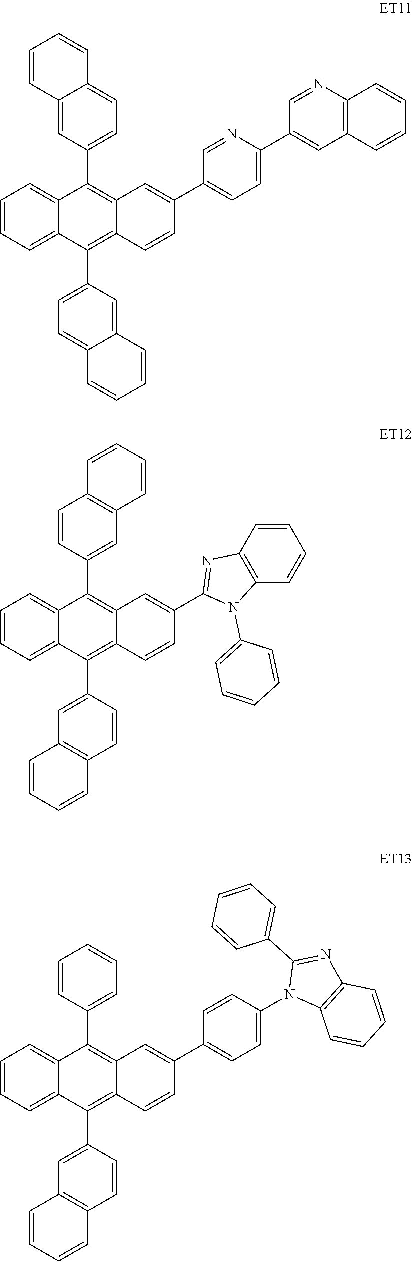

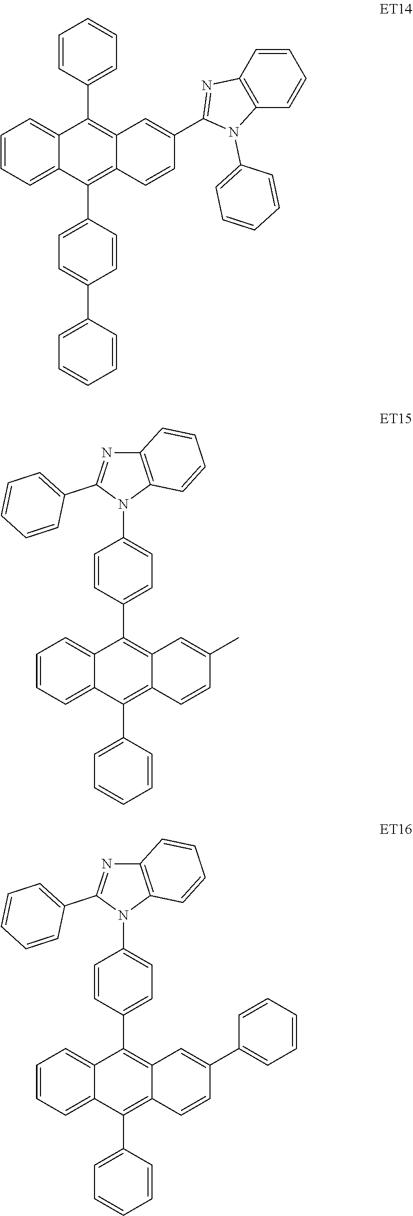 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

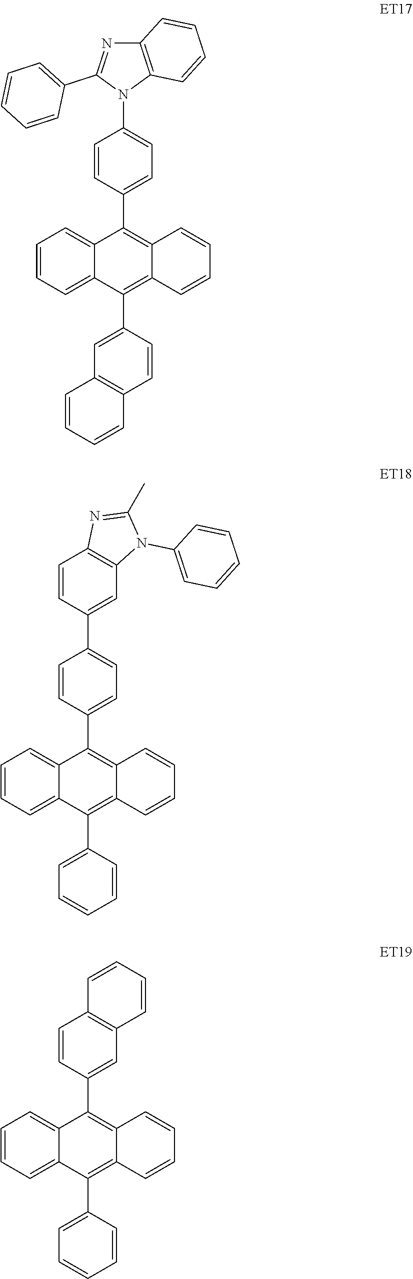

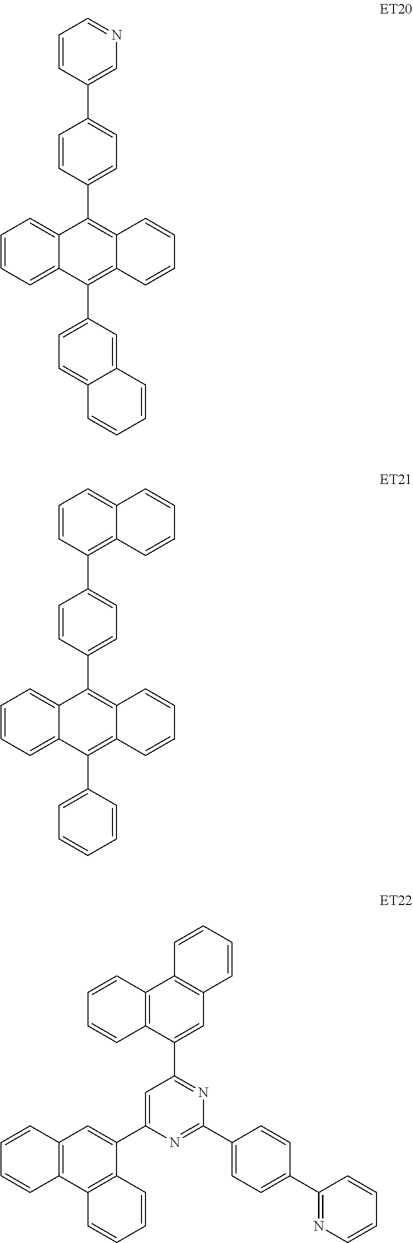

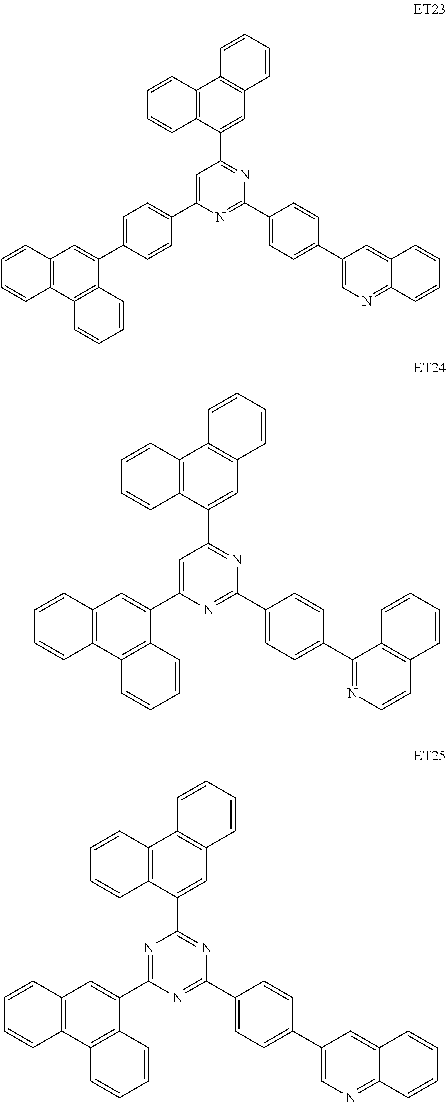 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

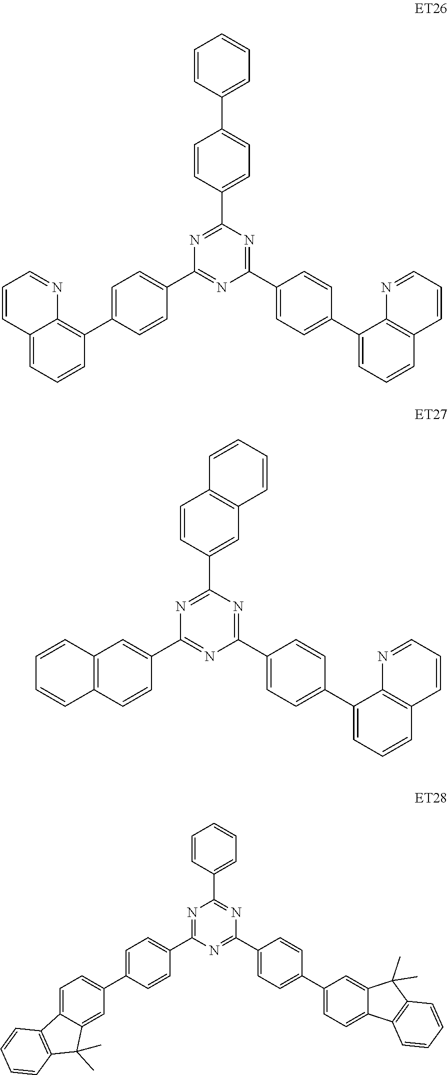 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

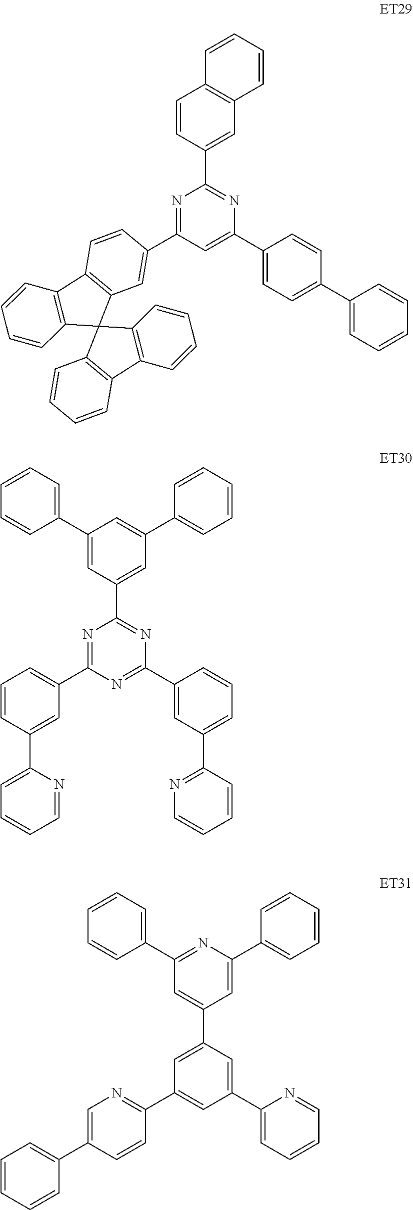 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

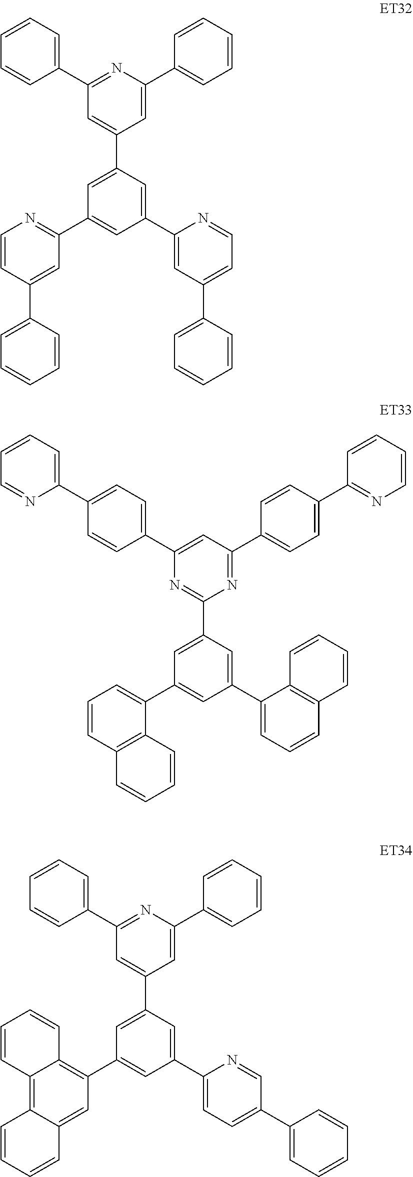 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

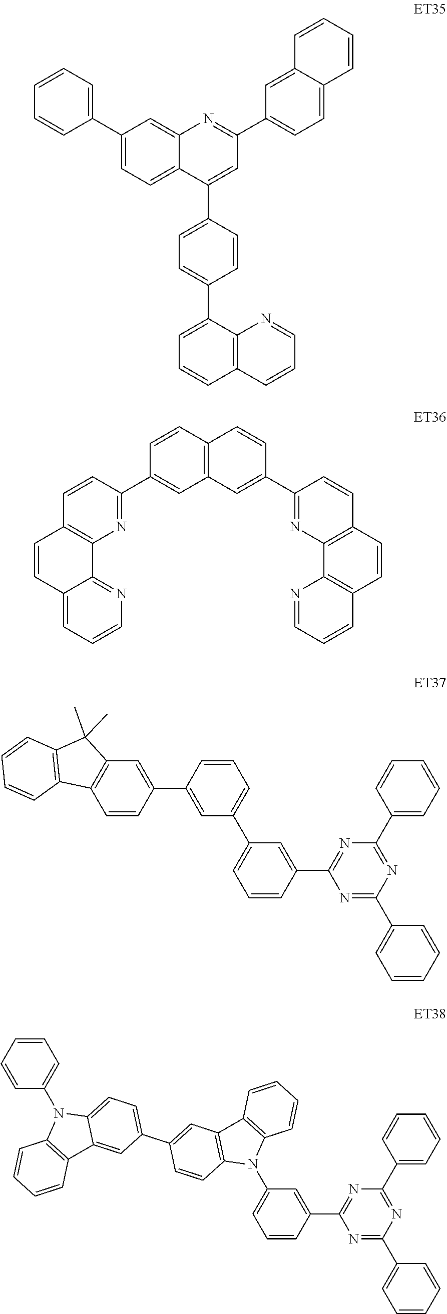 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

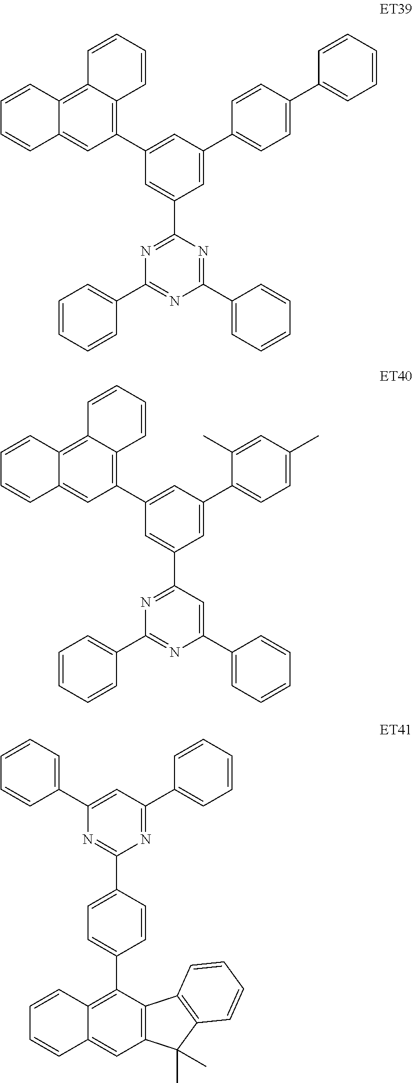

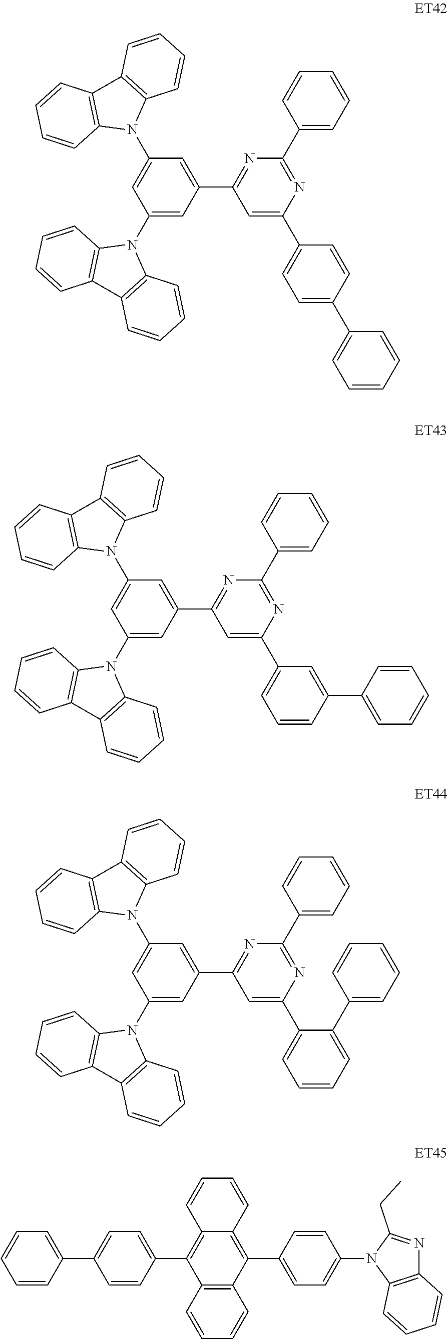 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

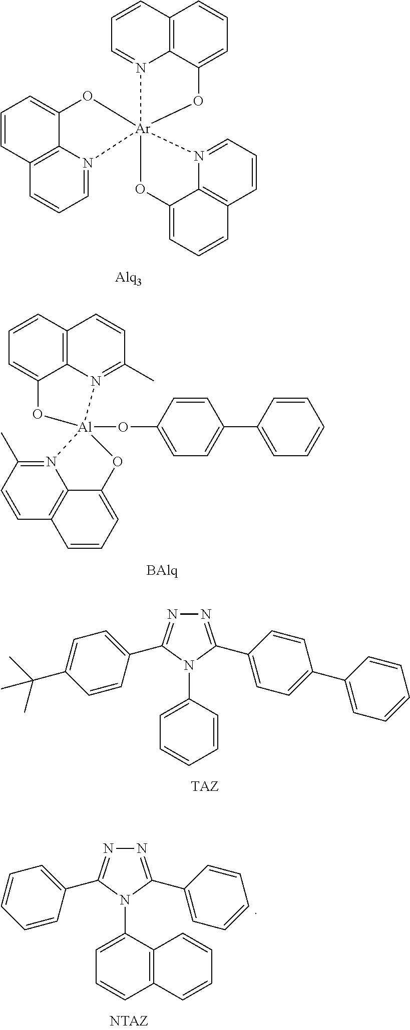

A thickness of the electron transport regions 160-1 and 160-2 may be in a range of about 100 Å to about 5,000 Å, for example, about 160 Å to about 4,000 Å. In case that the electron transport regions 160-1 and 160-2 include a buffer layer, a hole blocking layer, an electron control layer, an electron transport layer, or any combination thereof, thicknesses of the buffer layer, the hole blocking layer, and the electron control layer may each independently be from about 20 Å to about 1,000 Å, for example, about 30 Å to about 300 Å, and a thickness of the electron transport layer may be from about 100 Å to about 1,000 Å, for example, about 150 Å to about 500 Å. In case that the thicknesses of the buffer layer, the hole blocking layer, the electron control layer, the electron transport layer, and/or the electron transport regions 160-1 and 160-2 are within these ranges, satisfactory electron transporting characteristics may be obtained without a substantial increase in driving voltage.

The electron transport regions 160-1 and 160-2 (for example, the electron transport layer in the electron transport region) may further include, in addition to the materials described above, a metal-containing material.

The metal-containing material may include an alkali metal complex, an alkaline earth metal complex, or any combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) or ET-D2:

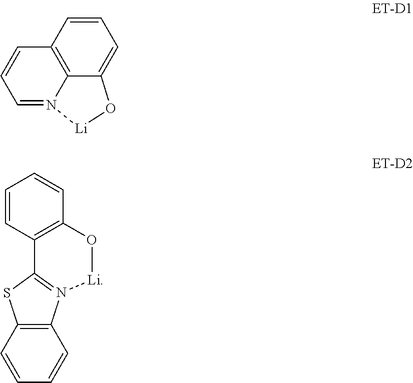

The electron transport regions 160-1 and 160-2 may include an electron injection layer that facilitates the injection of electrons from the second electrode 190. The electron injection layer may directly contact the second electrode 150.

The electron injection layer may have i) a single-layered structure consisting of a single layer consisting of a single material, ii) a single-layered structure consisting of a single layer consisting of different materials, or iii) a multi-layered structure including layers including different materials.

The electron injection layer may include an alkali metal, alkaline earth metal, a rare earth metal, an alkali metal-containing compound, alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (for example, fluorides, chlorides, bromides, or iodides), or tellurides of the alkali metal, the alkaline earth metal, and the rare earth metal, or any combination thereof.

The alkali metal-containing compound may include alkali metal oxides, such as Li₂O, Cs₂O, or K₂O, alkali metal halides, such as LiF, NaF, CsF, KF, LiI, NaI, CsI, or KI, or any combination thereof. The alkaline earth metal-containing compound may include an alkaline earth metal compound, such as BaO, SrO, CaO, BaₓSr₁₋ₓO (where x is a real number satisfying the condition of 0<x<1), BaₓCa₁₋ₓO (where x is a real number satisfying the condition of 0<x<1), or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth metal complex, and the rare earth metal complex may include i) one of ions of the alkali metal, the alkaline earth metal, and the rare earth metal and ii) as a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may consist of i) an alkali metal-containing compound (for example, an alkali metal halide), or ii) a) an alkali metal-containing compound (for example, an alkali metal halide), and b) an alkali metal, an alkaline earth metal, a rare earth metal, or any combination thereof. For example, the electron injection layer may be a LiF:Yb co-deposited layer, a KI:Yb co-deposited layer, an RbI:Yb co-deposited layer, or the like.

In case that the electron injection layer further includes an organic material, alkali metal, alkaline earth metal, rare earth metal, an alkali metal-containing compound, an alkaline earth metal-containing compound, a rare earth metal-containing compound, alkali metal complex, alkaline earth metal complex, rare earth metal complex, or any combination thereof may be uniformly or non-uniformly dispersed in a matrix including the organic material.

A thickness of the electron injection layer may be in a range of about 1 Å to about 100 Å, for example, about 3 Å to about 90 Å. In case that the thickness of the electron injection layer is within the ranges described above, satisfactory electron injection characteristics may be obtained without a substantial increase in driving voltage.

[Second Electrode 190]

The second electrode 190 may be located on the interlayer 150 described above. The second electrode 190 may be a cathode, which is an electron injection electrode, and as the material for the second electrode 190, a metal, an alloy, an electrically conductive compound, or any combination thereof, each having a low work function, may be used.

The second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 190 may be a transmissive electrode, a semi-transmissive electrode, or a reflective electrode.

The second electrode 190 may have a single-layered structure or a multi-layered structure including two or more layers.

[Capping Layer]

A first capping layer may be arranged outside the first electrode 110, and/or a second capping layer may be arranged outside the second electrode 190. In detail, the light-emitting device 10 may have a structure in which the first capping layer, the first electrode 110, the interlayer 150, and the second electrode 190 are sequentially stacked in this stated order, a structure in which the first electrode 110, the interlayer 150, the second electrode 190, and the second capping layer are sequentially stacked in this stated order, or a structure in which the first capping layer, the first electrode 110, the interlayer 150, the second electrode 190, and the second capping layer are sequentially stacked in this stated order.

Light generated in the emission layers 152-1 and 152-2 of the interlayer 150 of the light-emitting device 10 may be extracted toward the outside through the first electrode 110, which is a semi-transmissive electrode or a transmissive electrode, and the first capping layer, and light generated in the emission layers 152-1 and 152-2 of the interlayer 150 of the light-emitting device 10 may be extracted toward the outside through the second electrode 190, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 is increased, so that the luminescence efficiency of the light-emitting device 10 may be improved.

Each of the first capping layer and the second capping layer may include a material having a refractive index of about 1.6 or more (at about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include carbocyclic compounds, heterocyclic compounds, amine group-containing compounds, porphyrin derivatives, phthalocyanine derivatives, naphthalocyanine derivatives, alkali metal complexes, alkaline earth metal complexes, or any combination thereof. Optionally, the carbocyclic compound, the heterocyclic compound, and the amine group-containing compound may be substituted with a substituent including O, N, S, Se, Si, F, Cl, Br, I, or any combination thereof. In one or more embodiments, at least one of the first capping layer and the second capping layer may each independently include an amine group-containing compound.

For example, at least one of the first capping layer and the second capping layer may each independently include a compound represented by Formula 201, a compound represented by Formula 202, or any combination thereof.

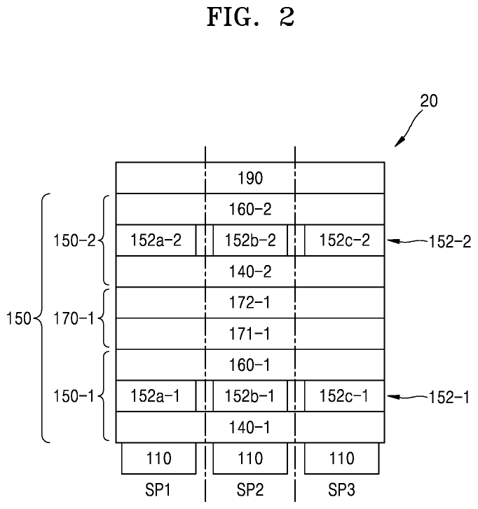

In one or more embodiments, at least one of the first capping layer and the second capping layer may each independently include one of Compounds HT28 to HT33, one of Compounds CP1 to CP6, β-NPB, or any combination thereof:

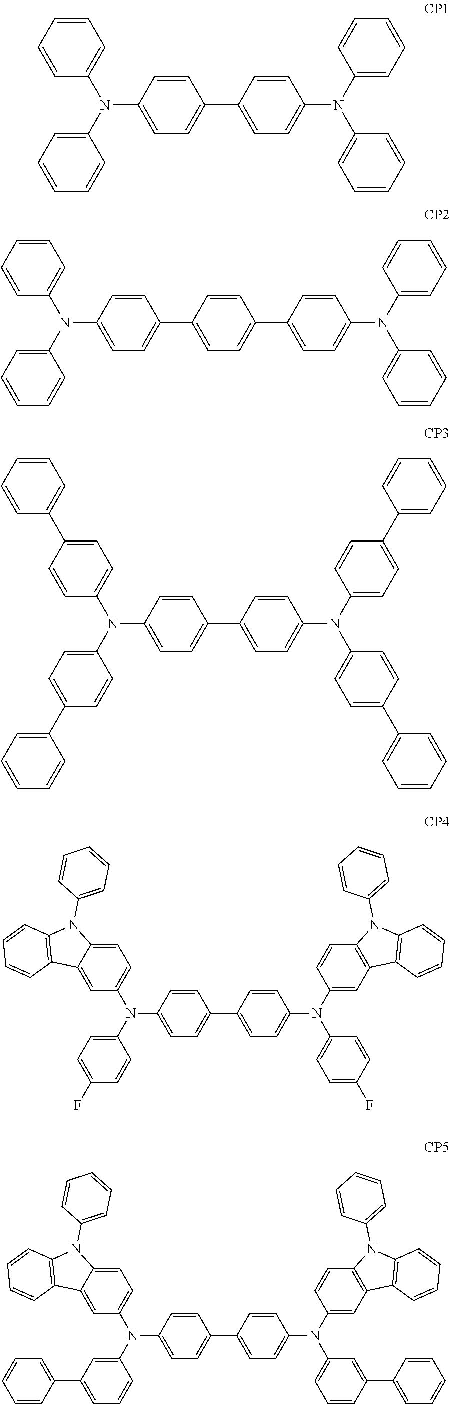 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

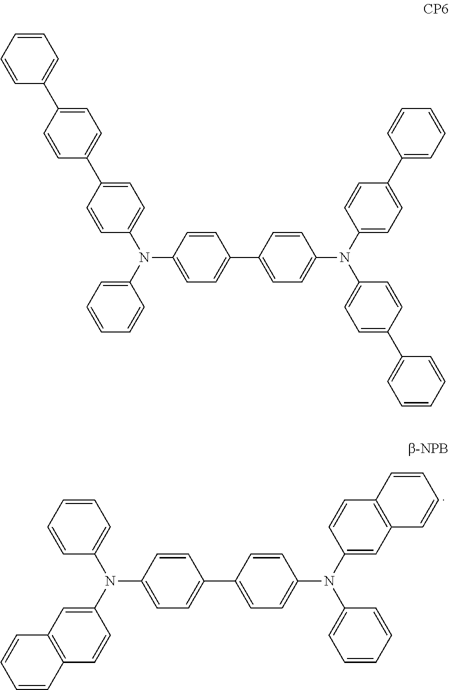 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

[Description of FIG. 2]

FIG. 2 is a schematic cross-sectional view of a light-emitting device 20 according to an embodiment. The light-emitting device 20 is a drawing exemplifying a light-emitting device in case that m is 2, but embodiments are not limited thereto. Because the functions of the components of FIG. 2 among the components of FIG. 1 are the same or similar to those of the components of FIG. 1, detailed explanations thereof will be omitted.

As shown in FIG. 2, the light-emitting device 20 may include first electrodes 110 arranged according to a first subpixel SP1, a second subpixel SP2, and a third subpixel SP3, respectively, a second electrode 190 facing the first electrodes 110, and an interlayer 150. The interlayer 150 may include two emitting units 150-1 and 150-2 and a charge generation layer 170-1 stacked between the first electrode 110 and the second electrode 190.

The first emitting unit 150-1 may include a first hole transport region 140-1, a first emission layer 152-1, and a first electron transport region 160-1 sequentially disposed in the stated order.

The first emission layer 152-1 may include a first first emission layer 152a-1 located in the first subpixel SP1 and emitting first first-color light, a second first emission layer 152b-1 located in the second subpixel SP2 and emitting second first-color light, and a third first emission layer 152c-1 located in the third subpixel SP3 and emitting third first-color light. In an embodiment, the first first-color light may be red light, the second first-color light may be green light, and the third first-color light may be blue light.

The second emitting unit 150-2 may include a second hole transport region 140-2, a second emission layer 152-2, and a second electron transport region 160-2 sequentially disposed in the stated order.

The second emission layer 152-2 may include a first second emission layer 152a-2 located in the first subpixel SP1 and emitting first second-color light, a second second emission layer 152b-2 located in the second subpixel SP2 and emitting second second-color light, and a third second emission layer 152c-2 located in the third subpixel SP3 and emitting third second-color light. In an embodiment, the first second-color light may be red light, the second second-color light may be green light, and the third second-color light may be blue light.

The first hole transport region 140-1 may be located in the form of a common layer between the first electrodes 110 and the first emission layer 152-1 including the first first emission layer 152a-1, the second first emission layer 152b-1, and the third first emission layer 152c-1.

The second hole transport region 140-2 may be located in the form of a common layer between the first p-type charge generation layer 172-1 included in the first charge generation layer 170-1 and the second emission layer 152-2 including the first second emission layer 152a-2, the second second emission layer 152b-2, and the third second emission layer 152c-2.

The first electron transport region 160-1 may be located in the form of a common layer between the first emission layer 152-1 including the first first emission layer 152a-1, the second first emission layer 152b-1, and the third first emission layer 152c-1 and the first n-type charge generation layer 171-1 included in the first charge generation layer 170-1.

The second electron transport region 160-2 may be located in the form of a common layer between the second emission layer 152-2 including the first second emission layer 152a-2, the second second emission layer 152b-2, and the third second emission layer 152c-2 and the second electrode 190.

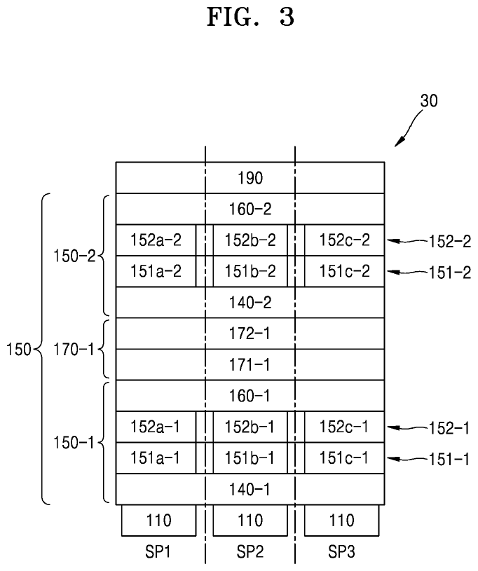

The first hole transport region 140-1 may include the first hole transport material, and the second hole transport region 140-2 may include the second hole transport material.

[Description of FIG. 3]

FIG. 3 illustrates a schematic cross-sectional view of a light-emitting device 30 according to an embodiment. The light-emitting device 30 is a drawing exemplifying a light-emitting device in case that m is 2, but embodiments are not limited thereto. Because the functions of the components of FIG. 3 among the components of FIG. 1 or 2 are the same or similar to those of the components of FIG. 1 or 2, detailed explanations thereof will be omitted.

As show in FIG. 3, the first emitting unit 150-1 may include the first hole transport region 140-1, a first auxiliary layer 151-1, the first emission layer 152-1, and the first electron transport region 160-1 sequentially disposed in the stated order.

The first auxiliary layer 151-1 may include a first first auxiliary layer 151a-1 arranged in the first subpixel SP1, a second first auxiliary layer 151b-1 arranged in the second subpixel SP2, and a third first auxiliary layer 151c-1 arranged in the third subpixel SP3.

The second emitting unit 150-2 may include a second hole transport region 140-2, a second auxiliary layer 151-2, a second emission layer 152-2, and a second electron transport region 160-2 sequentially disposed in the stated order.

The second auxiliary layer 151-2 may include a first second auxiliary layer 151a-2 arranged in the first subpixel SP1, a second second auxiliary layer 151b-2 arranged in the second subpixel SP2, and a third second auxiliary layer 151c-2 arranged in the third subpixel SP3.

The first first auxiliary layer 151a-1, the second first auxiliary layer 151b-1, and the third first auxiliary layer 151c-1 may each independently include the first hole transport material. A first first hole transport material included in the first first auxiliary layer 151a-1, a second first hole transport material included in the second first auxiliary layer 151b-1, and a third first hole transport material included in the third first auxiliary layer 151c-1 may each be identical to or different from each other. For example, the first first hole transport material, the second first hole transport material, and the third first hole transport material may be identical to each other.

The first second auxiliary layer 151a-2, the second second auxiliary layer 151b-2, and the third second auxiliary layer 151c-2 may each independently include the second hole transport material. A first second hole transport material included in the first second auxiliary layer 151a-2, a second second hole transport material included in the second second auxiliary layer 151b-2, and a third second hole transport material included in the third second auxiliary layer 151c-2 may be identical to or different from each other. For example, the first second hole transport material, the second second hole transport material, and the third second hole transport material may be identical to each other.

The refractive index of the first first hole transport material may be greater than the refractive index of the first second hole transport material.

The refractive index of the second first hole transport material may be greater than the refractive index of the second second hole transport material.

The refractive index of the third first hole transport material may be greater than the refractive index of the third second hole transport material.

[Electronic Apparatus]

The light-emitting device may be included in various electronic apparatuses. For example, the electronic apparatus including the light-emitting device may be a light-emitting apparatus, an authentication apparatus, or the like.

The electronic apparatus (for example, a light-emitting apparatus) may further include, in addition to the light-emitting device, i) a color filter, ii) a color conversion layer, or iii) a color filter and a color conversion layer. The color filter and/or the color conversion layer may be located in at least one traveling direction of light emitted from the light-emitting device. For example, the light emitted from the light-emitting device may be blue light or white light. For details on the light-emitting device, related description provided above may be referred to. In one or more embodiments, the color conversion layer may include a quantum dot. The quantum dot may be, for example, a quantum dot as described herein.

The electronic apparatus may include a first substrate. The first substrate may include subpixel areas, the color filter may include color filter areas respectively corresponding to the subpixel areas, and the color conversion layer may include color conversion areas respectively corresponding to the subpixel areas.

A pixel-defining film may be located among the subpixel areas to define each of the subpixel areas.

The color filter may further include color filter areas and light-shielding patterns located among the color filter areas, and the color conversion layer may further include color conversion areas and light-shielding patterns located among the color conversion areas.

The color filter areas (or the color conversion areas) may include a first area emitting first-color light, a second area emitting second-color light, and/or a third area emitting third-color light, wherein the first-color light, the second-color light, and/or the third-color light may have different maximum emission wavelengths from one another. For example, the first-color light may be red light, the second-color light may be green light, and the third-color light may be blue light. For example, the color filter areas (or the color conversion areas) may include quantum dots. In particular, the first area may include a red quantum dot, the second area may include a green quantum dot, and the third area may not include a quantum dot. For details on the quantum dot, related descriptions provided herein may be referred to. The first area, the second area, and/or the third area may each include a scatter.

For example, the light-emitting device may emit first light, the first area may absorb the first light to emit first-first-color light, the second area may absorb the first light to emit second-first-color light, and the third area may absorb the first light to emit third-first-color light. In this regard, the first-first-color light, the second-first-color light, and the third-first-color light may have different maximum emission wavelengths. In particular, the first light may be blue light, the first-first-color light may be red light, the second-first-color light may be green light, and the third-first-color light may be blue light.

The electronic apparatus may further include a thin-film transistor, in addition to the light-emitting device as described above. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, or the like.

The activation layer may include crystalline silicon, amorphous silicon, an organic semiconductor, an oxide semiconductor, or the like.

The electronic apparatus may further include a sealing portion for sealing the light-emitting device. The sealing portion may be located between the color conversion layer and/or the color filter and the light-emitting device. The sealing portion allows light from the light-emitting device to be extracted to the outside, and simultaneously prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. In case that the sealing portion is a thin-film encapsulation layer, the electronic apparatus may be flexible.

Various functional layers may be additionally located on the sealing portion, in addition to the color filter and/or the color conversion layer, according to the use of the electronic apparatus. Examples of the functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the light-emitting device as described above, a biometric information collector.

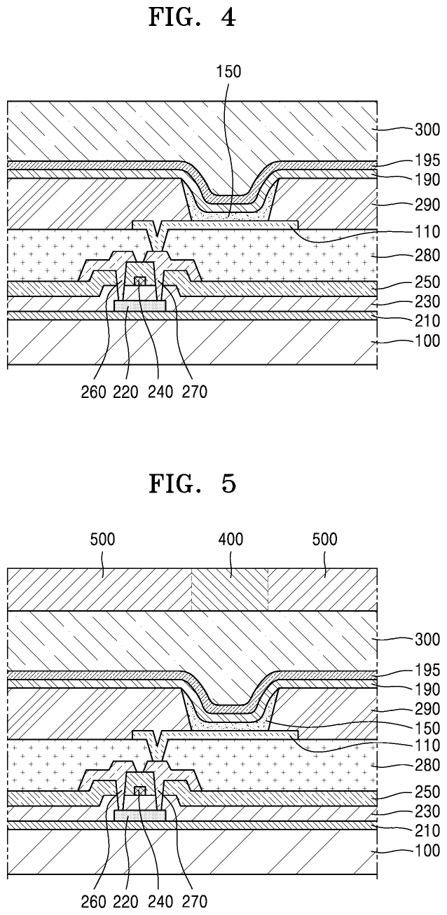

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

[Description of FIGS. 4 and 5]

FIG. 4 is a schematic cross-sectional view illustrating a light-emitting apparatus according to an embodiment of the disclosure.

The light-emitting apparatus of FIG. 4 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be located on the substrate 100. The buffer layer 210 may prevent penetration of impurities through the substrate 100 and may provide a flat surface on the substrate 100.

A TFT may be located on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240. The interlayer insulating film 250 may be located between the gate electrode 240 and the source electrode 260 and between the gate electrode 240 and the drain electrode 270, to insulate them from one another.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be located in contact with the exposed portions of the source region and the drain region of the activation layer 220.

The TFT is electrically connected to a light-emitting device to drive the light-emitting device, and is covered and protected by a passivation layer 280. The passivation layer 280 may include an inorganic insulating film, an organic insulating film, or any combination thereof. A light-emitting device is provided on the passivation layer 280. The light-emitting device may include the first electrode 110, the interlayer 150, and the second electrode 190.

The first electrode 110 may be located on the passivation layer 280. The passivation layer 280 may be located to expose a portion of the drain electrode 270 without fully covering the drain electrode 270, and the first electrode 110 may be located to be connected to the exposed portion of the drain electrode 270.

A pixel-defining film 290 including an insulating material may be located on the first electrode 110. The pixel-defining film 290 may expose a certain region of the first electrode 110, and an interlayer 150 may be formed in the exposed region of the first electrode 110. The pixel-defining film 290 may be a polyimide or polyacrylic organic film. Although not shown in FIG. 2, at least some layers of the interlayer 150 may extend to an upper portion of the pixel-defining film 290 to be located in the form of a common layer.

The second electrode 190 may be disposed on the interlayer 150, and a capping layer 195 may be additionally formed on the second electrode 190. The capping layer 170 may be formed to cover the second electrode 150.

The encapsulation portion 300 may be deposited on the capping layer 195. The encapsulation portion 300 may be located on a light-emitting device to protect the light-emitting device from moisture or oxygen. The encapsulation portion 300 may include an inorganic film including silicon nitride (SiNx), silicon oxide (SiOx), indium tin oxide, indium zinc oxide, or any combination thereof, an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE) or the like), or any combination thereof, or any combination of the inorganic films and the organic films.

FIG. 5 is a schematic cross-sectional view of a light-emitting apparatus according to another embodiment.

The light-emitting apparatus of FIG. 5 is the same as the light-emitting apparatus of FIG. 4, except that a light-shielding pattern 500 and a functional region 400 are additionally located on the encapsulation portion 300. The functional region 400 may be i) a color filter area, ii) a color conversion area, or iii) a combination of the color filter area and the color conversion area. In one or more embodiments, the light-emitting device included in the light-emitting apparatus of FIG. 5 may be a tandem light-emitting device.

[Manufacturing Method]

Respective layers constituting the hole transport regions 140-1 and 140-2, the emission layers 152-1 and 152-2, the electron transport regions 160-1 and 160-2 may each be formed in a certain region by using various methods such as vacuum deposition, spin coating, casting, Langmuir-Blodgett (LB) deposition, ink-jet printing, laser-printing, and laser-induced thermal imaging (LITI).

In case that each of the layers of the hole transport regions 140-1 and 140-2, the emission layers 152-1 and 152-2, and the electron transport regions 160-1 and 160-2 are formed by vacuum deposition, the deposition conditions may be selected, for example, to include a deposition temperature of about 100° C. to about 500° C., a vacuum degree of about 10⁻⁸ torr to about 10⁻³ torr, and a deposition speed of about 0.01 Å/sec to about 100 Å/sec, according to the material and structure of a layer to be formed.

### DEFINITION OF TERMS

The term “C₃-C₆₀ carbocyclic group” as used herein refers to a cyclic group consisting of carbon only as a ring-forming atom and having three to sixty carbon atoms, and the term “C₁-C₆₀ heterocyclic group” as used herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of a ring or a polycyclic group in which two or more rings are condensed with each other. For example, the C₁-C₆₀ heterocyclic group has 3 to 61 ring-forming atoms.

The “cyclic group” as used herein may include the C₃-C₆₀ carbocyclic group, and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

For example,

the C₃-C₆₀ carbocyclic group may be i) a T1 group or ii) a condensed cyclic group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) a T2 group, ii) a condensed cyclic group in which two or more T2 groups are condensed with each other, or iii) a condensed cyclic group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the π electron-rich C₃-C₆₀ cyclic group may be i) a T1 group, ii) a condensed cyclic group in which two or more T1 groups are condensed with each other, iii) a T3 group, iv) a condensed cyclic group in which two or more T3 groups are condensed with each other, or v) a condensed cyclic group in which at least one group T3 and at least one T1 group are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),

the π electron-deficient nitrogen-containing C₁-C₆₀ cyclic group may be i) a T4 group, ii) a condensed cyclic group in which two or more T4 groups are condensed with each other, iii) a condensed cyclic group in which at least one T4 group and at least one T1 group are condensed with each other, iv) a condensed cyclic group in which at least one T4 group and at least one T3 group are condensed with each other, or v) a condensed cyclic group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

the T3 group may be a furan group, a thiophene group, a 1H-pyrrole group, a silole group, or a borole group, and

the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as used herein refer to a group condensed to any cyclic group, a monovalent group, or a polyvalent group (for example, a divalent group, a trivalent group, a tetravalent group, etc.) according to the structure of a formula for which the corresponding term is used. For example, the “benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the monovalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has one to sixty carbon atoms, and specific examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof include an ethynyl group and a propynyl group. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (where A₁₀₁ is the C₁-C₆₀ alkyl group), and examples thereof include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and examples thereof include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom, as ring-forming atoms, and specific examples include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term C₃-C₁₀ cycloalkenyl group used herein refers to a monovalent cyclic group that has three to ten carbon atoms, at least one carbon-carbon double bond in the ring thereof, and no aromaticity, and specific examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one carbon-carbon double bond in the cyclic structure (or ring structure) thereof. Examples of the heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. In case that the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. In case that the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having the same structure as the monovalent non-aromatic condensed heteropolycyclic group described above.

The term “C₆-C₆₀ aryloxy group” as used herein indicates —OA₁₀₂ (where A₁₀₂ is a C₆-C₆₀ aryl group), and the term “C₆-C₆₀ arylthio group” as used herein indicates —SA₁₀₃ (where A₁₀₃ is a C₆-C₆₀ aryl group).

The term “C₇-C₆₀ aryl alkyl group” used herein refers to -A₁₀₄A₁₀₅ (where A₁₀₄ may be a C₁-C₅₄ alkylene group, and A₁₀₅ may be a C₆-C₅₉ aryl group), and the term C₂-C₆₀ heteroaryl alkyl group” used herein refers to -A₁₀₆A₁₀₇ (where A₁₀₆ may be a C₁-C₅₉ alkylene group, and A₁₀₇ may be a C₁-C₅₉ heteroaryl group).

The term “R₁₀ₐ” as used herein refers to deuterium, —F, —Cl, —Br, —I, a hydroxyl group, a cyano group, or a nitro group,

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁ to Q₃, Q₁₁ to Q₁₃, Q₂₁ to Q₂₃, and Q₃₁ to Q₃₃ used herein may each independently be hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a alkoxy group, a C₃-C₆₀ carbocyclic group or a C₁-C₆₀ heterocyclic group, each unsubstituted or substituted with deuterium, —F, a cyano group, a C₁-C₆₀ alkyl group, a alkoxy group, a phenyl group, a biphenyl group, or any combination thereof, a C₇-C₆₀ aryl alkyl group, or a C₂-C₆₀ heteroaryl alkyl group.

The term “heteroatom” as used herein refers to any atom other than a carbon atom. Examples of the heteroatom include O, S, N, P, Si, B, Ge, Se, and any combinations thereof.

The term “third-row transition metal” used herein includes hafnium (Hf), tantalum (Ta), tungsten (W), rhenium (Re), osmium (Os), iridium (Ir), platinum (Pt), gold (Au), and the like.

“Ph” as used herein refers to a phenyl group, “Me” as used herein refers to a methyl group, “Et” as used herein refers to an ethyl group, “tert-Bu” or “But” as used herein refers to a tert-butyl group, and “OMe” as used herein refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group”. In other words, the “terphenyl group” is a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

Hereinafter, compounds according to embodiments and light-emitting devices according to embodiments will be described in detail with reference to the following synthesis examples and examples. The wording “B was used instead of A” used in describing Synthesis Examples means that an identical molar equivalent of B was used in place of A.

### EXAMPLES

### Example 1

A first pixel electrode, a second pixel electrode, and a third pixel electrode were formed by patterning, as an anode electrode, Ag/ITO on a glass substrate at thicknesses of about 1,500 Å/about 70 Å.

NDP-9 (Novaled) was deposited on the first pixel electrode, the second pixel electrode, and the third pixel electrode to form a first hole injection layer having a thickness of about 50 Å, and Compound A, which is an aryl amine group-containing compound, was deposited thereon to form a first hole transport layer having a thickness of about 220 Å.

Within a blue subpixel area, CBP as a host and FD14 as a blue dopant were co-deposited on the first hole transport layer at a weight ratio of about 97:about 3 to form a blue organic emission layer having a thickness of about 160 Å. Within a red subpixel area, CBP as a host and Ir(btp)₂(acac) as a red dopant were co-deposited on the first hole transport layer at a weight ratio of about 97:about 3 to form a red organic emission layer having a thickness of about 450 Å. Within a green subpixel area, CBP as a host and Ir(ppy)₃ as a green dopant were deposited on the hole transport layer at a weight ratio of about 94:about 6 to form a green organic emission layer having a thickness of about 330 Å, thereby forming a first emission layer including the blue organic emission layer, the red organic emission layer, and the green organic emission layer.

ET37 was deposited on the blue organic emission layer, the red organic emission layer, and the green organic emission layer to form a first buffer layer having a thickness of about 50 Å, ET29 and LiQ were co-deposited thereon at a ratio of about 1:about 1 to form a first electron transport layer having a thickness of about 280 Å, thereby forming a first emitting unit including the first hole injection layer, the first hole transport layer, the first emission layer, the first buffer layer, and the first electron transport layer.

ET36 and Yb (the amount of Yb was about 1 wt %) were co-deposited on the first electron transport layer to form an n-type charge generation layer having a thickness of about 150 Å, and HT3 was deposited to form a p-type charge generation layer having a thickness of about 100 Å, thereby forming a first charge generation layer.

NDP-9(Novaled) was deposited on the first charge generation layer to form a second hole injection layer having a thickness of about 50 Å, and Compound B, which is an aryl amine group-containing compound substituted with at least one C₃-C₃₀ carbocyclic group, was deposited thereon to form a second hole transport layer having a thickness of about 220 Å. A second emission layer identical to the first emission layer was formed on the second hole transport layer.

On the second emission layer, a second buffer layer and a second electron transport layer identical to the first buffer layer and the first electron transport layer, respectively, were formed to thereby form a second emitting unit including the second hole injection layer, the second hole transport layer, the second emission layer, the second buffer layer, and the second electron transport layer.

AgMg was deposited on the second electron transport layer to form a cathode having a thickness of about 85 Å, and HT28 was deposited on the cathode to form a capping layer having a thickness of about 700 Å, thereby completing the manufacture of a light-emitting device.

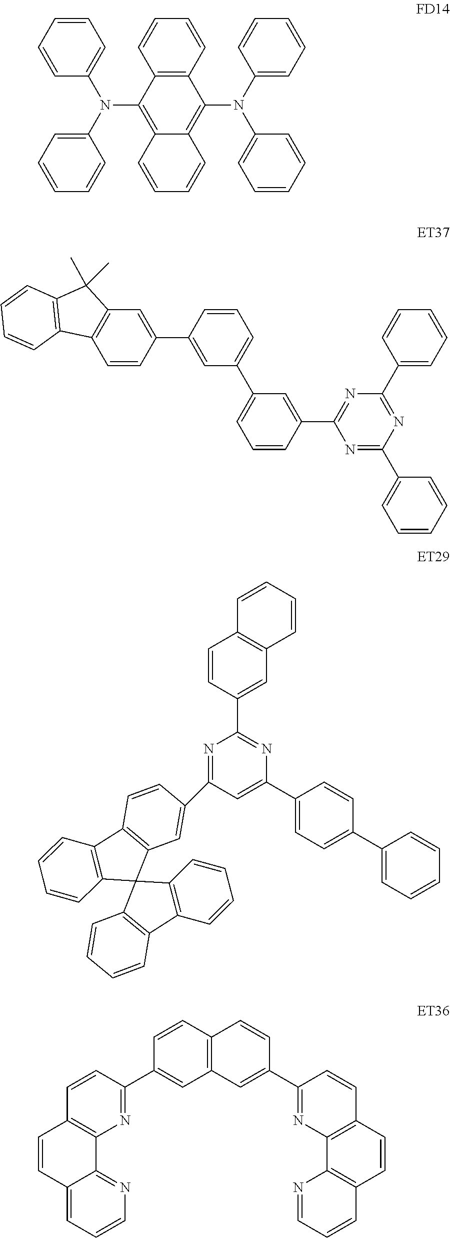 [SMILES: c1ccc(N(c2ccccc2)c2c3ccccc3c(N(c3ccccc3)c3ccccc3)c3ccccc23)cc1 ; CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1cnc2c(c1)ccc1ccc(-c3ccc4ccc(-c5ccc6ccc7cccnc7c6n5)cc4c3)nc12]

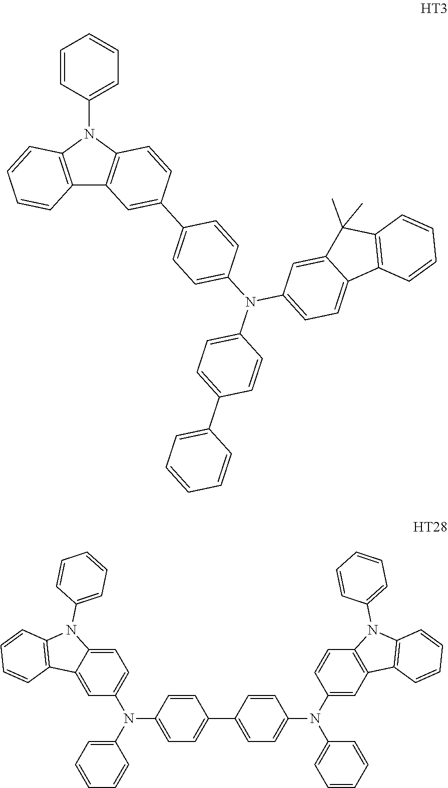 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### Comparative Example 1

An organic light-emitting device was manufactured in the same manner as in Example 1, except that Compound B was used when forming the first hole transport layer.

### Evaluation Example 1: Measurement of Refractive Index

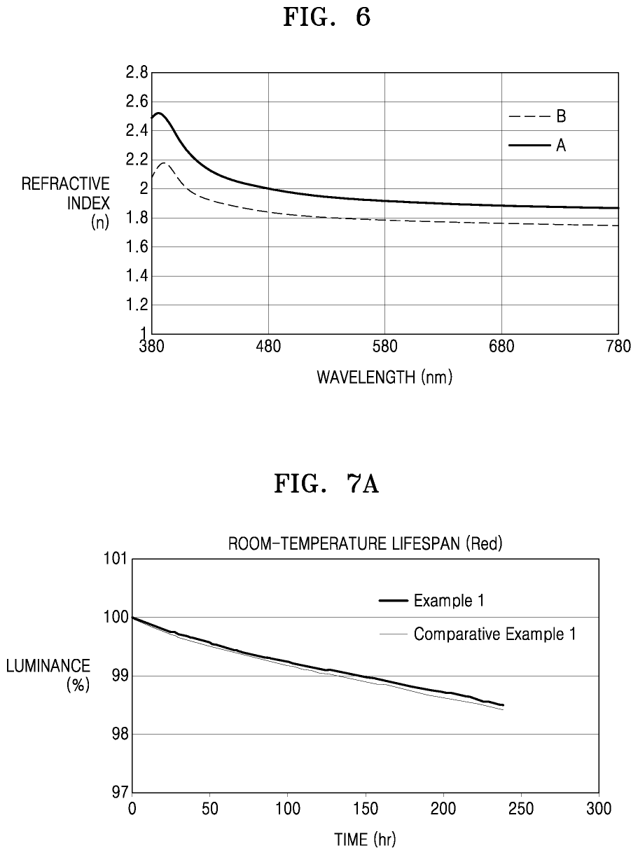

Regarding Compounds A to B, the refractive index in each wavelength was measured using an Ellipsometer (manufactured by K-mac, Republic of Korea) and the results thereof are shown in FIG. 6 and Table 1.

TABLE 1

| | Refractive index | Refractive index | Refractive index |
|---|---|---|---|
| Compound | (at 460 nm) | (at 530 nm) | (at 620 nm) |
| A | 2.043 | 1.954 | 1.907 |
| B | 1.871 | 1.811 | 1.779 |

From Table 1 and FIG. 6, it can be seen that the refractive index of Compound B is smaller than the refractive index of Compound A.

### Evaluation Example 2

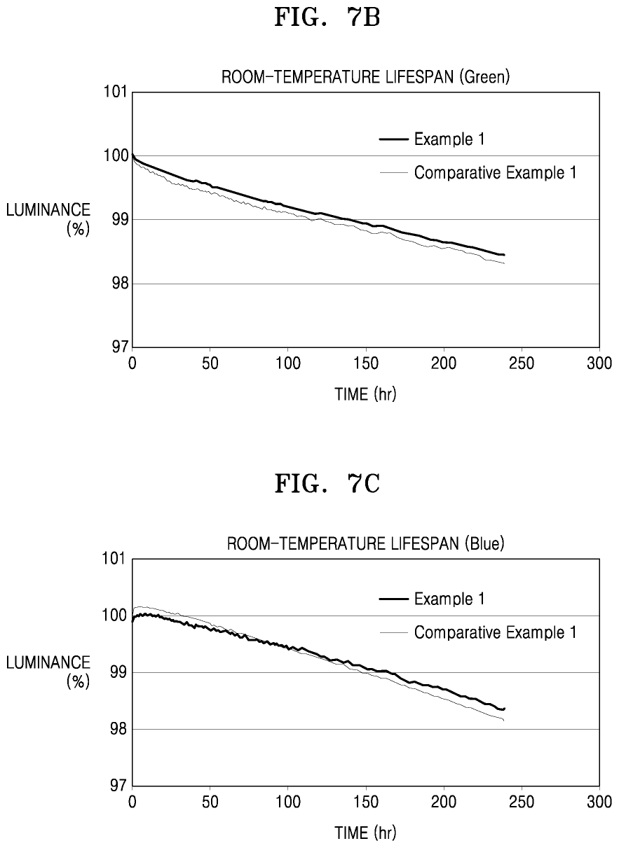

Regarding the light-emitting devices manufactured according to Example 1 and Comparative Example 1, the efficiency (Cd/A) at a luminance of 1,500 nits was measured by using a color luminance meter, a Keithley source meter apparatus, and a fixed current room-temperature lifespan apparatus. Results thereof are shown in Tables 2 and 3. Room-temperature lifespans were shown in FIGS. 7A to 7C.

TABLE 2

| | First hole | Second hole | Red light | | Green light | |
|---|---|---|---|---|---|---|
| | transport | transport | Color | Luminescence | Color | Luminescence |
| | layer | layer | coordinate | efficiency | coordinate | efficiency |
| Comparative | B | B | (0.680, 0.319) | 113.40 | (0.249, 0.711) | 322.80 |
| Example 1 | | | | | | |
| Example 1 | A | B | (0.680, 0.319) | 119.10 | (0.251, 0.711) | 332.20 |

TABLE 3

| | | Second | | | |
|---|---|---|---|---|---|
| | First hole | hole | Blue light | | While light |
| | transport | transport | Color | Luminescence | Luminescence |
| | layer | layer | coordinate | efficiency | efficiency |
| Comparative | B | B | (0.141, | 14.70 | 114.98 |
| Example 1 | | | 0.046) | | |
| Example 1 | A | B | (0.139, | 15.90 | 119.31 |
| | | | 0.048) | | |

From Tables 2 and 3 and FIGS. 7A to 7C, it can be seen that the light-emitting device of Example 1 has improved luminescence efficiency in red light, green light, blue light, and white light and room temperature lifespan, compared to that of the light-emitting device of Comparative Example 1.

While the disclosure has been described with reference to embodiments illustrated in the drawings, these embodiments are provided herein for illustrative purpose only, and one of ordinary skill in the art may understand that the embodiments include various modifications and equivalent embodiments thereof. Accordingly, the true scope of the disclosure should be determined by the technical idea of the appended claims.

The light-emitting device may have high efficiency, and thus may be used for manufacturing a high quality electronic apparatus having excellent light efficiency and a long lifespan.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light-emitting device comprising:
a first electrode;
a second electrode facing the first electrode;
m emitting parts located between the first electrode and the second electrode; and
m−1 charge generation layers each located between two neighboring ones among the m emitting parts, and each including an n-type charge generation layer and a p-type charge generation layer, wherein
m is an integer of 2 or greater,
the m emitting parts each include a hole transport region, an emission layer, and an electron transport region, disposed in sequence,
a first hole transport region included in a first emitting part among the m emitting parts includes a first hole transport material,
a second hole transport region included in a second emitting part among the m emitting parts includes a second hole transport material, and
a refractive index of the first hole transport material is greater than a refractive index of the second hole transport material.

2. The light-emitting device of claim 1, wherein a maximum emission wavelength of light emitted from at least one of the m emitting parts is different from a maximum emission wavelength of light emitted from at least one of remaining emitting parts of the emitting parts.

3. The light-emitting device of claim 1, wherein a maximum emission wavelength of light emitted from each of the m light-emitting parts is equal to each other.

4. The light-emitting device of claim 1, wherein a thickness of the first hole transport region and a thickness of the second hole transport region are equal to each other.

5. The light-emitting device of claim 1, wherein:
the first hole transport region directly contacts the first electrode,
the second hole transport region directly contacts the p-type charge generation layer of a first charge generation layer, the first charge generation layer being located between the first emitting part and the second emitting part, or
the first hole transport region directly contacts the first electrode, and the second hole transport region directly contacts the p-type charge generation layer of a first charge generation layer, the first charge generation layer being located between the first emitting part and the second emitting part.

6. The light-emitting device of claim 1, wherein
the first electrode is an anode,
the second electrode is a cathode,
the hole transport region includes at least one of a hole injection layer, a hole transport layer, an emission auxiliary layer, and an electron blocking layer, and
the electron transport region includes at least one of a buffer layer, a hole blocking layer, an electron control layer, an electron transport layer, and an electron injection layer.

7. The light-emitting device of claim 1, wherein
the first hole transport region includes a first hole transport layer including the first hole transport material, and
the second hole transport region includes a second hole transport layer including the second hole transport material.

8. The light-emitting device of claim 7, wherein a thickness of the first hole transport layer and a thickness of the second hole transport layer are equal to each other.

9. The light-emitting device of claim 7, wherein:
the first hole transport layer directly contacts the first electrode,
the second hole transport layer directly contacts the p-type charge generation layer of a first charge generation layer of the m−1 charge generation layers, the first charge generation layer being located between the first emitting part and the second emitting part, or
the first hole transport layer directly contacts the first electrode, and the second hole transport layer directly contacts the p-type charge generation layer of a first charge generation layer of the m−1 charge generation layers, the first charge generation layer being located between the first emitting part and the second emitting part.

10. The light-emitting device of claim 1, wherein
a refractive index of the first hole transport material is about 1.8 or greater and about 2.8 or less, and
a refractive index of the second hole transport material is about 1.5 or greater and about 2.5 or less.

11. The light-emitting device of claim 1, wherein a difference between the refractive index of the first hole transport material and the refractive index of the second hole transport material is 0.1 or greater and about 0.5 or less.

12. A light-emitting device comprising:
first electrodes arranged according to a first subpixel, a second subpixel, and a third subpixel, respectively;
a second electrode facing the first electrodes;
m emitting parts located between the first electrodes and the second electrode; and
m−1 charge generation layers each located between two neighboring ones among the m emitting parts, and each including an n-type charge generation layer and a p-type charge generation layer, wherein
m is an integer of 2 or greater,
the m emitting parts each include a hole transport region, an emission layer, and an electron transport region, disposed in sequence,
the emission layer includes a first emission layer located in the first subpixel and emitting first-color light, a second emission layer located in the second subpixel and emitting second-color light, and a third emission layer located in the third subpixel and emitting third-color light,
a first hole transport region included in a first emitting part among the m emitting parts includes a first hole transport material,
a second hole transport region included in a second emitting part among the m emitting parts includes a second hole transport material, and
a refractive index of the first hole transport material is greater than a refractive index of the second hole transport material.

13. The light-emitting device of claim 12, wherein a difference between the refractive index of the first hole transport material and the refractive index of the second hole transport material is about 0.1 or greater and about 0.5 or less.

14. The light-emitting device of claim 12, wherein
the first-color light is red light,
the second-color light is green light, and
the third-color light is blue light.

15. A light-emitting device comprising:
first electrodes arranged according to a first subpixel, a second subpixel, and a third subpixel, respectively;
a second electrode facing the first electrodes; and
m emitting parts located between the first electrodes and the second electrode; and
m−1 charge generation layers each located between two neighboring ones among the m emitting parts, and each including an n-type charge generation layer and a p-type charge generation layer, wherein
m is an integer of 2 or greater,
the m emitting parts each include a hole transport region, an auxiliary layer, an emission layer, and an electron transport region, disposed in sequence,
the emission layer includes:
a first emission layer located in the first subpixel and emitting first-color light;
a second emission layer located in the second subpixel and emitting second-color light; and
a third emission layer located in the third subpixel and emitting third-color light,
the auxiliary layer includes:
a first auxiliary layer located in the first subpixel and between the hole transport region and the first emission layer;
a second auxiliary layer located in the second subpixel and between the hole transport region and the second emission layer; and
a third auxiliary layer located in the third subpixel and between the hole transport region and the third emission layer,
the first auxiliary layer included in a first emitting part among the m emitting parts includes a first first auxiliary layer, a first second auxiliary layer, and a first third auxiliary layer,
the second auxiliary layer included in a second emitting part among the m emitting parts includes a second first auxiliary layer, a second second auxiliary layer, and a second third auxiliary layer,
the first first auxiliary layer, the first second auxiliary layer, and the first third auxiliary layer each independently include a first hole transport material,
the second first auxiliary layer, the second second auxiliary layer, and the second third auxiliary layer each independently include a second hole transport material, and
a refractive index of the first hole transport material is greater than a refractive index of the second hole transport material.

16. The light-emitting device of claim 15, wherein a difference between the refractive index of the first hole transport material and the refractive index of the second hole transport material is about 0.1 or greater and about 0.5 or less.

17. The light-emitting device of claim 16, wherein
a thickness of the first first auxiliary layer and a thickness of the second first auxiliary layer are equal to each other,
a thickness of the first second auxiliary layer and a thickness of the second second auxiliary layer are equal to each other, and
a thickness of the first third auxiliary layer and a thickness of the second third auxiliary layer are equal to each other.

18. An electronic apparatus including the light-emitting device of claim 1.

19. The electronic apparatus of claim 18, further comprising:
a thin-film transistor, wherein
the thin-film transistor includes a source electrode and a drain electrode, and
the first electrode of the light-emitting device is electrically connected to the source electrode or the drain electrode.

20. The electronic apparatus of claim 18, further comprising:
at least one of a color filter, a color conversion layer, a touch screen layer, and a polarizing layer.
